(19) United States
(12) Patent Application Publication
(10) Pub. No.: US 2008/0223429 A1
(43) Pub. Date: Sep. 18, 2008

(54) Solar Cell (Sliver) Sub-Module Formation

(75) Inventors: Vernie Allan Everett, Australian Capital Territory (AU); Andrew William Blakers, Australian Capital Territory (AU)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: The Australian National University, Acton (AU)

(21) Appl. No.: 11/660,006

(22) PCT Filed: Aug. 9, 2005
(86) PCT No.: PCT/AU2005/001193

§ 371 Date: May 17, 2007

(30) Foreign Application Priority Data
Aug. 9, 2004 (AU) 2004904476
Aug. 9, 2004 (AU) 2004904478
Aug. 9, 2004 (AU) 2004904479
Jun. 17, 2005 (AU) 2005903173

(51) Int. Cl. H01L 31/048; H01L 31/052; H01L 31/18

(52) U.S. Cl. 136/244; 136/251; 136/246; 29/825; 257/E31.131; 257/E31.127

(57) ABSTRACT

A solar cell sub-module (100) for a photovoltaic device, including a plurality of elongate solar cells (slivers) (101) mounted in a structure that maintains the elongate solar cells in a longitudinally parallel and generally coplanar configuration, the structure providing one or more conductive pathways (201) electrically interconnecting the elongate solar cells (101). Also claimed are inventions related to releasing elongate substrate from a wafer frame; providing a plurality of mutually spaced elongate storage bins with a particular spacing; dispensing elongate solar cells into an alignment jig and attaching the cells to a substrate; engaging a length of electrical interconnect with an engagement tool having spaced engagement sections and applying a cutting tool; forming an electrical connection in a photovoltaic module with a conductor defining an indirect path between locations to compensate for thermal expansion; maintaining the solar cell orientation of sliver solar cells when releasing them from a wafer frame; engaging only opposing faces of elongate substrates, interconnected by a wafer frame, when releasing them; storing elongate substrate in a stacked configuration with a translation mechanism.

### FIELD OF THE INVENTION

The present invention relates to a solar cell sub-module incorporating elongate solar cells and a method of forming the solar cell sub-module, and in particular to a solar cell sub-module for a photovoltaic device, a method of forming a solar cell sub-module for a photovoltaic device, a substrate release process, an elongate substrate dispensing process, a process for forming a solar cell sub-module for a photovoltaic device, an elongate substrate handling system, a process for forming a solar cell sub-module for a photovoltaic device, a process for forming an electrical connection in a photovoltaic module, a process for forming an electrical connector for a photovoltaic module, a process for forming electrical connections between sliver cells in a photovoltaic module, an electrical connector for a photovoltaic module, a system for forming electrical connectors for a photovoltaic module, a sliver removal process, a sliver removal apparatus, a sliver removal clamp, a process for releasing elongate substrates from a wafer, and a storage apparatus for storing elongate substrates in a stacked configuration.

### BACKGROUND

In this specification, the term “elongate solar cell” refers to a solar cell of generally parallelepiped form and having a high aspect ratio in that its length is substantially greater (typically some tens to hundreds of times larger) than its width. The thickness of an elongate solar cell is largely immaterial to the present invention, but is typically four to one hundred times smaller than the width of the cell. The length and width of a solar cell define the maximum available active surface area for power generation (the active “face” or “faces” of the solar cell), whereas the length and thickness of a solar cell define the optically inactive surfaces or “edges” of a cell. A typical elongate solar cell is 10-120 mm long, 0.5-5 mm wide, and 15-400 microns thick.

Elongate solar cells can be produced by processes such as those described in “HighVo (High Voltage) Cell Concept” by S. Scheibenstock, S. Keller, P. Fath, G. Willeke and E. Bucher, Solar Energy Materials & Solar Cells Vol. 65 (2001), pages 179-184 (“Scheibenstock”), and in International Patent Application Publication No. WO 02/45143 (“the Sliver patent application”). The latter document describes processes for producing a large number of thin (generally <150 μm) elongate silicon substrates from a single standard silicon wafer where the dimensions of the resulting thin elongate substrates are such that their total surface area is greater than that of the original silicon wafer. Such elongate substrates are referred to as ‘sliver substrates.’ The Sliver patent application also describes processes for forming solar cells on sliver substrates, referred to as ‘sliver solar cells’. However, the word ‘sliver’ generally refers to a sliver substrate which may or may not incorporate one or more solar cells. The word “sliver” is a registered trade mark of Origin Energy Solar Pty Ltd, Australian Registration No. 933476.

In general, elongate solar cells can be single-crystal solar cells or multi-crystalline solar cells formed on elongate substrates using essentially any solar cell manufacturing process. The elongate substrates are preferably formed in a batch process by machining a series of parallel elongate slots through a silicon wafer to define a corresponding series of parallel elongate substrates joined together by the remaining portions of the wafer, referred to as the wafer frame. Solar cells can be formed on the elongate substrates while they remain in the wafer frame, and subsequently separated from each other and the wafer frame to provide a set of individual elongate solar cells.

The elongate slices of silicon in which elongate solar cells are formed are fragile and need careful handling, in particular during separation from the host wafer, testing, sorting and binning, storage, mounting and electrical interconnection. Additionally, since the area and value of each cell is small when compared with larger area conventional (i.e., non-elongate, wafer based cells) solar cells, there is need for reliable, low cost handling, assembly, and mounting processes in order to make use of the elongate substrates and solar cells economically viable. Existing approaches to using elongate solar cells to form photovoltaic devices have been limited in scope. Some applications have involved gluing the cells to a substrate or a transparent or semi-transparent superstate such as glass, to form an array of electrically connected elongate solar cells. A “pick and place” robotic machine can be used to position the elongate solar cells on the substrate. The cells can then be electrically interconnected using a material such as a conductive epoxy or solder. An encapsulation material such as ethylene vinyl acetate (EVA), silicone, polyvinyl butyral (PVB), or polyurethane can then be used together with a cover layer of glass or Tefzel or Teflon film or similar transparent material to complete the assembly of a solar cell array.

A significant difficulty with forming a photovoltaic device using this technique is the requirement for relatively precise placement and electrical interconnection of a relatively large number of elongate cells over a relatively large area to form an array with a similar power output to a standard solar module of similar area, but with the possibility of substantially different voltage and current characteristics.

Additionally, conventional pick-and-place processes, which are generally designed for the assembly of high value, small-sized items over relatively small substrate areas, can be too slow and complex to be economically viable when modified to cover large area substrates. Alternatively, a high-speed assembly system with acceptable throughput would necessarily be expensive, require precision manufacturing and control systems, and would almost certainly have a limited practical life due to the wear and tear of handling large numbers of small elongate solar cells at high speeds over the area of a conventional solar module assembly.

Conventional modules, particularly modules constructed using mono-crystalline or multicrystalline silicon wafers, typically contain around 60 to 70 wafer cells per square metre of module area. The cells used in most conventional modules are mono-facial (i.e., they provide only one active surface for illumination), and there is no difficulty identifying the correct orientation of the cells. The large (e.g., typically 4 inch) diameter of conventional wafer cells also means that there is virtually no likelihood of the cells being flipped in the handling and assembly processes. The number of electrical connections in a module comprising conventional wafers is of the order of 200, or around 4 per cell.

With elongate cells, the number of electrical connections may be around six or eight per cell, but because the area of each elongate cell is only a small fraction of the area of a conventional cell, the number of electrical connections for modules incorporating only elongate solar cells may be in the range of 2,000 to 20,000 or more per square metre of module area. It is evident from this consideration alone that a non-conventional approach is required in order to cheaply and reliably establish the electrical interconnections of modules incorporating elongate solar cell sub-module assemblies.

Furthermore, the mono-facial nature of conventional cells allows their orientation and polarity to be easily determined visually. However, elongate solar cells can be bifacial (i.e., have two opposing optically active faces), and can also be perfectly symmetrical in physical form, making visual determination of their polarity impossible. Elongate solar cells with a very large aspect ratio, can readily warp or bend if they are thin enough, but at the same time are quite brittle when subjected to localized stress and may fracture or become damaged during separation, handling, testing, binning, and assembly.

Another difficulty with elongate solar cells is that they can easily be mis-oriented about their length axis during separation and handling. The elongate substrates can be processed to form mono-facial solar cells, in which case the electrodes can be on the cell faces, or even close to the cell edges. Alternatively, the elongate substrates can be processed to form bifacial solar cells, in which case the electrodes can be on the cell faces, or more likely, on the cell edges. The bifacial nature of some forms of elongate solar cell demands that the orientation, and hence the polarity, of each cell is mechanically maintained in an absolutely reliable manner during handling. The elongate bifacial solar cells can also appear physically symmetrical, with no markings or features available from which the solar cell polarity may be determined visually. Mis-oriented elongate bifacial solar cells can therefore inadvertently be incorporated in the module in an orientation that forces them to operate in reverse bias, which would reduce the module output and has the potential to destroy the cell and/or the module.

In conventional photovoltaic modules, the cells, bus bar and cell connections are entirely encapsulated within a matrix of elastic material such as ethylene vinyl acetate (EVA), which is itself sandwiched between a glass substrate and a protective back-sheet or another glass sheet. For various reasons, it is not convenient to entirely encapsulate elongate solar cells in the standard manner described above. Rather, it is preferable to bond elongate cells directly to a supporting substrate, most commonly glass. However, this arrangement makes it difficult to form reliable electrical connections between elongate cells.

One application of solar cells is in so-called linear concentrator systems. An example of such a system is a trough concentrator, which includes long sun-tracking rows of mirrors or refractive lenses. A typical linear photovoltaic concentrator system operates at a geometric solar illumination concentration ratio in the range of about 8 to 80 times that of a “one-sun” system (referred to as 8-80 “suns”). In such an arrangement, a single line of conventional solar cells is mounted on the receiver. Each conventional cell is 2 cm to 5 cm wide and 20 to 40 cells are connected in series along the length of the receiver which has a length of 1-2 m. The uniformity of the light is generally good along the length of the receiver but poor in the transverse direction. The solar cells are usually connected in series to provide a higher overall voltage output. Electrical current is typically conducted from the centre of each cell on the upper and lower surfaces to four contacts on the two edges of each cell. Electrical connection is made to each of these contacts to remove the current. Series connection of the solar cells is achieved at the edge of the receiver by an appropriate interconnection technique typically involving the use of copper tabs. However, the series interconnection with this conventional system occupies a significant area. Additionally, electrical current flow along the length of the concentrator receiver is a process of moving electrical charge transversely from the central region of each cell to the edge into the external connections and back to the central region of the neighbouring cell. As a consequence, significant series resistance losses arise. The application of elongate solar cells to concentrator systems has the potential to solve a number of the problems associated with conventional solar cells presently in use, as detailed above.

It is desired to provide a solar cell sub-module for a photovoltaic device, a method of forming a solar cell sub-module for a photovoltaic device, a solar cell sub-module for a photovoltaic device, a method of forming a solar cell sub-module for a photovoltaic device, a substrate release process, an elongate substrate dispensing process, a process for forming a solar cell sub-module for a photovoltaic device, an elongate substrate handling system, a process for forming a solar cell sub-module for a photovoltaic device, a process for forming an electrical connection in a photovoltaic module, a process for forming an electrical connector for a photovoltaic module, a process for forming electrical connections between sliver cells in a photovoltaic module, an electrical connector for a photovoltaic module, a system for forming electrical connectors for a photovoltaic module, a sliver removal process, a sliver removal apparatus, a sliver removal clamp, a process for releasing elongate substrates from a wafer, and a storage apparatus for storing elongate substrates in a stacked configuration that alleviate one or more of the above difficulties, or at least provide a useful alternative.

### SUMMARY OF THE INVENTION

In one aspect, the present invention provides a solar cell sub-module assembly for a photovoltaic device, including a plurality of elongate solar cells mounted in a structure that maintains the elongate solar cells in a substantially longitudinally parallel and generally co-planar configuration, said structure providing one or more conductive pathways electrically interconnecting the elongate solar cells.

In another aspect, the invention provides a method of forming a solar cell sub-module for a photovoltaic device including the steps of mounting a plurality of elongate solar cells in a structure that maintains the elongate solar cells in a substantially longitudinally parallel and generally co-planar configuration; and establishing one or more conductive pathways extending through the structure to electrically interconnect the elongate solar cells.

The invention has particular application to solar power modules, which typically use non-concentrated sunlight, and which usually comprise 30-50 conventional silicon solar cells connected electrically together in series and encapsulated behind glass.

The invention also has particular application to linear concentrator receivers, which utilise concentrated sunlight, and which usually comprise 2040 silicon solar cells connected electrically together and mounted on a suitable heat sink at the focus of a solar linear concentrating system.

The mounting structure prevents damage to the elongate solar cells or electrical connections resulting from thermal cycling during manufacture or use. In one form of the invention, this is achieved by mounting the elongate solar cells on a thermally compatible substrate and providing one or more electrically conductive pathways that extend across the substrate in order to establish electrical interconnection. In another form of the invention the one or more electrical interconnections between the elongate cells form the physical retention structure so that different rates of thermal expansion do not produce any significant stress in the structure.

The elongate solar cells in each sub-module can be spaced according to functional and performance requirements for the particular photovoltaic device. In some applications there will be no spacings so that the adjacent elongate solar cells abut. In other applications the spacings between each elongate solar cell could be as much as several times the width of the individual elongate solar cells. In some applications, the elongate solar cells may be bifacial; in these applications the spacing is determined to take advantage of irradiation of both sides of the elongate solar cells by use of appropriately positioned reflectors or by illumination from both sides. In other applications, the elongate solar cells may be mono-facial. In these latter applications the spacing is preferably determined to take advantage of irradiation received on one side only of the elongate solar cells. However, in the latter case there may be some advantage offered by the use of appropriately positioned reflectors to trap light by total internal reflection within the structure, or by illumination from both sides where the light from the rear can be re-directed to the front surface of the long narrow solar cell.

In one form of the invention, the substrate takes the form of one or more crossbeams to which the elongate cells are bonded. The crossbeams provide mechanical stability to the sub-module assembly structure, and electrical interconnection between the elongate solar cells along the surface of the crossbeam members in continuous, semi-continuous, or intermittent electrically conducting tracks. The crossbeams can be fabricated from silicon or any other suitable material such as thin glass sheets, rigid polymer sheets such as Lexan® polycarbonate sheets, or resin-based acrylics such as Shinkolite® VH acrylic sheet, Marplex® acrylic sheet, or flexible materials such as Lexan® polycarbonate film, or resin-based acrylics such as Shinkolite® VH acrylic film, Marplex® acrylic film, polyimide films such as Kapton®, fluoropolymer films such as Tefzel®, or polyethylene-based films such as Tedlar®. It will be understood by those skilled in the art that there are many other suitable materials too numerous to list, transparent or opaque, low- or high-temperature stable depending on the particular requirements.

In the form of the invention where the elongate cells are mounted to a cross beam, thermal compatibility of the substrate is achieved by virtue of the small dimension of the bonded area which adheres the cross beam to the individual elongate solar cells. That is, because of the small common area physically joined and constrained by the mutually bonded region, the thermal expansion coefficient of the cross beam does not need to be as critically matched to the thermal coefficient of expansion of the elongate cells as for some other forms of the invention.

The sub-modules formed by the bonding of elongate solar cells to crossbeams are referred to in this specification as “rafts”. The rafts can include a few to several hundred elongate solar cells. In one form of the invention the rafts can be formed in sizes similar to conventional solar cells, typically 10 cm×10 cm, or 12 cm×12 cm, or even 15 cm×15 cm or more. This allows each sub-module assembly to be incorporated as an (aggregate) “cell” in a photovoltaic device, allowing the use of similar techniques for testing, binning, handling, assembly, stringing, encapsulation and electrical connection to those currently used for conventional solar cells. However, a significant difference is that each raft will usually have a much higher voltage and a correspondingly lower current than a typical conventional solar cell, depending upon whether the elongate solar cells are connected in series or in parallel.

In another form of the invention, referred to in this specification as “boats”, the elongate solar cells are mounted on a continuous or semi-continuous substrate or optically clear or transparent superstrate. The substrate or superstrate is thermally compatible in as much as it has a thermal expansion coefficient similar to that of the silicon to reduce stress during thermal cycling. In particular, the substrate or superstrate is selected so that the coefficient of thermal expansion is such that the stress introduced in the module structure and components, including any adhesive or bonding layer, by the differential expansion of the elongate cells, the substrate or the superstrate, and the bonding or adhesive material including electrical connections and other physical structures is not sufficient to damage the integrity of the structure or to reduce the lifetime or reliability of the module or components. Alternatively, the substrate or superstrate can be compliant, allowing thermal stresses to be accommodated.

The substrate or superstrate material is preferably low cost, electrically insulating (either intrinsically or by way of coating with an insulating material), thin, and capable of being selectively coated with conductive tracks for electrical connections, and may be flexible for applications requiring flexible sub-module assemblies within flexible photovoltaic power modules. Suitable substrates include silicon and borosilicate glass and polymer sheets or strips such as Lexan® polycarbonate, fluorinated polymer sheets or strips such as Tefzel®, polyethylene sheets or strip such as Tedlar®, Polyimide sheets or strips such as Kapton®, resin-based acrylics such as Shinkolite® acrylic sheet or Marplex® acrylic sheet or flexible film materials such as Lexan® polycarbonate film, fluorinated polymer films such as Tefzel®, polyethylene films such as Tedlar®, and polyimide film such as Kapton® tape.

This form of the invention is particularly applicable to use under concentrated sunlight. In this form of the invention the elongate solar cells may be closely positioned or spaced apart. Preferably the boat substrate or optically clear superstrate is mounted to a heat sink so that the solar cells can be cooled via thermal transfer through the substrate to the heat-sink.

In yet another form of the invention elongate solar cells of the sub-module are retained in their relative locations with respect to adjacent cells by the electrical interconnections and electrical interconnecting material alone, removing the need for the crossbeams or substrate as well as the interconnecting electrical tracks. This form of the invention is hereinafter referred to as a “mesh raft”.

The elongate solar cells are particularly suitable for use in concentrated sunlight applications because the rafts and boats have a high voltage capability. The maximum power voltage of a elongate silicon solar cell under concentrated sunlight is around 0.7 volts. The typical width of a cell is around 0.7 mm to 3 mm. Thus voltage builds at a rate of up to 10 volts per linear centimetre of elongate solar cell assembly array, with the advantage of a correspondingly small current.

Consequently, elongate solar cells, formed from crystalline or multi-crystalline silicon or other solar cell material, mono-facial or bifacial in nature, and whether thin or thick, formed into sub-module assemblies such as rafts, mesh rafts, or boats are particularly suitable for use in linear concentrator systems in place of conventional solar cells. Each elongate solar cell can be series connected to its neighbour along the length (continuously or intermittently) of each edge, or between an edge and a face, or even between faces and edges or faces and faces, depending on the electrode arrangements and whether the elongate cells are bifacial or mono-facial.

Electrical current consequently moves substantially only in a direction parallel to the longitudinal axis of the receiver rather than in a series of alternating transverse and longitudinal directions as occurs when conventional solar cells are used. Additionally, the space occupied by the series connections between the elongate cells is comparatively very small, so that little sunlight is lost by absorption in those connections. Furthermore, the series resistance loss of the sub-module assemblies constructed from elongate solar cells, and hence the concentrator receivers constructed from elongate solar cell sub-modules such as rafts, mesh rafts, or boats is nearly independent of the width of the illuminated region.

A number of advantages flow from the feature of certain forms of elongate cells that include electrical connections only at the edge of each solar cell. In the rafts, mesh rafts, or boats described herein, electrical connections are not required at the edges of a row of rafts, mesh rafts, or boats (where the “edge” in question is formed by the ends of the constituent elongate solar cells forming the linear array of solar cells within the sub-module assembly) because the connections are provided by way of the one or more conductive pathways on or in the substrate or crossbeams. This means that several parallel rows of rafts or boats can be used on a single receiver with only a narrow spacing required between each row. Consequently, a receiver can be relatively wide, up to many tens of centimetres. This has particular advantage in concentrator applications where multiple mirrors or wide mirrors reflect light onto a single fixed receiver. In such an application, each of the rows of rafts or boats will have a fairly uniform illumination in the longitudinal direction although the illumination level may be different for each row.

In these applications it is difficult to control series resistance, manage the problems associated with uneven illumination across the width of a wide receiver, and minimise wasted space between rows and cells if conventional concentrator solar cells are used. This is not the case with the elongate solar cell sub-modules described herein.

A further advantage of the rafts, mesh rafts, or boats described herein is that because they are formed from elongate solar cells, the receiver voltage can be large so that the voltage up-conversion stage of an inverter (used to convert DC to AC current) associated with the photovoltaic system can be eliminated. A further advantage is that each raft, mesh raft, or boat can be operated electrically in parallel to other rafts, mesh rafts, or boats. Alternatively, a group of rafts or boats can be series connected, and the groups so formed can be run in parallel with other groups. This parallel connection ability can greatly reduce the effect on receiver output of non-uniformities in illumination, arising for example from shadows cast by structural element, imperfections in the mirrors, partial shading from debris, contamination, uneven degradation in the mirror performance, or optical losses at the ends of linear concentration system.

It will be apparent that the rafts, mesh rafts, or boats described herein provide a significant advance over existing uses of elongate solar cells. In particular, the placing of elongate cells one by one into a solar power module is avoided by the use of elongate solar cell rafts, mesh rafts, or boats, each comprising tens to hundreds of individual elongate cells. Because each such raft, mesh raft, or boat is small, it can be inexpensively assembled in a mechanical jig that allows sufficiently precise placement of the components. The desired number of rafts or boats can then be deployed to form the solar power module with any desired shape, area, current and voltage characteristics, and associated output power.

Similar benefits pertain to the formation of concentrator receivers and minimodules. Minimodules are small photovoltaic modules that use artificial light (and occasionally sunlight) to power consumer electronics or charge small batteries, and which deliver an appropriate voltage that is generally larger than can be provided by a single solar cell.

The rafts, mesh rafts, and boats described herein can be encapsulated and mounted on a flexible material such as Lexan® polycarbonate film, fluorinated polymer films such as Tefzel®, polyethylene films such as Tedlar®, and polyimide film such as Kapton® all in sheet, film, or tape form as required for the particular application, so as to form flexible photovoltaic modules by taking advantage of the flexibility of the thin elongate solar cells. It will be evident to those skilled in the art that a very large range of suitable materials, and combinations of these materials and adhesives, can be utilised to form the sub-module assemblies described above.

Another method of taking advantage of the flexibility of rafts, mesh rafts, and boats fabricated using thin and flexible solar cells and crossbeams or substrates or superstrates is to mount the raft or boat conformally onto a rigid curved supporting structure. It would be difficult to achieve such a goal using some form of robotic “pick and place machine” for the solar cells. Alternatively, the raft, mesh raft, or boat can be mounted onto a flat supporting structure that is then curved to the desired shape.

One example of a suitable supporting structure is curved glass for architectural applications. Recent improvements in polymer technology have delivered UV-stable polymers, materials such as Lexan® polycarbonate, and UV-stabilised acrylics that are suitable for some architectural applications.

Another example of an application that takes advantage of the flexibility of thin elongate solar cell sub-assemblies is to mount the raft, mesh raft, or boat onto a curved linear concentrator receiver fabricated from extruded aluminium or other materials. One advantage of so doing is that the individual elongate solar cells in the raft or boat will receive near-normal incidence illumination even from sunlight reflected or refracted from the edge regions of the linear concentrator optical elements.

Another advantage of the rafts, mesh rafts, and boats formed described herein is the ease of measurement of the efficiency of the sub-module assembly. The measurement of the efficiency of a large number of individual small solar cells is both inconvenient and expensive. The rafts, mesh rafts, and boats described herein allow the efficiency of the rafts, mesh rafts, or boats to be directly measured, thus effectively allowing dozens to hundreds of small solar cells to be measured together in a single operation. This approach reduces measurement cost and time so that it becomes viable to sort the rafts, mesh rafts, or boats into categories of performance (including a fail category), and then select from the sorted rafts, mesh rafts, and boats to assemble solar power modules, receivers or minimodules with different performance characteristics. Those rafts, mesh rafts, and boats whose performance is below a minimum level can be discarded or divided into sub-sections and remeasured. If the individual elongate solar cells that cause the poor performance are primarily in one portion of the raft, mesh raft, or boat, then some subsections may have good performance while another section might need to be discarded because its performance is not sufficiently good.

The rafts, mesh rafts, or boats described herein also address difficulties that can occur during the fabrication of solar cells where it may be inconvenient or difficult to carry out some steps on small solar cells. For example, it may be difficult to metallise one of the faces of an elongate solar cell in order to create a reflector on one surface until it is removed from the remaining portions of the silicon wafer from which it was formed, as described in the Sliver patent application. Another example is the application of an anti-reflection coating, which in some circumstances may be more conveniently performed after metallisation has been completed. This however carries a risk that the anti-reflection coating will cover the metallisation, which would make it difficult to establish electrical contact with each cell. Provided the appropriate materials are selected to form the raft, mesh raft, or boat, layers such as anti-reflection coatings and reflective coatings can be deposited by evaporation, chemical vapour deposition, sprayed deposition, or other means during or after the time when the raft, mesh raft, or boat has been assembled.

Similarly, the raft, mesh raft, or boat sub-modules can provide a more convenient approach for electrical passivation of the surface of solar cells. Electrical passivation is sometimes carried out using a material such as silicon nitride deposited by a plasma-enhanced chemical vapour deposition (PECVD) process or by depositing amorphous silicon on the surface of the cell. These coatings obviate the need for high-temperature processing in order to achieve good surface passivation. In some cases it is difficult, or impossible, to carry out this step during normal solar cell processing.

For example, silicon nitride deposition by PECVD is not conformal. Consequently, it is difficult to successfully coat the surfaces of some forms of elongate solar cells while they remain attached to other portions of the silicon wafer. The process can, however, be successfully carried out during or after the assembly of the raft, mesh raft, or boat sub-modules containing this particular type of elongate solar cell.

In another form, the present invention provides a photovoltaic device for a solar linear concentrator, including a plurality of rafts, mesh rafts, or boats positioned in a closely adjacent arrangement so that the electrical current path occurs substantially lengthwise along the concentrator receiver, but transverse to the length direction of the elongate solar cells.

Elongate solar cells can be fabricated in several types or categories. The categories include: thin elongate solar cells where a “thin” solar cell is less than 150 microns thick; thin elongate bifacial solar cells where the cell electrodes are on the edges of the cell; thin elongate mono-facial solar cells where the electrodes are on the faces or partially on the faces of the solar cell; thin elongate mono-facial solar cells where the electrodes are in some combination of the faces or the edges of the solar cells; thick solar cells where a “thick” solar cell is defined as a solar cell greater than or equal to 150 microns thick; thick elongate bifacial solar cells where the cell electrodes are on the edges of the cell, thick elongate mono-facial solar cells where the electrodes are on the faces or partially on the faces of the solar cells; and thick elongate mono-facial solar cells where the electrodes are in some combination of faces and edges of the solar cells.

There are several distinctive features of solar cell sub-module assemblies such as rafts, mesh rafts, and boats comprising elongate solar cells that distinguish these assemblies from conventional cells and sub-assemblies of conventional cells.

For example, the elongate solar cells are contained in a substantially planar arrangement. The elongate solar cells are organised in a one-dimensional linear array of substantially parallel cells where the cells are aligned such that the length axis of the cells runs transverse to the direction of the linear array. This places the electrode edge of one cell adjacent to the electrode edge of the juxtaposed cell. This contrasts with most devices assembled from conventional cells, or devices assembled from small-area diced conventional cells where the purpose of the assembly of conventional cells or diced conventional cells is predominantly to build the device output voltage to a level suitable for powering small or portable low-power electrical devices such as calculators or for low power battery chargers such as mobile phone chargers or portable music player battery chargers. In such devices the cells are frequently organised into a two-dimensional planar array.

The elongate solar cells forming rafts or mesh rafts are fixed in positions relative to adjacent cells with a uniform or near-uniform or a repeating pattern of spacing between the cells forming the linear array of the sub-module assembly in order to substantially reduce the surface area of silicon relative to the overall area or footprint occupied by the sub-module. The purpose of the spacing is to substantially reduce the quantity of expensive solar cell material in the module without substantially reducing the power output of the module. A scattering reflector placed behind the array reflects the light which passes through the gaps in the array in such a way that some of the reflected light strikes the rear surface of the elongate cells, some of the light is reflected at a sufficiently high angle that it is trapped by total internal reflection within the module, and only a small portion of the light is lost by being reflected back out of the module.

Elongate solar cells are particularly suitable for this type of static optical concentration module design due to the fact that optimisation of static concentrator performance requires the thickness profile of the module to be of the order of the width of the elongate solar cells. It is clear from this observation alone that conventional cells in conventional formats are not suitable candidates for this form of static concentration. However, raft and mesh raft assemblies of elongate solar cells are eminently suitable for this form of static concentration design with the accompanying benefit of a substantial reduction in silicon consumption.

Modules constructed from elongate solar cells can easily be designed to produce very high voltages per unit of area compared with conventional solar cells. Since voltage can be built at a rate of up to around one volt per linear millimetre, compared with conventional modules where the rate is typically around one volt per ten to thirty linear centimetres, even a small PV installation can be operated at a voltage which is sufficiently high to allow the elimination of the voltage up-conversion inverter stage, as well as significantly reducing current-carrying capacity requirements associated with low voltage, high current conventional cells and conventional solar power modules that is a serious draw-back for conventional PV module arrays.

Further, significant areas of sub-module assembly cell arrays within modules constructed from elongate solar cells can be operated in parallel, whilst still retaining a high module output voltage. This offers significant improvements in annual energy output through reductions in partial shading losses, reduced reverse bias operation without the requirement for by-pass diode protection, and other benefits such as lower module and cell operating temperatures compared with conventional modules.

The plurality of elongate cells forming the raft, mesh raft, or boat sub-module assembly are electrically interconnected in an integral manner such that the electrical interconnections between the constituent elongate cells in the raft, mesh raft, or boat sub-module assemblies are comprehensive and complete and no further internal electrical interconnections within the sub-module assemblies are necessary between the constituent cells upon assembly of the sub-modules to form solar power modules save for electrical connections between the sub-module assemblies themselves, sub-modules to bus bars, or between sub-module groups or arrays of sub-modules and bus-bars or sub-module groups and other sub-module groups.

The substantially planar array arrangement of the plurality of elongate cells can be assembled on crossbeams, semi-continuous or continuous substrates or superstrates, constructed from optically transparent or opaque supporting materials, electrically conductive or non-conductive support materials, thermally conductive or non-conductive support materials, using rigid or flexible support materials.

Particular methods and processes for assembling a plurality of elongate solar cells into sub-module assemblies or arrays of cells depend principally on the structure and format of the elongate cells, the orientation and arrangement of the cells in the parent wafer, and the structure and format of the planar array of the elongate cells in the finished sub-module assembly. However, the structure and function, the motivation and purpose, and the benefits and utility of the sub-module assemblies described above do not reside in the process of formation, but rather in the physical, optical, electrical, and utilitarian properties of these assemblies of elongate solar cells forming the raft, mesh raft, and boat sub-module assembly structures described above. The raft, mesh raft, and boat sub-module assemblies are products and structures that make possible the convenient, fast, low cost, and reliable handling, manipulation and testing and binning, and final assembly of large numbers of elongate solar cells in a single operation.

The ability to fabricate stand-alone, self-contained “rafts”, “mesh rafts”, or “boats” greatly simplifies the separation, handling, and assembly of all forms of elongate solar cells and the construction of PV modules containing these elongate solar cells. The assembly of rafts, mesh rafts, or boats can be accomplished with small, cheap devices, jigs, and machines that eliminate the requirements for large-scale accuracy and automation such as devices and machines presently in use or presently thought to be necessary for elongate solar cell module assembly.

Furthermore, the tasks required for the assembly of solar power modules and concentrator receivers, such as stringing and encapsulating the rafts, mesh rafts or boats, can be performed with very slightly modified conventional PV cell stringing interconnecting, cell handling, and cell assembly equipment.

An additional advantageous feature of the sub-module assemblies described herein is that solar power modules constructed using sub-modules assembled from elongate solar cells can be manufactured using entirely conventional PV module materials. The sub-module assemblies, and the separation, handling, testing, binning, and assembly of the sub-assemblies into solar power modules can be achieved using only the elongate solar cells, solder and conventional bus-bars, EVA and glass.

The structures and processes described herein provide an opportunity and a means of eliminating the use, and also the requirements for the use, of adhesives of all forms, conductive epoxies or polymers or compounds of all forms including inks, pastes, and elastomers, and optical adhesives of all forms. Not only do sub-module assemblies and processes described herein provide this opportunity and means of eliminating the use, and the requirement for the use of such materials, thus adding greatly to the confidence of the long-term reliability of the elongate solar cell module, but also eliminates the requirement for stencilling or dispensing the solder paste for solder reflow which would otherwise be necessary for forming the solder joints that provide electrical interconnections between the elongate solar cells, and physical and mechanical support between the cells and the sub-module assembly supporting structure.

In accordance with yet a further aspect of the present invention, there is provided a process for forming an electrical connection in a photovoltaic module, including attaching an electrical conductor to mutually spaced locations of a support, said electrical conductor defining an indirect path between said locations to accommodate different rates of thermal expansion of said electrical conductor and said support, and thereby to maintain an electrical connection between said locations.

In another aspect, the present invention also provides an electrical connector for a photovoltaic module, said electrical connector being adapted for attachment to mutually spaced attachment locations of a support, said electrical conductor defining an indirect path between said locations to accommodate different rates of thermal expansion of said electrical conductor and said support, and thereby to maintain an electrical connection between said attachment locations. Preferably, said indirect path includes one or more corrugations of said electrical conductor.

Preferably, said indirect path includes first regions of said electrical conductor shaped to facilitate attachment to said support between second regions of said electrical conductor including one or more corrugations.

Preferably, said first regions are substantially planar. Preferably, said electrical connector includes a bus bar for said photovoltaic module.

Preferably, said bus bar is adapted to form electrical connections between solar cells and banks or arrays of solar cells of said photovoltaic module.

Preferably, said solar cells of said photovoltaic module include elongate solar cells.

In another aspect, the present invention also provides a process for forming an electrical connector for a photovoltaic module, including deforming a length of an electrically conductive substance to define an indirect path between at least two mutually spaced attachment locations along said length to accommodate different rates of thermal expansion of said electrically conductive substance and a support, and thereby to maintain an electrical connection between said attachment locations when at least part of said length of said electrically conductive substance is attached to said support at said mutually spaced attachment locations. Advantageously, said length of said electrically conductive substance may be in the form of a wire or a narrow strip or a sheet.

Advantageously, said length of said electrically conductive substance may be in the form of a sheet, and the process may include cutting said sheet along a direction substantially parallel to the length direction to form a plurality of electrical connectors.

Advantageously, the method may include cutting the deformed length of electrically conductive substance into predetermined lengths to form a plurality of electrical connectors.

Preferably, the process includes further deforming the deformed length of electrically conductive substance so that the electrically conductive substance and said support are pressed together during production of said photovoltaic module.

Preferably, said step of further deforming includes deforming length to a shape or profile selected such that the further deformed length naturally curls into a substantially circular shape.

Preferably, said electrically conductive substance includes a metal.

Preferably, said electrically conductive substance is copper.

Preferably, for solder-based electrical interconnections, said electrically conductive substance is tinned, (solder-coated), copper.

In yet a further aspect, the present invention also provides a process for forming electrical connections between elongate solar cells in a photovoltaic module, including attaching a bus bar to mutually spaced attachment locations of a substrate, said bus bar defining an indirect path between said locations to accommodate different rates of thermal expansion of said bus bar and said substrate, and thereby to maintain an electrical connection between said attachment locations.

Preferably, said bus bar includes one or more corrugations.

Preferably, said bus bar includes one or more corrugated regions separated by respective second regions adapted to facilitate attachment of said bus bar to said substrate.

Preferably, said bus bar includes one or more corrugated regions separated by respective second regions adapted to facilitate electrical connection of said bus bar to said solar cells.

Preferably, said second regions are substantially planar.

Advantageously, the substantially planar second regions may be convex towards said substrate.

The present invention also provides a system having components for executing the steps of any one of the above processes.

The present invention also provides a system for forming electrical connectors for a photovoltaic module, the system including a pair of rotating rollers having mutually opposed projections and recesses adapted to deform a length of an electrically conductive substance fed between said rollers to define an indirect path between at least two mutually spaced attachment locations along said length to accommodate different rates of thermal expansion of said electrically conductive substance and a support, and thereby to maintain an electrical connection between said attachment locations when at least part of said length of said electrically conductive substance is attached to said support at said mutually spaced attachment locations.

In accordance with one aspect of the present invention, there is provided a sliver removal process, including:
receiving a plurality of mutually spaced sliver solar cells interconnected by one or more wafer frame portions, each of said sliver solar cells having outwardly facing edges or electrodes having respective polarities and solar cell faces perpendicular to said edges; and
releasing the sliver solar cells from the one or more wafer frame portions in a substantially simultaneous manner whilst maintaining the relative orientation of said solar cell edges to provide a plurality of released sliver solar cells whose solar cell edges or electrodes of a selected polarity have the same orientation.

The present invention also provides a sliver removal process, including:
receiving a plurality of slivers interconnected and maintained in a mutually spaced arrangement by one or more connecting portions, each of said slivers having outwardly facing edges and faces perpendicular to said edges, the edges of each sliver including a first edge and a second edge, wherein said first edges of said slivers have a first orientation; and
releasing the engaged slivers from the one or more connecting portions in a substantially simultaneous manner whilst maintaining the relative orientation of said edges to provide a plurality of released slivers wherein the first edges of the released slivers have the same orientation.

Preferably, the slivers include sliver solar cells, wherein the edges of each sliver solar cell have opposite polarities.

Advantageously, the process may include:
engaging the edges of said slivers;
removing the one or more connecting portions from the engaged slivers to provide a plurality of released and mutually spaced slivers; and
disengaging the mutually spaced slivers to conflate said slivers into a substantially contiguous stack.

Advantageously, the process may include:
engaging the one or more connecting portions; and
successively removing each of said slivers from said one or more connecting portions in a substantially simultaneous manner to form a conflated stack of slivers.

Advantageously, the process may include:
engaging the one or more connecting portions;
engaging the edges of said slivers; and
removing said slivers from said one or more connecting portions to provide a plurality of released and mutually spaced slivers.

Advantageously, the edges of said slivers may be engaged with adhesive tape.

Preferably, the process includes:
placing the released and mutually spaced slivers into a storage device; and
disengaging the edges of said slivers to form a conflated stack of slivers.

The present invention also provides a sliver removal apparatus having components for executing the steps of any one of the above processes.

The present invention also provides a sliver removal apparatus, including:
a clamp having two opposing portions for engaging respective edges or one or more connecting portions of a plurality of mutually spaced slivers interconnected by said one or more connecting portions, each of said slivers having faces perpendicular to said edges, said faces having a relative orientation; wherein said two opposing portions include alignment slots for receiving respective guides of a sliver storage device in a direction substantially transverse to longitudinal axes of said slivers.

Preferably, said two opposing portions include compliant surfaces for engaging said edges of said slivers without damaging said edges.

Advantageously, said compliant surfaces may be at least partially adhesive.

The present invention also provides a sliver removal apparatus, including a sliver storage device having a plurality of elongated guides for mating with respective alignment slots in a clamp engaging one or more connecting portions or edges of a plurality of mutually spaced slivers interconnected by said one or more connecting portions, said edges having a relative orientation; wherein said elongated guides are arranged adjacent and substantially perpendicular to opposing edges of said slivers when said guides are mated with said slots.

Preferably, the sliver storage device includes a biased retaining plate for retaining released slivers under compression.

Preferably, the sliver storage device includes a base adapted to fracture said slivers at or near ends of said slivers when said base is pressed into said slivers.

The present invention also provides a sliver removal clamp having two opposing portions for engaging one or more connecting portions of a plurality of mutually spaced slivers interconnected by one or more connecting portions, each of said slivers having outwardly directed edges and faces perpendicular to said edges; wherein said two opposing portions include openings to allow edges of said slivers to be engaged to allow substantially simultaneous removal of said slivers from said one or more connecting portions whilst retaining relative orientation of said edges.

The sliver removal processes and apparatus described herein allow convenient and cost-effective separation of slivers from a wafer. Embodiments of the invention advantageously preserve and maintain the orientation and polarity of separated sliver cells, and present a clean, conflated array to subsequent processing or assembly stages.

In accordance with a still further aspect of the present invention, there is provided a method for removing sliver solar cells from the parent wafer frame. The wafer containing the set or array of sliver solar cells is cut, or snapped, to expose one face of the sliver solar cell array. The wafer is then secured in a clamp contacting the edges of the wafer outside the sliver cell array area in the plane of the faces of the wafer. More than one wafer so prepared can be clamped to provide a planar grid or planar array of the faces of exposed sliver solar cell surfaces. The number of wafers clamped in the array may be equal to the number of sliver solar cells required to form the above described sub-module assemblies of sliver rafts, sliver mesh rafts, or sliver boats.

In one form of the invention, the exposed sliver solar cell from each wafer in the clamped wafer array can be removed in a single operation in a planar array arrangement by mechanical means such as a vacuum engagement tool. In another form of the invention the exposed sliver solar cell from each wafer clamped in an array arrangement can be removed in a planar array arrangement by a fast-cure adhesive which directly and permanently bonds the sliver solar cell(s) to the above described sliver raft or sliver boat cross-beam or substrate respectively, or sliver mesh raft electrical interconnection array. In yet another form of the invention, the exposed sliver solar cell from each wafer can be removed in an array by a re-useable sticky surface that temporarily bonds the sliver solar cell(s) to the transport or transfer mechanism, retaining the planar array format and relative spacing between the constituent sliver solar cells. In a still further form of the invention, the exposed sliver solar cell from each clamped wafer in the wafer array can be removed in an array arrangement using static electrical attraction that temporarily bonds the sliver solar cell(s) to the transport or transfer mechanism.

In accordance with the above form of the invention, the sliver solar cells from the wafer are positively engaged at all times to ensure the retention of the correct orientation and polarity of the constituent sliver solar cells. The sliver solar cells can also be directly assembled into sliver raft, sliver mesh raft, or sliver boat sub-modules following separation of the planar array of sliver cells from the wafer, and whilst retaining the orientation, polarity, and relative position of constituent sliver solar cells, thus avoiding any intermediate handling or storage steps involving the separated sliver cells.

In accordance with a further aspect of the present invention there is provided a method of separating sliver solar cells from a single wafer, handling the separated sliver solar cells, and storing the sliver solar cells which have been removed from the wafer frame in some form of bulk storage unit such as a cassette which sequentially presents sliver solar cells with a face at least partially exposed. Separated sliver solar cells may be stored in a plurality of bulk storage units which may subsequently be assembled to provide a grid or array of sliver surfaces in a planar arrangement formed by the accessible sliver solar cell in each unit. This planar arrangement can embody the desired relative location and orientation of sliver solar cells in the raft or boat array.

In accordance with yet a further aspect of the present invention there is provided a method of handling sliver solar cells that have been already removed from the parent wafer frame and are subsequently contained in some form of bulk storage unit such as a cassette which sequentially presents sliver solar cells with a face at least partially exposed. A plurality of bulk storage units, or cassettes, may be assembled to provide a grid or array of sliver cell surfaces in a planar arrangement formed by the accessible sliver solar cell in each unit, with the required uniform spacing between the edges of the sliver cells in the final array provided by the spacing between the storage units or cassettes. This planar arrangement of the cells so presented then embodies the required relative location and orientation of sliver solar cells in the completed sliver raft, sliver mesh raft or sliver boat solar cell array.

In another form of the invention, the sliver solar cell stacks may be assembled in an integral multiple-stack unit, which is preferably effectively a single unit incorporating multiple separate stacks of separated sliver solar cells. The pitch of the stacks of sliver cells is selected according to the required sliver solar cell location spacing or pitch in the final sliver raft, sliver mesh raft, or sliver boat unit.

In the case of a sliver solar cell array assembled from multiple single-stack cassettes, the number of cassettes or bulk sliver cell storage units can be equal to the number of sliver solar cells required to form a sliver raft, sliver mesh raft, or sliver boat sub-module. Alternatively, the sliver cell sub-module array may be constructed using more than one repeated separation and assembly operation from single or grouped single stack cassettes.

In one form of the invention, the exposed or first-presented sliver solar cell from each single-stack cassette, group of single-stack cassettes, or set of individual single-stack cassettes, or integrated multi-stack cassette can be removed by mechanical means such as a vacuum engagement tool. In another form of the invention, the exposed sliver solar cell from each single-stack cassette, group of single-stack cassettes, or set of individual single-stack cassettes or integrated multi-stack cassette can be removed by a fast-cure adhesive which directly and permanently bonds the presented sliver solar cells to the sliver raft cross-beam, sliver mesh raft electrical connecting wires, or sliver boat substrate presented to the exposed sliver solar cell array in the sliver cell stack mechanism.

In a still further form of the invention, the exposed sliver solar cell from each single-stack cassette, group of single-stack cassettes, or set of individual single-stack cassettes, or integrated multi-stack cassette can be removed by a re-useable sticky surface that temporarily bonds the exposed or partially exposed sliver solar cell array to the transport or transfer mechanism. In a still further form of the invention, the exposed sliver solar cell from each single-stack cassette, group of single-stack cassettes, or integrated multi-stack cassette can be removed as a complete sub-module assembly array of sliver cells using static electrical attraction that temporarily bonds the sliver solar cells to the transport or transfer mechanism.

It will be apparent that the sliver solar cell, group of sliver solar cells, partial or complete array of sliver solar cells removed from the single-stack cassette, group of single-stack cassettes, or integrated multi-stack cassette in this aspect of the invention are positively engaged at all times in order to ensure correct orientation and polarity, and maintenance of the correct regular or repeating pattern of spacing between the sliver solar cells in the partial or complete sub-module assembly array. The extracted sliver solar cells can be directly assembled into sub-module assemblies such as sliver rafts, sliver mesh rafts, or sliver boats immediately following separation from the single-stack cassette, group of single-stack cassettes, or integrated multi-stack cassette, thus avoiding any further intermediate handling or storage steps.

In accordance with yet another aspect of the present invention, there is provided a method of handling sliver solar cells contained in a mechanism defined as a sliver cell dispenser cassette. The dispenser cassette is used to mechanically dispense single sliver solar cells into an array of aligned, correctly oriented sliver solar cells with a selected array pitch or repeated pattern of spacing between the sliver cells. The array pitch is selected according to the required placement locations of the individual sliver cells in the sub-module assembly of sliver rafts, sliver mesh rafts, or sliver boats. The sliver cell dispenser cassette preferably releases a single sliver solar cell into a groove or slot machined in an alignment jig made of metal or plastic or other rigid material.

Preferably, the groove or slot locations in the alignment jig have a lateral pitch that matches the relative sliver solar cell locations, or array pitch or repeated pattern of spacing between the sliver cells forming the sliver raft, sliver mesh raft, or sliver boat sub-module assembly. The sliver solar cells are preferably mechanically removed from the base of the sliver cell dispensing cassette by the approaching wall of the groove or slot in the alignment jig as the sliver cell dispensing cassette traverses the groove or slot array in the alignment jig. The groove depth is preferably slightly less than the sliver solar cell thickness, so that only one sliver cell at a time is engaged by the wall of the grooves or slots in the alignment jig and thus removed from the sliver cell dispensing cassette. The width of the grove or slot in the alignment jig is preferably slightly wider than the width of the sliver solar cell so that the sliver solar cell can rest in the groove or slot in the alignment jig, with suitable edge clearance, without jamming which creates difficulties for the removal of the dispensed array, or being crushed by the sliver cell dispensing cassette.

The sliver cell dispensing cassette preferably has a rear gate slightly higher than the top surface, or face, of a sliver solar cell resting in the groove or slot of the alignment jig. This ensures that the sliver solar cell adjacent in the dispenser to the sliver solar cell being dispensed is retained in the sliver cell dispensing cassette until the next vacant groove or slot in the alignment jig is presented by relative motion of the sliver cell dispensing cassette and the alignment jig. The top of the sliver cell dispensing cassette is preferably enclosed and includes a follower-plate and weight or spring mechanism that applies pressure to the stack of sliver solar cells in the sliver cell dispensing cassette.

The pressure on the stack is preferably selected to ensure that the leading edge of the bottom sliver solar cell engages the far side of the groove or slot wall in the alignment jig. Continued pressure on the stack ensures that the bottom-most sliver solar cell rests flat on the bottom of the groove or slot in the alignment jig. Once the sliver solar cell is resting flat on the bottom of the groove, and held there by pressure transferred from the adjacent sliver solar cell in the stack, the rear gate of the dispensing cassette can clear the rear edge and top face of the retained sliver solar cell. This sequence of removal of sliver cells from the stack in the dispensing cassette, and placement of removed sliver cells in the grooves or slots in the alignment jig is repeated for all grooves or slots in the array-forming alignment jig as the dispensing cassette continues a transit of the metal or rigid plastic or polymer alignment jig until all grooves or slots are filled. A trailing double-ended ski mechanism retains the sliver solar cells in the grooves to prevent them flipping or jumping as the rear gate of the sliver cell dispensing cassette and trailing edge of the adjacent sliver solar cell retained in the sliver cell dispensing cassette slips over the front edge of the sliver solar cell retained in in the groove or slot of the alignment jig.

It will be apparent that in this form of the invention the sliver solar cells are removed from the dispensing cassette and retained in a regular planar array or repeating pattern of spacing between the sliver solar cells within the alignment jig without the requirement for individually locating, engaging, and removing single sliver solar cells as is the case with a conventional pick and place process.

Movement of the sliver cell dispensing cassette continues until the number of sliver solar cells required to form a sliver raft, sliver mesh raft, or sliver boat sub-module assembly array have been dispensed into the grooves or slots in the alignment jig. In one form of the invention, cross beams, prepared electrical interconnection wires, or substrates that are required to complete the sliver raft, sliver mesh raft, or sliver boat sub-module array are previously prepared with adhesive in areas where the cross-beam or substrate surface coincides with the sliver solar cell surface. The cross-beams, prepared and bent wires for electrical interconnections, or substrates required to complete the sliver raft, sliver mesh raft, or sliver boat assembly can be presented to the top surface of the array and bonded in place to provide mechanical stability with conventional adhesives such as SMT IR-130 heat-curable adhesive, or bonded in place using conductive epoxies such as heat curable Electrodag 5915 to provide mechanical stability and electrical interconnection, or soldered in place using a conventional reflow operation in order to provide mechanical support and electrical interconnection. More preferably, and advantageously, a selective wave solder process can be used in order to provide mechanical support and electrical interconnection without the requirement for dispensing or screen printing solder paste for subsequent reflow.

Alternatively, the cross beams, prepared and bent electrical wire interconnects, or substrate can be prepared with adhesive material by stencilling or printing or dispensing and then placed in support grooves or support devices aligned with the grooves or slots in the alignment jig. The sliver solar cells are then placed in position over the support structures and electrical interconnection materials in the usual manner with the sliver cell dispensing cassette. The sub-module assembly arrays can then be completed by heat curing or reflow of the solder paste as described above. More preferably, and advantageously, the sub-module assembly formed on cross beams, prepared and bent electrical wire interconnects, or a substrate, can be clamped in the alignment jig, inverted, and a selective wave solder process can be used in order to provide mechanical support and completed electrical interconnection without the requirement for dispensing or screen printing solder paste for subsequent reflow, and without a heat-curing process step to cure adhesives or electrically conductive materials.

The sliver solar cell dispensing on the metal jig may be continuous or semi-continuous. That is, for continuous-type assembly, the sliver rafts, sliver mesh rafts, or sliver boats may be formed in a continuous or contiguous manner in a long metal jig. For semi-continuous assembly, the sliver rafts, sliver mesh rafts, or sliver boats may be formed in a disjoint or semi-detached jig where each grooved section is only as long as the individual sliver raft, sliver mesh raft, or sliver boat assembly. These individual jig sections can be attached to a chain or belt conveyor to provide a linear assembly concept for the assembly of sliver rafts, sliver mesh rafts, or sliver boats.

In the continuous or semi-continuous procedures described above, the same approach to integrating the assembly of cross beams, prepared and bent electrical wire interconnects, or substrate can be incorporated in the continuous or semi-continuous alignment jig. The sliver solar cells are placed in position over the support structures and electrical interconnection materials contained in the continuous or semi-continuous alignment jig sections in the usual manner with the sliver cell dispensing cassette. Processing of the sub-module assembly arrays contained in the individual alignment jig sections can then be completed by heat curing or reflow of the solder paste as described above.

More preferably, and advantageously, the sub-module assemblies formed on cross beams, prepared and bent electrical wire interconnects, or substrates contained within the continuous or semi-continuous alignment jig sections, can be clamped in the alignment jig, inverted, and a selective wave solder process can be used in order to provide mechanical support and completed electrical interconnection without the requirement for dispensing or screen printing solder paste for subsequent reflow, and without a heat-curing process step to cure adhesives or electrically conductive materials. Using this dispensing cassette technique, continuous or semi-continuous alignment jig sections on a conveyor, belt, or chain, inverting the clamped sub-assemblies and completing mechanical support and electrical interconnection requirements using a selective wave solder process provides a continuous, in-line assembly process that completely eliminates the expensive, technically demanding, time-consuming, and yield-compromising steps of stencilling or dispensing, along with expensive materials, cleaning, and waste disposal associated with stencilling and dispensing.

It will be apparent that in the various forms of the invention disclosed above the engaging motion of the vacuum engagement tool with respect to the sliver solar cells in the wafer, single-stack cassette, group of single-stack cassettes, or integrated multi-stack cassette, or the dispensing motion of the sliver cell cassette dispenser with respect to the alignment jig, is always relative to the wafer array, sliver stack, multi-stack cassette, or alignment jig respectively. That is, the vacuum engagement tool may be stationary and the wafer array, single-stack cassette, group of single-stack cassettes, or integrated multi-stack cassette may be moved to remove the presented sliver solar cell or cells singly or in a planar array of sliver solar cells. Similarly, the sliver cell dispensing cassette may be stationary and the grooved alignment jig may be moved to dispense the sliver solar cells into the grooves of the metal alignment jig. Further, the moveable alignment jig may take the form of sub-sections appropriate for the size of a single sliver raft, sliver mesh raft, or sliver boat held on a chain conveyor or some other suitable transport mechanism. If the assembly of sliver solar cells into sub-module assemblies is performed in a continuous manner, the transport mechanism can proceed through the adhesive curing stage and the electrical connection stage or the selective wave solder stage in a linear fashion.

More than one single-stack cassette, group of single-stack cassettes, or integrated multi-stack cassette or cassettes, or bulk storage units may be used to provide a grid or array of exposed or partially exposed sliver solar cell surfaces constituting the accessible sliver solar cells in each unit or collection of units. A number of cassettes or buffer storage units are arranged in a grid or array so that the accessible sliver solar cell in each unit is in the correct location and orientation, relative to other sliver solar cells, to form a sliver raft, sliver mesh raft, or sliver boat assembly. The number of cassettes or bulk storage units in the array may be equal to the number of sliver solar cells required to form a sliver raft, sliver mesh raft, or sliver boat. The exposed, partially exposed, or accessible sliver solar cells from each unit may be removed by mechanical means such as a vacuum engagement tool, fast cure adhesive, a re-useable sticky surface from which the sliver solar cells can be removed after separation from the wafer and subsequent assembly into rafts or boats, electrostatic attraction or any other suitable temporary engagement and release technique, or permanent engagement technique onto permanent sub-module assembly support structures. Irrespective of whether the sliver engagement process is permanent or temporary, the removed collection or planar array of sliver solar cells are directly assembled into sliver rafts, sliver mesh rafts, or sliver boats. During the transfer process, the separated sliver solar cells are retained on the transfer tool with the orientation and relative position or repeating pattern of spacing between the cells is maintained.

The assembly of sliver rafts, sliver mesh rafts, or sliver boats directly from sliver cells contained in the host wafer or separated sliver cells contained in single-stack cassettes, group of single-stack cassettes, or integrated multi-stack cassettes, or sliver dispensing cassettes can be accomplished with small, cheap devices that do not require large-scale accuracy and automation such as devices presently thought to be necessary for large-scale sliver solar cell module assembly.

In accordance with yet a further aspect of the present invention, there is provided a substrate release process, including:
receiving a wafer including a plurality of elongate substrates interconnected by lateral wafer frame portions, the wafer further including proximal and distal wafer frame portions;
removing at least one of said proximal and distal wafer frame portions to expose a face of a corresponding one of said elongate substrates;
engaging at least one of the lateral wafer frame portions to secure the plurality of elongate substrates, without engaging the edges of the plurality of elongate substrates;
applying elongate substrate engaging means to the exposed face of the exposed elongate substrate to engage the exposed elongate substrate; and
moving the elongate substrate engaging means away from the plurality of elongate substrates to release the exposed elongate substrate from the remaining elongate substrates.

In accordance with yet a further aspect of the present invention, there is provided a substrate release process, including:
receiving a plurality of wafers, each of the wafers including a plurality of elongate substrates interconnected by lateral wafer frame portions, the wafers further including proximal and distal wafer frame portions;
removing at least one of said proximal and distal wafer frame portions from each of the wafers to expose a face of a corresponding one of said elongate substrates of each wafer;
engaging at least one of the lateral wafer frame portions of each wafer to secure the plurality of elongate substrates, without engaging the edges of the plurality of elongate substrates;
   wherein the engaged wafers are arranged so that the exposed elongate substrates are presented as an array of mutually spaced elongate substrates.

In accordance with yet a further aspect of the present invention, there is provided an elongate substrate dispensing, process, including:
providing a plurality of mutually spaced elongate substrate storage bins, each of said elongate substrate storage bins having a stack of elongate substrates stored therein, the spacing between the elongate substrate storage bins being selected to provide a desired spacing of elongate substrates in a solar cell sub-module to be assembled from the stored elongate substrates.

In accordance with yet a further aspect of the present invention, there is provided a process for forming a solar cell sub-module for a photovoltaic device including:
dispensing elongate solar cells from an elongate substrate dispensing unit into respective slots of an alignment jig; and
attaching the elongate solar cells to a substrate, crossbeam or electrical interconnects to form the solar cell sub-module.

In accordance with yet a further aspect of the present invention, there is provided an elongate substrate handling system, including:
an elongate substrate dispensing unit for storing and dispensing one or more stacks of elongate substrates; and
an alignment jig having mutually spaced slots for receiving respective elongate substrates dispensed from the storage unit.

In accordance with yet a further aspect of the present invention, there is provided a process for forming a solar cell sub-module for a photovoltaic device including:
engaging a length of electrical interconnect with an engagement tool having a plurality of mutually spaced engagement sections so that only mutually spaced regions of the electrical interconnect are engaged by the tool; and
applying a cutting tool to locations of the electrical interconnect between the engaged regions to cut the engaged electrical interconnect into corresponding lengths of the electrical interconnect.

In this specification, the term ‘plank’ refers to a particular form of elongate substrate which preferably incorporates one or more solar cells, but need not do so. Planks can be created by machining parallel grooves into a wafer to produce a series of parallel elongate substrate referred to herein as planks. The width of the planks is determined by the spacing of the machined grooves and the length of the planks is typically five to twenty times larger than the plank width. The thickness of the plank is determined by the wafer thickness which is usually less than 400 microns.

In yet a further aspect, the present invention provides a process for releasing planks from wafers and mounting them in solar cell modules.

In one form of the invention planks can be partially pre-cut at the ends to facilitate easy snapping out of the wafer frame. An entire array of planks can be stacked in a plank “slab” frame from which individual stack scan be removed and stored in a single stack cassette or a multi-stack cassette.

In another form of the invention, every second plank is removed and stacked in a multi-stack cassette.

In yet another form of the invention, planks are individually removed and stacked in a single-stack cassette.

In another form of the invention, the plank wafer can be held by the top and bottom faces covering the plank array window in a clamp that leaves the four or more portions of the wafer frame exposed. The plank wafer frame is successively removed by snapping the four or more exposed portions.

Several processes can be used to load planks into a storage cassette or dispenser. The cassette can be loaded from the top. In this case, it is important that the top surface of the plank residing or previously stored in the cassette is close enough to the top of the cassette and the plane of the top surface of the clamp, which forms the transfer slide surface, so that the plank cannot flip or jam at an angle in the top of the cassette. The rear edge of the plank entering the cassette is disengaged from the front edge of the plank leaving or about to leave the transfer slide surface. These two requirements can be met by a mechanically linked spring mechanism. The mechanically linked mechanism actuates a dual pair of “walking beams” that grip the edge of the plank cell stack, level with the top loading surface of the cassette, and depress the stack by a preset distance which is the thickness of a plank cell plus the required clearances and tolerances. The plank cell is slid into the cassette, and the process repeats.

In yet another form of the invention, the cassettes are loaded from the base. A walking beam system, similar to the top loading mechanism, raises the stack in the cassette by the required amount to provide the clearance. The new plank is loaded into the base of the cassette. The cycle continues until the cassette is full.

In yet a further aspect, the present invention provides a process for releasing elongate substrates from a wafer incorporating a plurality of elongate substrates interconnected by wafer frame portions, including:
engaging only opposing faces of each elongate substrate, the engaged faces being in the same plane as the wafer surfaces;
removing the wafer frame portions to disconnect the elongate substrates from one another; and
disengaging one of the faces of each elongate substrate, the other face of each elongate substrate remaining engaged.

The present invention also provides a process for releasing elongate substrates from a wafer incorporating an array of elongate substrates interconnected by wafer frame portions, including:
engaging only selected non-adjacent ones of the elongate substrates and disconnecting the engaged substrates from the other elongate substrates in the array; and
depositing the engaged elongate substrates in respective mutually spaced storage bins of a storage unit, the spacing between the storage bins corresponding to the spacing between the engaged elongate substrates.

The present invention also provides a process for releasing elongate substrates from a wafer incorporating an array of elongate substrates interconnected by wafer frame portions, including:
(i) engaging a selected one of the elongate substrates and disconnecting the engaged substrate from the other elongate substrates in the array;
(ii) depositing the engaged elongate substrate in a storage unit; and
(iii) repeating steps (i) and (ii) to form a stack of elongated substrates in the storage unit.

The present invention also provides a storage apparatus for storing elongate substrates in a stacked configuration, the storage apparatus including a translation mechanism for translating a stack of stored elongate substrates to allow receipt of a subsequently received elongate substrate for storage in the storage apparatus.

### BRIEF DESCRIPTION OF THE DRAWINGS

Preferred embodiments of the invention are hereinafter described, by way of example only, with reference to the accompanying drawings, wherein:

FIG. 1 is a schematic plan view of a first preferred embodiment of a solar cell sub-module formed from elongate solar cells and referred to as a “raft” sub-module;

FIG. 2 is a schematic plan view of part of the raft shown in FIG. 1 showing one form of electrical interconnection between the elongate solar cells;

FIG. 3 is a plan view of a second preferred embodiment of a solar cell sub-module referred to as a “boat” sub-module, showing one form of electrical interconnection between elongate solar cells;

FIG. 4 is a plan view similar to FIGS. 2 and 3 illustrating one form of electrical interconnection, suitable for both raft and boat sub-modules, in which conductive paths on the crossbeam or substrate connect the two edges of an elongate cell together; in the lower part of FIG. 4 the solar cells are not shown, to illustrate the conductive paths more clearly;

FIG. 5 is a schematic cross-sectional side view diagram illustrating the use of angled evaporation to partially coat faces of elongate solar cells to provide electrical contact surfaces on both an optically-inactive edge and an adjacent active face of each elongate solar cell;

FIG. 6 is an end view of a elongate solar cell raft or boat sub-module showing one form of mounting onto a supporting crossbeam or substrate the elongate solar cells with electrical contacts on both faces and edges;

FIG. 7 is a diagram showing how elongate solar cells can be mounted onto a heatsinking substrate in a toothlike formation;

FIG. 8 is a plan view of part of a third preferred embodiment of a solar cell sub-module referred to as a “mesh raft” sub-module comprising only elongate solar cells and electrical interconnections therebetween;

FIG. 9 is a plan view of an alternative embodiment of a mesh raft sub-module in which the wire interconnections are aligned along the direction of the array;

FIG. 10 is a photographic image of the raft sub-module having silicon cross-beams and electrical interconnections formed using a selective wave solder process, and thus containing only solder and silicon materials;

FIGS. 11 and 12 are plan and cross-sectional side views, respectively of a preferred arrangement of sliver cells in a single array in a silicon wafer;

FIGS. 13 to 15 are plan views of silicon wafers having alternative arrangements of sliver cells processed into more than one region in each wafer;

FIGS. 16 and 17 are cross-sectional side and plan views, respectively of a first preferred embodiment of a sliver wafer clamp of a sliver handling system;

FIGS. 18 and 19 are plan views of a sliver cell wafer, illustrating the removal of top and bottom frame portions from the wafer to expose top and bottom sliver cells, respectively;

FIGS. 20 and 21 are front and side views, respectively, of a preferred embodiment of a sliver storage device of the sliver handling system;

FIGS. 22 and 23 are cross-sectional side and plan views, respectively, of a second preferred embodiment of a sliver wafer clamp;

FIGS. 24 and 25 are plan and side views, respectively, of a third preferred embodiment of a sliver wafer clamp;

FIG. 26 is a schematic diagram illustrating the application of adhesive tape to the sliver cell array in the wafer clamped by the sliver wafer clamp of FIGS. 24 and 25;

FIG. 27 is a schematic diagram illustrating removal of the sliver cell array from the sliver cell wafer by separating the adhesive tape and the wafer clamp;

FIG. 28 is a schematic diagram of the resulting sliver cell assembly secured by the adhesive tape;

FIG. 29 is a side view illustrating the placement of the sliver cell assembly into the sliver storage device;

FIG. 30 is a schematic diagram illustrating the removal of the adhesive tape from the sliver cells retained within the sliver storage device;

FIG. 31 is a schematic diagram illustrating the set of sliver cells retained by the sliver storage device;

FIG. 32 is a schematic diagram of a sliver cell singulation unit that dispenses single slivers from a set of sliver cells retained by adhesive tape; and

FIG. 33 is a schematic diagram of a sliver cell singulation unit that dispenses single slivers onto a solid jig or frame from a set of sliver cells retained on adhesive tape.

FIG. 34 is a diagram of a processed wafer with one side cut off to expose the sliver solar cells;

FIG. 35 is a diagram of a sliver solar cell wafer with part of the frame removed to allow access to the sliver solar cell array with the wafer held in a clamp;

FIG. 36 is a diagram of an array of sliver solar cell wafers with part of the frame of each wafer removed to allow access to the sliver solar cell array within the wafer;

FIG. 37 is a diagram of an array of sliver solar cell wafers with part of the frame of each wafer removed to allow access to the sliver solar cell array within the wafer;

FIG. 38 is a diagram of an array of sliver solar cell stacks removed from processed wafers and stored in a multi-stack cassette;

FIG. 39 is a diagram showing one possible implementation of removal of a single sliver solar cell from a stack in an array of stacks in a multi-stack cassette;

FIG. 40 is a diagram showing one possible implementation of removal of sliver cells and construction of a sliver raft array of sliver solar cells from a multi-stack cassette;

FIG. 41 is a diagram of one possible implementation of a sliver solar cell dispensing cassette;

FIG. 42 is a diagram illustrating how sliver solar cells are dispensed from the sliver dispensing cassette into an alignment jig;

FIG. 43 is a diagram showing one possible implementation for in-situ sliver raft sub-module assembly integrated with the dispensing process in an alignment jig;

FIG. 44 is an image of a prototype sliver dispensing cassette showing an array of sliver solar cells located in an alignment jig;

FIG. 45 is a diagram showing a plan view of an array of wires strung across a frame, the dimensions of which span a sub-module array of slivers;

FIG. 46 is a diagram showing a plan view of an array of tweezers positioned to grip the wires strung on the frame;

FIG. 47 is a diagram showing a plan view of a set of anvils introduced under the wires strung on the frame;

FIG. 48 is a diagram showing a plan view of an array of cutting blades positioned above the wires, the anvil array below the wires, and the tweezers positioned ready to grip the wires strung on the frame;

FIG. 49 is a diagram showing a plan view of an array of tweezers, with the tweezers now gripping the array of short, cut wires;

FIG. 50 is a diagram showing a plan view of an array of tweezers gripping the array of short, cut wire sections with the notched plates inserted into the array of short wire sections, ready to bend the protruding ends of the short-wire array;

FIG. 51 is a diagram showing a detailed plan view of part of an array of slivers introduced into the array of tweezers gripping the array of short, cut wire sections which are held in close proximity to the sliver electrode. The wires are attached to the sliver electrodes mechanically and electrically by using solder or a combination of solder and adhesive;

FIG. 52 is a diagram of a plan view of another form of a sliver mesh raft in which adjacent interconnections between sliver electrodes are staggered or offset;

FIG. 53 is a plan view of a preferred embodiment of a sliver cell module including bus bar and cell interconnects;

FIG. 54 is an enlarged view of a portion of FIG. 53;

FIG. 55 is a cross-sectional side view of the sliver cell module portion taken along the line B-B′ of FIG. 54;

FIG. 56 is a schematic diagram illustrating the formation of the bus bar of the sliver cell module;

FIG. 57 is a photographic image of the bus bar and nearby slivers;

FIG. 58 is a photographic image of the bus bar and nearby slivers, illustrating the absence of corrugations near the point of electrical connection;

FIG. 59 is a schematic diagram illustrating the simultaneous removal of an array of planks from a wafer in a single step using a mechanical separation head (vacuum, electrostatic, sticky, re-useable etc) and subsequent stacking as a complete contiguous array;

FIG. 60 is a schematic diagram illustrating the removal of planks from a wafer and stacking in a mutually spaced (2×) stacking array;

FIG. 61 is a schematic diagram illustrating the individual removal of planks by a mechanical separation head (vacuum, electrostatic, sticky, re-useable etc) and stacking in a single-stack cassette;

FIG. 62 is a schematic diagram illustrating the exposing of planks by removing one or more portions of the wafer frame;

FIG. 63 is a schematic diagram illustrating how planks once exposed can be individually removed and stacked in a single-stack cassette;

FIG. 64 is a schematic diagram illustrating how planks can be loaded into a mechanical stack from the base using a clamp and lift mechanism; and

FIG. 65 is a schematic diagram illustrating how planks can be stored in a single cassette stack using a walking beam system.

### DETAILED DESCRIPTION

### Sub-Module Formation

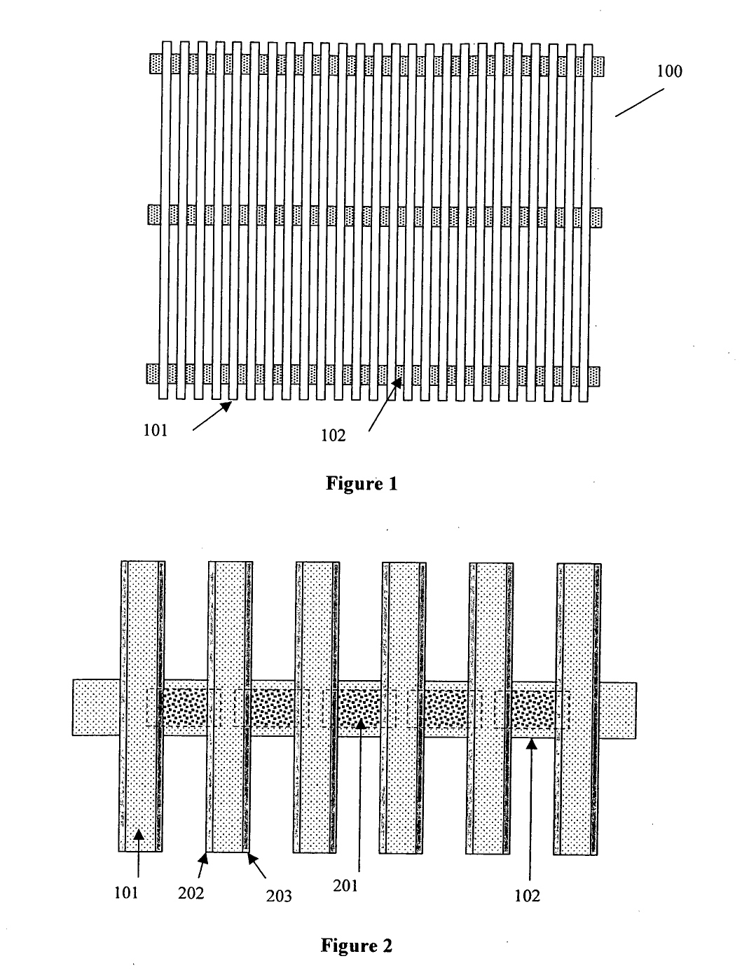

Referring to FIG. 1, elongate solar cells 101 and crossbeams 102 are assembled to form a sub-module referred to herein as a “raft” sub-module 100. Although the spacing between adjacent elongate solar cells 101 is shown in FIG. 1 as being approximately equal to the width of each cell, in the general case the spacing between cells 101 can range from zero (whereby adjacent cells abut one another) up to several times the width of each cell. The crossbeams 102 can be made of any material and are preferably thin, not electrically conductive (or are coated with an insulating material) and can be readily and selectively coated with conductive tracks. For example, thin strips of silicon from 30 microns to 100 microns thick, 1 to 3 mm wide, and 2 to 20 cm long are particularly suitable for the crossbeams 102. The cells 101 are mechanically adhered to the crossbeams 102 using adhesive or metal solder or conductive epoxy or a similar material.

Referring to FIG. 2, serial or parallel electrical connections between the solar cells 101, connecting the n-contact 202 of each cell 101 to the p-contact 203 of the adjacent cell can be made by depositing a conductive material 201 at mutually spaced regions on the crossbeams 102. The conductive material can be an evaporated metal film, bonded metal foil, B-stage conductive adhesive film, or conductive epoxy. If the material from which the crossbeams 102 are fabricated is not itself electrically insulating, then an insulating material can be deposited on the crossbeams 102, either between the spaced regions of conductive material 201, or deposited in a continuous layer along the length of the crossbeams 102 prior to deposition of the conductive material 201, so that the underlying insulating material is exposed in the gaps between the conductive material 201. Electronic devices such as bypass diodes or logic devices can be included in the circuit where appropriate.

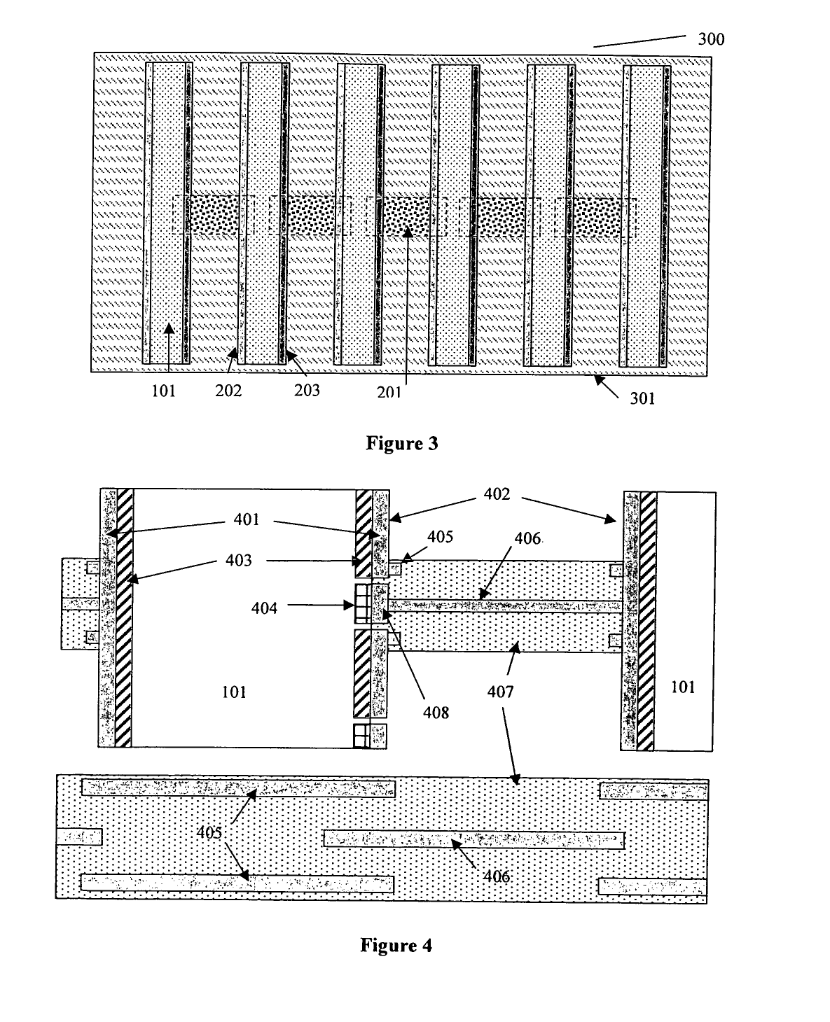

Referring to FIG. 3, the solar cells 101 can be assembled on a continuous or semicontinuous substrate 301 to form a type of sub-module 300 referred to herein as a “boat” sub-module. In certain applications, transparent or semi-transparent material can be used for the array support material, in which case the material can form a superstrate support for the array of elongate solar cells, allowing the solar cells to be illuminated through the transparent superstrate. As in the case of rafts described above, the spacing between the adjacent elongate solar cells in the array can range from zero to several times the width of each elongate solar cell. The continuous or semi-continuous substrate, or continuous or semi-continuous transparent or semi-transparent superstrate, 301, is preferably a non-conductive material (or is coated with an insulating material), can be readily coated with a continuous or intermittent electrically conductive track 201, and has a thermal expansion coefficient sufficiently similar to that of silicon to avoid damage during thermal cycling. Silicon and borosilicate glass are suitable substrates, and borosilicate glass is a suitable superstrate, particularly for rigid support structure applications. However, it will be apparent that a wide variety of other materials can alternatively be used.

Still referring to FIG. 3, the solar cells 101 can be assembled on a continuous or semicontinuous flexible or compliant substrate 301 to form a type of sub-module 300 referred to herein as a “flexible boat”. In certain applications, a flexible transparent or semi-transparent material can be used for the array support material, in which case the flexible material is used to form a superstrate support for the array of elongate solar cells. The spacing between the adjacent elongate solar cells in the flexible array can range from zero to several times the width of each elongate solar cell. The continuous or semi-continuous flexible substrate, or continuous or semi-continuous transparent or semi-transparent flexible superstrate 301 is preferably a non-conductive material (or is coated with an insulating material), and can be readily coated with a continuous or intermittent electrically conductive track 201.

Advantageously, an optically transparent substrate material can be used to allow a rear reflector to be applied either to the sub-module assembly or to the photovoltaic power module in order to recover some of the light which has passed through the gaps in the array of elongate solar cells forming the flexible boat. Additionally, transparent substrate or superstrate materials can be used to form transparent or semi-transparent photovoltaic power modules, based on flexible boat sub-assemblies, for use in such applications as architectural installations, building integrated installations, highway noise barriers, or other applications where transparency or true bifacial photovoltaic power modules are desired.

Because the flexible material used for the substrate or superstrate of flexible boats can be quite thin, and also suitably compliant, the thermal expansion coefficient does not have to be as well-matched to that of silicon, as was the case for the rigid support structures such as rigid boats and some forms of rafts where rigidity in a planar, two-dimensional aspect, may be required.

Polyethylene teraphthalate (PET), Teflon-based films such as Tefzel®, temperature-resistant polymers such as members of the polyimide family commercially available in forms such as Kapton® film, sheet, or tape, are examples of suitable substrate materials that are temperature stable, have widely differing coefficients of thermal expansion, and yet form sufficiently stable substrate structure materials. Similarly, these materials can also be used for forming superstrate support structures providing that the transparency requirements are met. Practically any pliant material with suitable thermal, mechanical, chemical, and optical properties, lifetime, and stability under typical PV operating conditions, and that will not place excessive thermal expansion mismatch stress on the boat during thermal cycling, can be used.

A plurality of elongate solar cells formed by the processes described in Scheibenstock or the Sliver® patent application can be used to form photovoltaic rafts, mesh rafts, or boats that have a similar size to, and can directly substitute for, conventional solar cells—albeit with substantially different current and voltage characteristics. Elongate solar cells, made from materials other than silicon, such as GaAs, can also be used. The solar cells can be electrically interconnected in series, in parallel, or a mixture of series and parallel, to deliver the desired raft, mesh raft, or boat sub-module output voltage and corresponding current. If the raft, mesh raft, or boat sub-module output voltage is sufficiently large that the rafts, mesh rafts, or boats can be connected in parallel, or even a small number of these sub-module assemblies connected in series to form groups subsequently connected in parallel, then the effect on module output of a raft, mesh raft, or boat that has a low current (for example, caused by shading) will be less than in a conventional photovoltaic module where a single large cell of comparable size to the sub-module assembly of a plurality of elongate solar cells is partially shaded.

An additional use for conductive tracks on the crossbeam or substrate of a raft, mesh raft, or boat sub-module is to electrically connect the electrode on one long edge of a elongate solar cell to the electrode on the other edge of the same elongate cell. For example, the n-contacts (the negative electrode) on one edge of an elongate cell could be connected to n-contacts on the other edge of the same cell. The p-contacts (the positive electrode) on one edge of the elongate cell could be connected to p-contacts on the other edge of the same elongate solar cell. The n and p contacts on the particular elongate solar cell would remain electrically isolated from each other to avoid short-circuiting the cell.

One reason for connecting the electrical contacts or electrodes on the two remote edges of the same elongate solar cell together electrically is to reduce electrical resistance losses arising from current having to cross the width of the elongate solar cell. This is particularly important for elongate solar cells as the width of the cell increases, or where elongate solar cells are designed for use under concentrated sunlight where the current flow is high because the illumination intensity is high. For any given current, the resistance loss within the cell between the two electrodes is proportional to the square of the width of the elongate solar cell. However, if n contacts are present on both long edges and p contacts on one edge alone, or p contacts present on both edges and n contacts on one edge alone, then the effective “electrical” width of the cell (for electrical resistance purposes) is halved, and the resistance loss within the elongate solar cell is therefore quartered. An elongate solar cell with this configuration of contacts can be twice as wide, and yet have the same resistance loss as, an elongate solar cell of standard design width having only n-contacts on one edge and p-contacts on the other edge.

FIG. 4 shows one method of using the crossbeams 407 of a raft to electrically connect the two edges of the same polarity 401 of an elongate solar cell together. A similar function could be achieved using a boat substrate rather than a crossbeam, where the same electrical interconnections are performed on regions of the surface of the boat substrate or transparent boat superstrate. In this case only the n-contacts 401 of the n-diffusion 403 on each edge of the elongate cell 101 are electrically connected using the tracks 405 on the cross beam 407. This arrangement is suitable for an elongate solar cell in which electrical resistance in the n-type diffused emitter (which in some elongate bifacial solar cells covers the broad face of each side of the cell) dominates. If electrical resistance in the substrate is also an important consideration, then both n and p contacts can be present on each edge and can be electrically connected in order to reduce or minimise the electrical resistance.

Series connections between adjacent cells 101 in the elongate solar cell raft sub-module assembly are established from the p-contact 408 on the p-diffusion 404 of one cell, to the n-contact 402 on the adjacent cell, via the pre-formed track metallisation 406 on the substrate or transparent superstrate material. Some types of elongate solar cells have metallisation deposited for electrodes and electrical contacts on the edges of the solar cell. During the assembly of raft, mesh raft, or boat sub-module assemblies, it is sometimes convenient that the electrode metallisation of the elongate solar cells wraps around onto one face of the solar cell immediately adjacent to the edge, but preferably not onto the other, or opposite, face which is also immediately adjacent to the edge but which will be directed towards the top or sunward side of the sub-module assembly during operation when incorporated in the solar power module.

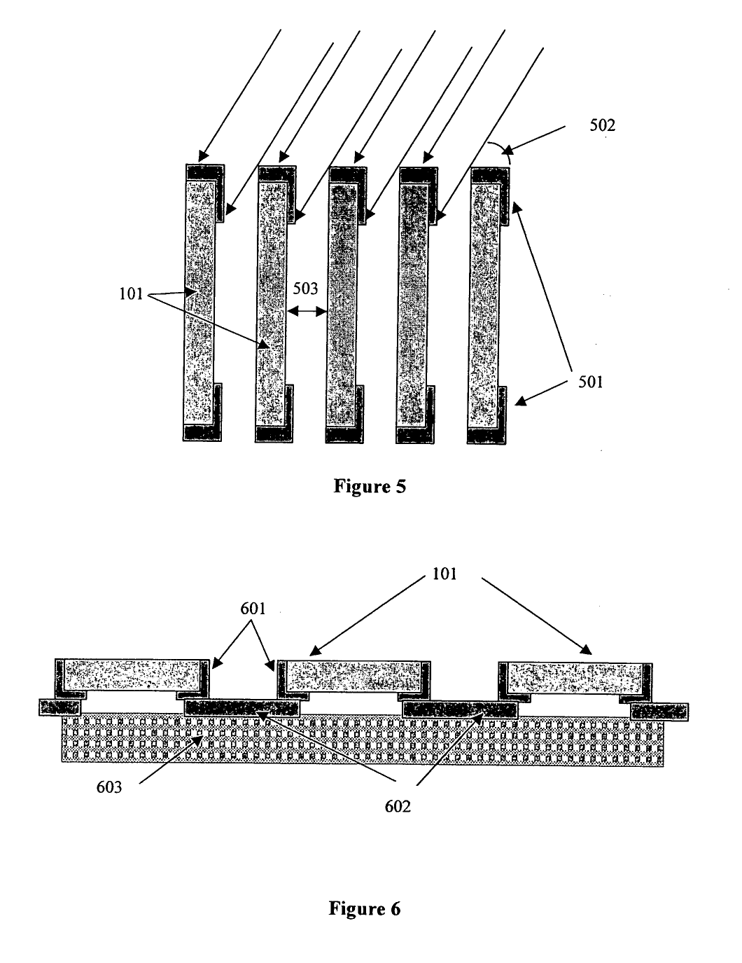

Referring to FIG. 5, a suitable wrap-around electrode can be formed on adjacent surfaces of each solar cell by the angled evaporation of metal. Selection of the angle of evaporation 502, and the spacing 503 between the adjacent faces of the elongate solar cells 101 during evaporation allows the degree or extent of metallisation across the face 501 of the elongate solar cell adjacent to the exposed edge to be controlled. This arrangement can be used in conjunction with shadow-masking along the direction of the length of the elongate solar cell to cause the partial metallisation to be intermittent so that shading of the solar cell by the metal during operation is proportionally reduced. The solar cells can be held in a jig for the purpose of partial metallisation described above. Some methods of manufacturing solar cells, such as the Sliver® process described in the Sliver patent application, naturally produce an array of cells as shown in FIG. 5, prior to their separation from the wafer frame, as described above.

Referring to FIG. 6, elongate solar cells 101 that have partial metallisation on the cell face 601 are suitable for applications where the elongate solar cell is to be soldered or otherwise directly electrically connected to a substrate or superstrate 603. The electrical interconnections can be established using conventional lead-tin solder, or lead-free solder, or conductive polymers, or conductive epoxies, or conductive elastomers applied directly to conductive tracks 602 on the crossbeams or substrate 603. The conductive tracks 602 can be applied to, or formed on, the crossbeams or substrate beforehand by screen printing, masked metal evaporation, direct writing or printing of conductive inks or pastes or organometallic materials by inkjet printing, pad printing, B-stage transfer processes, or other suitable material transfer techniques.

The connection 602 between the solar cells and the crossbeams or substrate can be a multi-purpose connection that provides electrical connection, thermal connection, and mechanical adhesion. For example, elongate solar cells can be secured solely by solder, which provides all the appropriate electrical, thermal, and mechanical properties. Furthermore, this avoids the need for any other form of adhesive, and the solder operation is performed without requiring any form of stencilling, printing, or dispensing. This is a very important and extremely advantageous feature, since dispensing or stencilling of solder paste on the scale necessary for the large-scale production of sub-module assemblies would be an expensive process with respect to infrastructure tools, consumables and materials, time, and waste disposal.

Eliminating the solder paste application step simplifies the assembly process by removing a series of slow process steps such as printing, reflow, and cleaning, tool cleaning, consumables, and waste handling, along with associated yield and reliability issues. The entire solder process used to form standard solar cell assemblies, is thus replaced by a single, clean, very fast, reliable, high yield, and simple process step that forms solder interconnections without the requirement for adhesives, without the requirement for expensive tools, without the requirement for additional expensive materials, without the requirement for additional complicated handling steps, and without the requirement for additional waste handling and disposal. A particularly advantageous solder process is described in Australian provisional patent application No. 2005903172, filed on 17 Jun. 2005 (“the solder process patent application”), the entire contents of which are incorporated herein by reference.

If the elongate solar cells are spaced apart from one another when mounted on the crossbeams or substrate, then some of the sunlight entering the photovoltaic power module will strike the crossbeams or substrate. The crossbeams or substrate can be textured or roughened, and can be coated with a reflective material, so that most of this light is reflected and scattered in such a way that a large fraction of the light is trapped within the photovoltaic module and has a high probability of intersecting another elongate solar cell within the module. In particular, if the crossbeams are mounted away from the sunward surface, then the effective shading of the crossbeams is reduced.

It can be advantageous to space the solar cells apart from one another. For example, this reduces the number of solar cells required per square metre of solar power module area. Provided that a reflector is placed behind the solar cells, then much of the incident light that passes through the gaps between adjacent cells will be reflected, and may be trapped by total internal reflection, in which case it will subsequently intersect a solar cell. In the case of a sun-tracking concentrator receiver, the range of angles of incident light is considerably smaller than in the case of a non-tracking photovoltaic system. This allows a suitable rear reflector to be designed with much higher performance than in the case of a non-tracking system (as allowed for by the fundamental laws of optics).

It can also be advantageous to space the elongate solar cells apart from one another in order to specifically ensure a more uniform distribution of light onto each surface in the case of a sub-module assembly of bifacial elongate solar cells. For example, in concentrator receiver systems, electrical series resistance losses in the emitter of a bifacial elongate solar cell constitute a significant loss mechanism for the system. If half of the light can be steered to the surface away from the sun, then the series resistance losses in the elongate solar cell, and the sub-module assembly, will be halved. In photovoltaic module applications that require the constituent solar cells to be heat-sunk, the elongate solar cells can be thermally connected to the crossbeams or substrate. In raft or boat sub-module assemblies, this thermal connection can be accomplished using thermally conductive adhesive, or very thin layers of conventional adhesive such that the thermal resistance is sufficiently small, or by means of the material used to create electrical connections between the elongate solar cells and between the elongate solar cells and the substrate or crossbeam. In particular, the electrical interconnections can be established using the solder processes described above and in the solder process patent, which also provide excellent thermal contact of the elongate solar cells to the crossbeams or substrate. In turn, the crossbeams or substrate can be attached to a suitable heat sink in order to complete the extraction of excess heat from the elongate solar cells. The use of thin electrically insulating layers allows for good thermal connection between the solar cells and the heat sink without also providing electrical conduction between the elongate cells and the crossbeams or substrate.

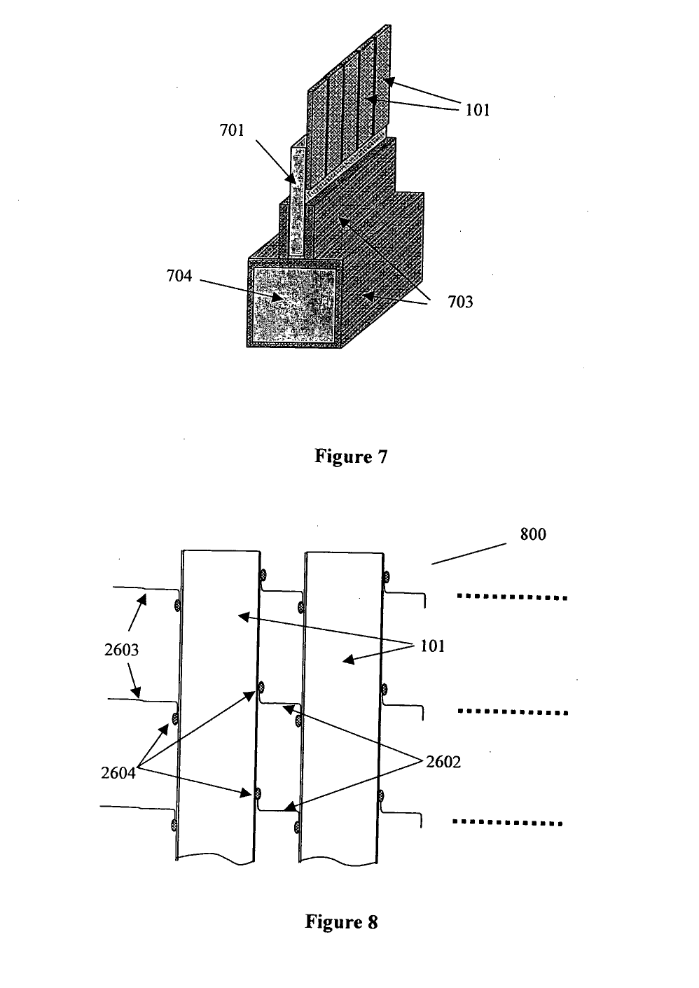

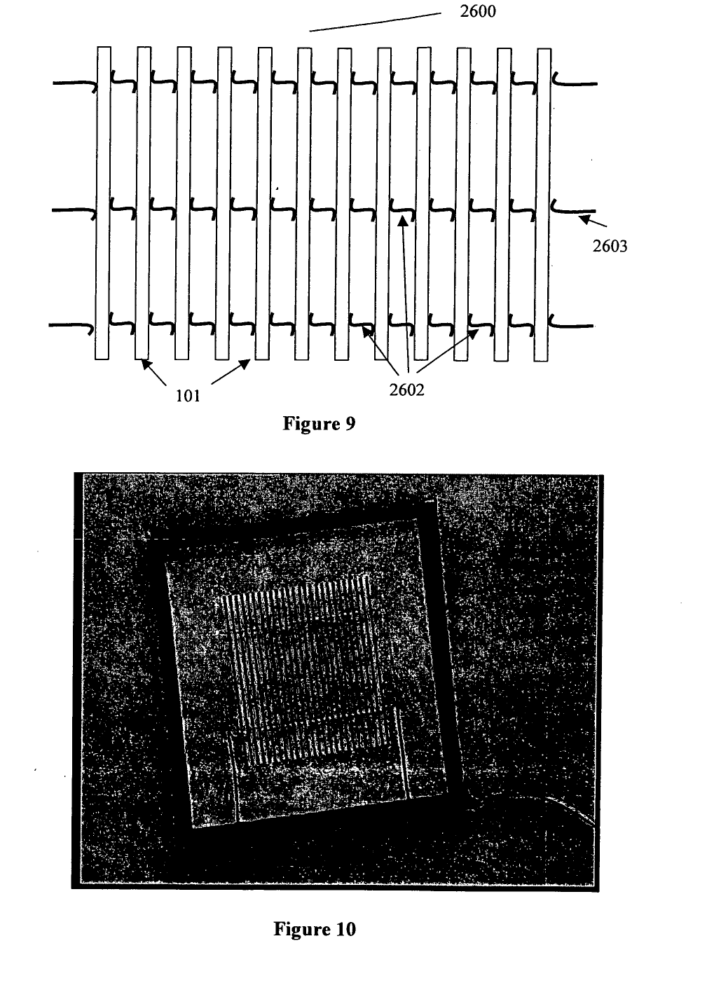

Silicon is a highly thermally conductive material. Even when, illuminated by concentrated sunlight, it is unnecessary that the whole of one surface of the elongate solar cell be directly connected to a heat sink. Heat will conduct laterally across the sub-module assembly, along the length of constituent elongate solar cells to a region where heat sinking is accomplished. In the case where the elongate solar cells are electrically connected edge-to-edge, such as in some embodiments of boats, not every elongate solar cell may need to be connected to a heat sink. Heat can flow from one elongate solar cell through the electrical connection to an adjacent elongate solar cell that is thermally attached to the heat sink. In some cases, heat can flow in this manner across several elongate solar cells until a cell that is attached to a heat sink is reached. Referring to FIG. 7, in an alternative configuration the elongate solar cells at 101 are mounted on a thermally conductive substrate or heatsink 701. The substrate 701 is preferably made of silicon or some other thermally conducting material having a thermal expansion coefficient substantially compatible with the elongate solar cells 101. The substrate 701 is bonded to a thermally conducting extrusion 703 having a hollow or cavity 704. A heat exchange fluid (such as air, water, glycol etc.) can be circulated in the cavity at 704. The sub-system assembly shown in FIG. 7 can be used as a micro-receiver in a solar concentrator system. Such a sub-system may contain any number of elongate solar cells depending upon voltage output requirements.

In an alternative embodiment, as shown in FIG. 8, a sub-module assembly, referred to as a “mesh raft”, is formed by a plurality of elongate solar cells held in place by the electrical interconnection materials 2602 alone, typically formed from thin, pre-bent lengths of copper wire or similar material, fully removing the requirement for a metallised conductive track as well as the supporting structure provided by the cross-beam or substrate.

The electrical interconnections 2602 between the elongate cells 101 are formed from thin wires, which in some implementations may be thicker than the elongate solar cells. The individual interconnect wires 2602 are formed from a number of single lengths of wire, each longer than the distance between the adjacent elongate solar cells of the mesh raft array. Details of the formation of these wire interconnects are described below.

The short wire lengths forming the electrical interconnections 2602 may be “S”-shaped as shown in FIG. 8, or “U”-shaped, or any other shape that provides arms that run along the elongate solar cell electrodes for a sufficient length to enable the formation of a reliable electrical connection 2604 between the electrodes of adjacent elongates by means such as soldering, or bonding with conductive epoxy, or conductive elastomer, or other suitable electrically conductive material, and an intermediate section 2602 spanning between adjacent elongate solar cells in the mesh raft assembly between the two contact arms terminating at the electrodes and conductive material 2604.

The wire interconnects for the entire mesh raft are formed in a highly parallel process which avoids the requirement of picking or placing individual short wires used to establish elongate cell interconnects. Details of the formation of these wire interconnects are also disclosed in the International Patent Application referenced above.

Advantageously, if conductive epoxy, conductive polymer materials, or conductive elastomer materials are used for electrical interconnection, the mechanical and electrical connections can be decoupled. Mechanical integrity can be achieved by bonding the wire 2602 to the electrode of the elongate solar cell with adhesive, or other conductive or non-conductive material over only a short section of the contact length of the wire arm and the electrode. Electrical connection 2604 and improved mechanical integrity can be provided later at a more convenient time and using a more convenient and reliable application process for the electrically conductive material without the additional requirement for external mechanical restraint of the elongate solar cells and the wire interconnects. Alternatively, a soldering process can be used to provide electrical interconnection during a subsequent assembly process stage.

Preferably, the electrical connections are established using a wave solder process and more preferably a selective wave solder process that eliminates the requirement for the intermediate adhesive step. With a suitable clamp, the selective wave solder process can provide mechanical constraint and electrical interconnections for mesh rafts constructed from elongate solar cells in a process similar to that described above for rafts, as described in the solder process patent application.

The mesh raft 800 described above is particularly suitable for flexible module construction. Elongate solar cells are quite flexible along their length, particularly thin elongate cells, and can be bent in a curve normal to a elongate face with a radius of curvature of as little as 2 cm, depending on their thickness. However, elongate solar cells are not at all flexible in the plane parallel to a face, even if the cells are only a few hundred microns wide, and will shatter before any bend is visible.

However, very thin wires are also very flexible, and, very importantly for flexible module applications, will bend equally in all directions normal to the length axis of the wire. A grid of elongate solar cells, such as a raft with elongate crossbeams is quite flexible in the longitudinal direction along the length of the elongate cell array when the array is bent in a curve lying in a plane normal to the face of the elongate-solar cells, and also in the transverse direction along a curve lying in the same plane of orientation as for the thin elongate cross beam. However, the elongate cell and elongate cross-beam array, when bonded in a grid, is significantly less flexible in a plane included to the longitudinal axis of the elongate solar cells and the crossbeam. The introduction of the thin, short-wire interconnects, which provide mechanical support and restraint, as well as electrical interconnection, relieves stresses introduced by bending in the plane of the mesh raft array.

The sub-module assemblies described herein provide a number of advantages over the prior art. In particular, they do not require expensive equipment and high-level automation control that would be necessary to achieve precise positioning of individual elongate solar cells over large areas.

The integral sub-module assemblies of elongate solar cell rafts, mesh rafts, or boats are a convenient collective form of elongate solar cells that allow easy subsequent assembly of solar power modules, and which can be regarded for all intents and purposes as high voltage conventional cells, using only very slight modifications of conventional equipment, materials, and handling processes.

The use of thin-wire interconnects for mesh raft sub-module assemblies significantly reduces the shading of the elongate solar cells, particularly shading of sections of the rear surface of elongates cells where the elongate solar cells are bonded to crossbeams, and eliminates the requirements for the preparation and metallisation of raft crossbeams.

Flexible, fully symmetric bi-facial modules can easily be constructed using the thin-wire mesh raft sub-module assembly process described herein, which provides thin assemblies of electrically interconnected elongate solar cells which have flexibility in many planes.

### Formation of Electrical Connections

As shown in FIGS. 1 and 2, a sliver cell photovoltaic module includes a glass, polymer or resin-based substrate 102 having attached to it an array of sliver cells 104. The sliver cells 104 are bonded to the substrate 102 using a non-conductive, preferably transparent adhesive 302 such as Dymax 429 or Dymax 4-20417, which are highly transparent UV-curable adhesives from the Dymax Light-Weld range. Highly transparent adhesives are preferred because they also provide optical coupling to the sliver face directed towards the substrate 102. However, this bonding can alternatively be achieved using anodic bonding, bonding with a PMMA-type adhesive, or a suitable two-part or single-part heat- or UV-curable epoxy. Furthermore, the bonding material need not be transparent if the bifacial nature of the sliver cells is not utilised, such as is the case with some concentrator receiver applications. The sliver cells 104 are electrically interconnected by cell interconnects 106 transverse to the longitudinal axes of the sliver cells 104 and bus bars 108 parallel to these axes. The bus bars 108 are made from pre-tinned copper, but can alternatively be made from other metallic materials. Copper is preferred for its high conductivity, and the tinning, which reduces oxidation of the bus-bar surface, is preferably a silver-content solder such a 62/36/2 lead/tin/silver solder. However, alternative forms of solder, including any solder from the lead-free solder range, can be used, and the tinning can include other solders, conductive epoxies, conductive polymers, conductive silicones, conductive inks, and other protective and conductive coatings. The cell interconnects 106 are formed by a single part heat-curable conductive epoxy adhesive such as Acheson Electrodag 5915 or Elecolit 3043, or a two-part conductive epoxy such as Acheson Electrodag 5810, or a silver-content solder such a 62/36/2 lead/tin/silver solder, or a lead-free solder such as a solder from the SynTECH-LF range, but can alternatively be formed from another conductive material or combination of conductive materials.

Any of the electrical interconnections can be alternatively formed using solder, wire-bonding, or anodic bonding where electrical conduction paths have been formed on the glass substrate, or by the application of a conductive material such as colloidal silver paste, electrically conductive epoxy, electrically conductive silicone, electrically conductive inks, or electrically conductive polymers. These materials can be deposited using any one of a variety of techniques, including stencilling, screen-printing, dispensing, pump-printing, ink-jet printing, or stamp-transfer methods, after the cells 104 have been placed on the substrate 102. Alternatively, the cells 104 can be placed over pre-formed interconnects already fixed to the substrate or superstrate 102. These pre-formed interconnects form the electrical interconnections between the sliver cells 104 in the array and also between the sliver cells and the bus bar 108 used to link sections of the array of sliver cells together to form an electrical circuit.

As above, these interconnects need not be formed by the same conductive material, either within the cell array, or between the cell array and the bus-bar or array sub-module interconnections, and may comprise a single conductive material or any combination of materials such as those described above.

For example, cell interconnections can be established with conductive epoxy and the bus-bar electrical connections established with solder. Alternatively, cell interconnections can be established with solder and the bus-bar electrical connections established with conductive epoxy. Furthermore, hybrid interconnections can be used; for example, by soldering to a conductive epoxy or silver-loaded ink material, or using a conductive compound to connect to a solder track or joint. Furthermore, the sliver cells 104 can already be electrically interconnected in a sub-module assembly prior to the sub-module assembly being mounted on the substrate 102 or electrically connected to other sub-modules or main bus-bar assemblies, and the resultant array of sub-modules can then be electrically interconnected using a selection or combination of the above-mentioned materials.

Any of the above techniques, or combination of techniques, can be used to connect sections of the module or sub-module, or individual slivers or parts of a sliver array, to a bus bar 108 or cell interconnect 106 that electrically interconnects sections of the module.

As shown in the cross-sectional view of FIG. 3, the sliver cells 104 are bonded to the glass or polymer or resin-based substrate 102 with adhesive 302. The thickness of the substrate 102 is typically anywhere from a fraction of a millimetre to several millimetres. After bonding and forming electrical interconnections, a lamination process is used to deposit and cure an EVA encapsulating layer 304 over and around the module components, and under a 1.1 mm cover glass or other suitable clear protective film such as Tefzel. This lamination process encapsulates and seals the module components and bonds the active component layer between and to the glass substrate and superstrate layers.

Because the sliver cells 104 are directly attached to the substrate 102, stresses in the various components of the module can be produced by changes in temperature. The coefficients of thermal expansion of crystalline silicon and glass are around 2.5×10⁻⁶° C.⁻¹ and 9×10⁻⁶° C.⁻¹, respectively. Accordingly, if the substrate 102 is made of glass, the rates of expansion and contraction of the sliver cells 104 and the substrate 102 are comparable, at least to within a factor of two or three, and can be accommodated by the adhesive 302. However, polymers have coefficients of thermal expansion of the order of ten times greater than glass. Consequently, standard adhesives are unable to accommodate the resulting degree of differential thermal expansion.

In any case, the coefficient of thermal expansion of the metallic bus bar 108 is substantially larger than those of crystalline silicon and glass, being of the order of 17×10⁻⁶° C.⁻¹, and cannot be accommodated by standard adhesives. Commercial photovoltaic modules are subjected to reliability testing, including thermal cycling over the temperature range of 40° C. to +90° C., which would result in a total differential excursion of 1.04 mm per metre length of module for a glass substrate and copper bus bar. A straight metallic bus bar would expand and buckle, or shrink and tear, due to its greater coefficient of thermal expansion relative to the substrate 102 and slivers 104. Furthermore, even if such buckling and tearing could be avoided, the stresses produced by thermal cycling can lead to long-term module failure due to work-hardening and subsequent brittleness of the bus bars 108.

However, the bus bars 108 in the photovoltaic module are not straight and planar, but include alternating corrugated regions 110 and planar regions 114 along their longitudinal axes, as shown in the cross-sectional view of FIG. 4. The length of each region is such that the planar regions 114 are aligned with the cell interconnects 106, as shown in FIGS. 1 and 2. This allows the bus bars 108 to be physically attached and electrically connected to the cell interconnects 106 at these planar regions 114 by the conductive adhesive or solder joints of the cell interconnects 106, as shown in FIG. 4. However, the corrugated regions 110 between the attachment locations are not attached to the substrate 102 and thus allow the bus bars 108 to expand and contract during thermal cycling whilst avoiding excessive stresses that may otherwise detach the planar regions 114 from the substrate 102 and cell interconnects 106. Thus the corrugated regions 110 define an indirect path that provides stress relief between the planar regions 114 attached to the substrate 102 by way of the conductive adhesive or solder joints of the cell interconnects 106. This indirect path accommodates the different rates of thermal expansion of the bus bar and the substrate, and thereby maintains the electrical connection between the cell interconnects 106 over a wide range of temperatures, and in particular over the 40° C. to +90° C. temperature range experienced during reliability testing.

FIGS. 6 and 7 are photographic images of the preferred bus bar stress relief profile. The slivers 104 are 1 mm wide and the bus bar 108 is 1.25 mm wide. The stress relief corrugations 110 are at a 2 mm pitch and are not symmetrical in cross section, although symmetrical corrugations are still effective in providing stress relief.

FIG. 4 shows a region of the module where the bus bar 108 is bonded to the substrate surface. The electrical connection is made to planar regions 114 of the bus bar 108 in order to provide better bonding of the bus bar 108 to the substrate 102, and to provide a more secure electrical connection between the cell interconnects 106 and the bus bar 108.

Depending on the bonding material and the range of differential thermal expansion between the components being bonded, it is possible to omit the planar regions altogether to provide a bus bar that is corrugated along its entire length, thus avoiding any need to align the planar regions with the cell interconnects 106.

Although a particular configuration of bus bars and other module components has been described above, it will be apparent that alternative configurations can include variations to provide a desired degree of stress relief.

For example, bonding of the bus bar 108 to the substrate at or near the point of electrical connection can be achieved or supplemented using a poorly conducting or even a dielectric material, in cases where the electrical connection is established using conductive ink or other conductive material that does not have sufficient strength to securely bond the bus bar 108 to the substrate. In this case, the electrical connections are made close to, adjacent, or even overlaying the physical attachment material which may be a poor conductor or even an insulator.

In general, it is preferable to ensure that the vertical heights of the module components assembled on the substrate or superstrate are as uniform as possible across the entire module so that the top surfaces of these components lie in a single plane in order to avoid generating internal stresses in the glass or polymer or resin-based substrate and superstrate cover during and following the module lamination process. For example, a localised region of cell components thicker than its surrounding regions can be caused by, for example, a wire or a line of thicker cells or a thicker deposit of conductive material or bonding adhesive. The thicker region can cause the overlying portion of cover glass or superstrate 306 to deform so as to assume an outwardly convex surface, producing tensile stress in the glass or polymer or resin-based cover sheet in this region. Because the tensile strength of glass is relatively low compared with polymers and resins, this can cause the cover glass superstrate 306 to crack.

These restrictions on the module component surface heights and overall planarity also limit the possible configurations or profiles of stress-relief bus bars for bi-glass sliver cell modules such as the module described herein. Although it is possible that alternative embodiments of the bus bar can be formed in the shape of a single arc formed between attachment points to the substrate when viewed from the side and still provide stress relief, such configurations are not preferred. Generally, it is preferred that extended regions of higher profile and including one or more arcs of relatively large radii of curvature are avoided, although these can be provided without stress-failure provided that the height of the top surfaces of these regions above the substrate is not more than 60-80% of the distance between the substrate 102 and superstrate 306. The height of the module components, where “height” is measured as the distance from the substrate to the plane defined by the top surfaces of the highest module components, is most preferably less than 50% of the distance between the two glass sheets 102, 306, or less than half the thickness of the encapsulant 304. For 125 μm high bus bars, the height of stress relief profiles is preferably less than 200 μm, leaving 75 μm between the upper and lower surfaces of the bus bar and the top and bottom of the profile, respectively. In practice, it is preferable that as much of the bus bar as possible is corrugated with the stress relief profile to ensure that the stress relief is spread over as much of the length of the bus bar as possible.

A typical bus bar includes 50 μm to 75 μm high corrugations with a 2 mm pitch. A section of the bus bar from 2 mm to 4 mm long is left uncorrugated or at least substantially planar to allow good bonding to a flat surface close to the substrate 102. Bonding may be effected using the conductive material in the case of conductive epoxy or solder or other materials providing good bond-line strength. Dielectric bonding materials may be used, either to provide the total bonding strength in the case of conductive inks being used for electrical connections, or partial bonding strength in the case of conductive epoxies being used for the electrical connections, provided these assisting bonding materials do not interfere with the electrically conductive pathways. The reduction in bus-bar length due to corrugations is typically of the order of 1% to 2%, although a lower figure can be achieved by low-profile, more widely spaced corrugations. Alternatively, a higher proportional reduction in length will be produced by higher profile, closer-spaced corrugations. The degree of stress relief offered by the corrugations is directly related to the reduction in bus bar length caused by the corrugations.

As shown in FIG. 5, the bus bar 108 is formed by feeding copper wire 502 of a selected diameter between a mutually spaced pair of rollers 504 having complementary surface features 508, 510 to provide a deformed copper strip of a desired width and thickness. The copper wire 502 is preferably pre-tinned. When the wire 502 is pressed between a pair of opposing surface features on the rollers 504, i.e., a projection 508 on one roller and a recess 510 of complementary shape in the other roller, the wire 502 is permanently deformed into a strip having a series of corrugations 506 spaced along the feed direction. The projections 508 and recesses 510 on the surfaces of the rollers 504 are evenly spaced around the circumference of the rollers 504 to provide evenly spaced corrugations, except for featureless regions 514 on the roller surfaces which result in the strip having periodic planar regions where no corrugations have been formed. As described above, these facilitate secure attachment of the bus bar 108 to the substrate 102.

Preferably, the corrugated strip is formed from a rolled wire so that it has no sharp edges or burrs associated with cutting, slicing, or slitting a wide or continuous sheet into narrow strips.

The wire can be continuously fed through the rollers 504 from a wire roll, or can be fed through the rollers in pre-cut lengths, preferably selected to provide the desired bus-bar length. In any case, the circumference of the rollers 504 is preferably greater than the desired bus bar length to allow for waste produced by cutting or joining strip segments. In order to facilitate the assembly of sliver cells into solar cell modules, the sliver cells can first be assembled into sub-modules, and a desired number and arrangement of these sub-modules can subsequently be, assembled into a complete solar cell module. The sub-modules may be arrangements of sliver cells held in a clamp or jig and transferred to the substrate in a single operation as a group or in several operations as smaller subsections of the sub-module assembly. The slivers at the ends of each sub-module may be interconnected by relatively short sections of the continuously-formed bus bar to electrically join together two or more sub-module sections, while the resulting sub-modules or collections of connected sub-modules are then interconnected by longer section of the same bus bar. In this way, any combination of series and parallel sub-module connections, series connection of parallel sub-module connections, parallel connections of series sub-module connections, or combinations of series and parallel sub-module connections can be achieved.

Alternatively, an initially planar sheet rather than wire 502 can be fed between the rollers 504. The sheet can be pre-cut into the width desired for the bus bar 108, or the sheet and rollers 504 can be much wider (i.e., in the dimension perpendicular to the paper) than the bus bar 108, and the sheet, once corrugated, cut into thin strips of the desired width (in this case 1.25 mm). The cutting to provide strips of a desired width and/or length can be performed by stamping, sheet slitting methods, or laser cutting. Alternatively, deformed strips can be prepared from an un-deformed sheet using a guillotine, with the opposing clamping and base-plate members of the guillotine preformed to match the stress-relief profile to avoid distorting this profile during the cutting operation.

The resulting bus bar strips can be pre-tinned to facilitate subsequent soldering if desired. In either case, each of the corrugated strips can be cut into strips of a desired length, but is preferably rolled into a continuous spiral roll or coil on a storage drum. This rolling further deforms the corrugated strip so that when a length of bus bar material is unrolled from the coil, it adopts a convex/concave shape determined by the corresponding circumference of the coil and the corrugation-induced curvature. The convex surface of the bus bar 108 is then applied towards the substrate 102 so that when a length of the bus bar material is attached to the substrate 102 at either end, such as at attachment locations 116 and 118 shown in FIG. 1, the portion of the bus bar 108 between the attachment locations 116, 118 contacts and exerts pressure on the substrate 102 and any intervening material between the bus bar 108 and the substrate 102, such as the cell interconnects 106 at locations 120.

The contact pressure exerted by the bus bar 108 at electrical connection points 120 and any other physical attachment locations, produced by the elastic deformation of the otherwise coiled bus bar 108, provides a natural locating and contact pressure between the bus bar 108 and the cell interconnects 106 or substrate 102 during placement, bonding, and electrical interconnection that greatly simplifies the bus bar application, the mechanical bonding of the strip or bus bar 108 to the substrate 102, and the electrical interconnection between cell interconnects 106 and the bus bar 108. In the case where conductive epoxy is used for electrical connections, the bus bar 108 is held securely in place during the dispensing or printing application of the adhesive, the transport of the solar cell module to the curing oven, and during the curing process where the temperature may rise to over 130° C. for many minutes. It is important to ensure that there is no relative movement between the bus bar 108, substrate 102, and conductive material during the curing process. This can be achieved by bonding the stress-relief bus bar 108 to the substrate 102 close to the electrical connection locations 120 using a UV-curable adhesive. The innate locating pressure of the uncoiled bus bar 108 facilitates rapid UV curing without any optical obstruction of the bonding region by mechanical clamping or locating mechanisms.

Thus the alternating corrugated and essentially planar regions of the bus bar 108 not only provide stress relief, which ensures module reliability and durability, but also simplifies the module assembly procedures and assists with the construction process as described above.

The stress relief bus bars described above provide a reliable means of eliminating electrical failure due to differential thermal expansion during thermal cycling and thermal excursions during module lamination, module reliability testing, and daily and annual thermal cycling during normal use within sliver cell modules. The method is simple, reliable, and adaptable to a wide range of bus bar materials, bonding materials, electrical interconnection materials, substrates and superstrates, and any combinations of these components.

### Sliver Removal and Handling

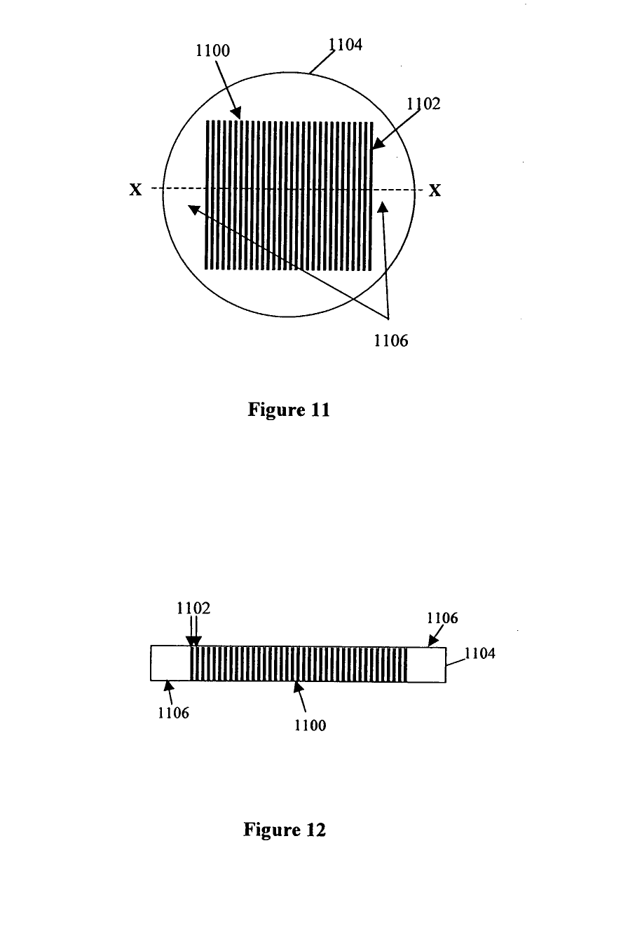

As shown in the plan and cross-sectional side views of FIGS. 11 and 12, a set of sliver cells 1100 can be formed by first forming elongated channels 1102 completely through a silicon wafer 1104, with the width of the channels 1102 being less than the thickness of the wafer 1104. The channels 1102 are formed by preferential chemical etching, but can alternatively be formed by cutting with a laser or dicing-saw. The regions of the silicon wafer remaining between these channels 1102 form a series of parallel elongated strips or slivers of silicon. As described in the sliver patent application, the entire wafer 1104 can then be processed so that each sliver becomes a pn junction solar cell, referred to as a “sliver cell.” The slivers are preferably formed as a single rectangular array, as shown in FIG. 11, where the array of slivers 1100 remains joined to and surrounded by a peripheral region 1106 of the wafer 1104, referred to as the wafer frame 1106.

The shape of a typical sliver cell resembles an extremely long plank, with a high length to width aspect ratio, and a very high length to thickness aspect ratio. Whilst still retained in a wafer, each sliver cell has four exposed faces. Because the width of the channels 1102 is less than the thickness of the wafer 1104, the two faces that were part of the (usually polished) surfaces of the starting wafer 1104 are the smallest of these faces, and these are referred to hereinafter as the ‘edges’ of a sliver.

The largest faces of each sliver are those two newly formed faces perpendicular to the original surfaces of the starting wafer, and these are referred to hereinafter as the ‘faces’ of a sliver. When processed to form a sliver cell, these provide the ‘active’ faces of the resulting solar cell, with one edge generally being of n-type, and the other edge generally being p-type. Optionally, some sections of an edge can be n-type, and other sections p-type to provide for special or demanding applications where resistance or electrical interconnection requirements make this arrangement advantageous. Once a sliver is removed from the wafer 1104 and the other slivers in the array 1100, the two newly exposed faces at opposite ends of the elongated sliver are referred to as the ‘ends’ of the sliver. Thus each sliver cell is said to have two opposing ends, two opposing edges of generally opposite polarity, and two opposing faces.

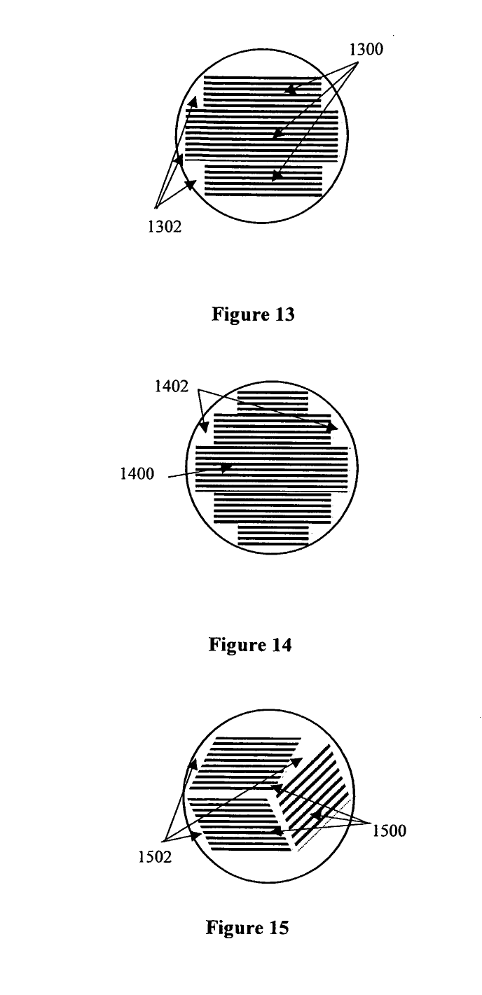

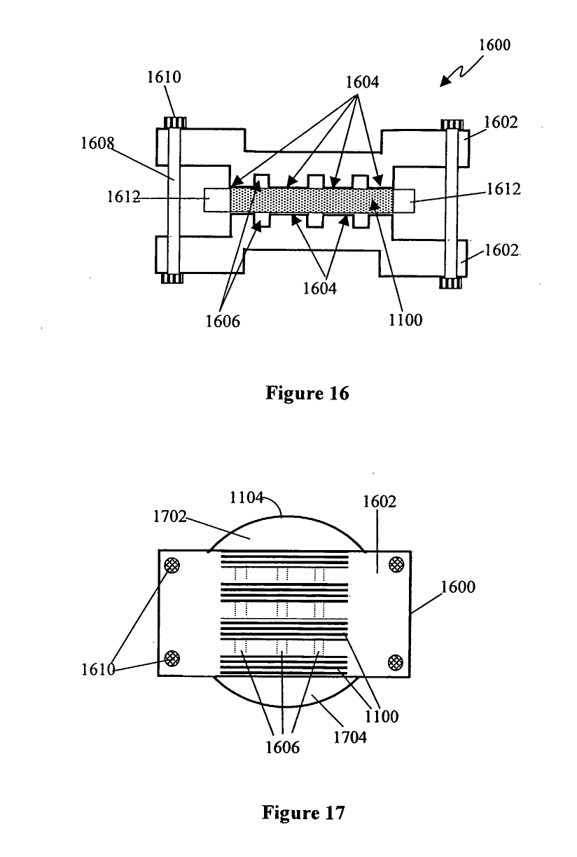

Alternatively, as shown in FIGS. 13 to 15, sliver cells can be formed in a wafer as separate rectangular arrays 1300 or contiguous rectangular arrays 1400, or as separated or contiguous parallelepiped or rhomboid-shaped sliver cell arrays 1500. These sliver array arrangements allow greater wafer utilisation, or greater total sliver cell face area per wafer, but this comes at the price of increased complexity in separating and handling the sliver cells, as described below. As shown in the cross-sectional side view of FIG. 16 and the partial cut-away plan view of FIG. 17, a clamp 1600 includes two opposing halves or pieces 1602 having mutually opposed square inner faces 1604, each divided by three parallel alignment slots or channels 1606 between which the wafer 1104 is placed. The clamp 1600 is operated by separating the two halves 1602 of the clamp 1600, and inserting the wafer 1104 between these two faces in a position and orientation such that the inner faces 1604 of the clamp 1600 will grip only the edges of the slivers 1100 and will not grip any of the wafer frame 1106, and that the longitudinal axes of the slivers 1100 are perpendicular to the longitudinal axes of the alignment slots 1606.

The slivers 1100 are then secured between the opposing faces 1602 of the clamp 1600 by tightening four bolts 1608 that pass through both openings in halves 1602 at each corner of the clamp 1600 using thumb screws 1610 at the ends of the bolts 1608 until a desired force is supplied. The force may be supplied by the tension in the bolts, or it may be provided by springs (not shown) provided at the ends of the bolts 1608. The two halves 1602 of the clamp 1600 are thus brought together so that the inner faces 1604 of the clamp halves 1602 securely grip the sliver cells 1100 by their edges.

As shown in FIG. 6, the clamp 1600 extends only to the edges of each sliver adjacent its (as yet unexposed) end, and does not extend over the lateral frame portions 1612 interconnecting the slivers 1100. As shown in the plan view of FIG. 17, the clamp 600 does not extend over the top portion 1702 or the bottom portion 1704 of the wafer frame 1106. It should be appreciated that the representation shown in FIG. 17 includes cut-out portions to illustrate the relative positioning of the slivers 1100 and the alignment slots 1606. However, in reality the sides of the clamp 1600 are solid and opaque, and the slivers 1100 would not be seen.

The wafer frame top 1702, bottom 1704, and lateral portions 1612, unobstructed by the clamp 1600, are then removed by fracturing, leaving the individual sliver cells of the array 1100 separated from each other but securely retained within the clamp 1600 with their orientation and relative position maintained. The removal of the wafer frame portions 1702, 1704, 1612 can be achieved by fracturing the wafer, cleaving along a crystal plane, scribing and breaking, laser cutting, dicing saw cutting, or water jet cutting.

The faces 1604 of the clamp 1600 contacting the edges of the sliver cells 1100 have compliant surfaces so that the cells 1100 are not damaged or crushed or fractured by localized stress, and yet the sliver cells are held securely. Furthermore, the compliant surfaces 1604 are preferably sticky to assist with retaining the sliver cells 1100 in their original relative locations and orientation.

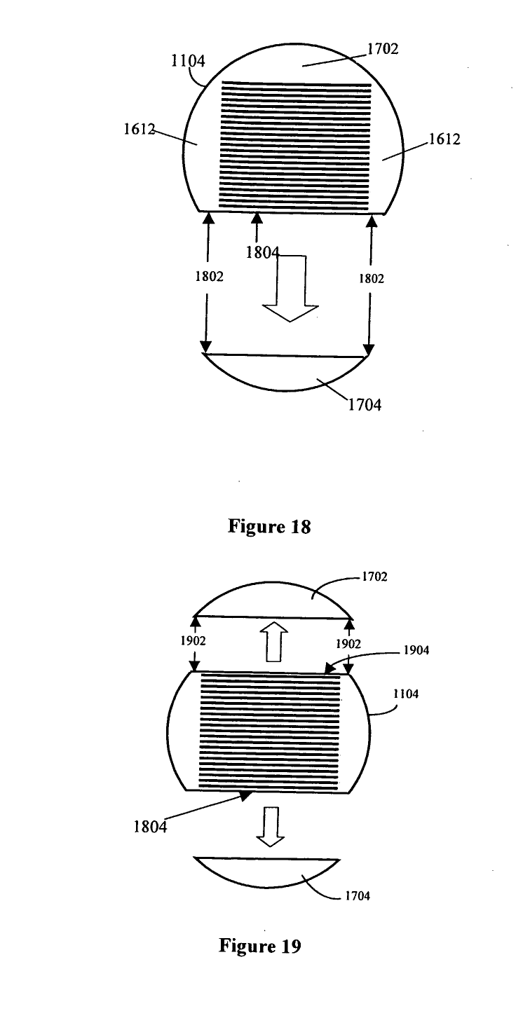

Alternatively, the top frame portion 1702 and/or the bottom frame portion 1704 can be removed prior to inserting the wafer 1104 between the clamp halves 1602 by fracturing or otherwise cutting the wafer frame joining portions 1802, 1902 to expose a bottom sliver 1804 and/or a top sliver 1904, as shown in FIGS. 18 and 19.

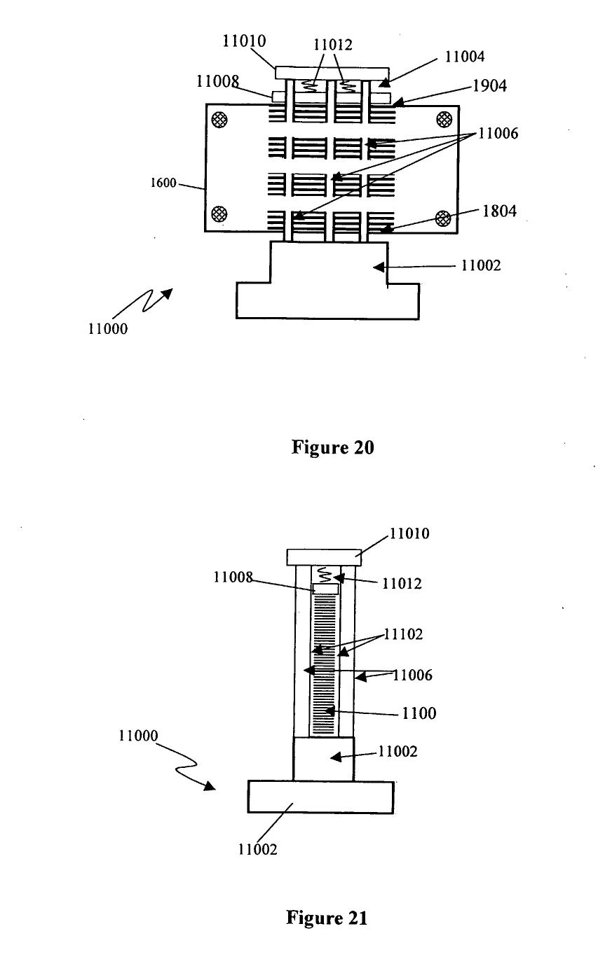

As shown in FIG. 20, a sliver cassette or storage device 11000 includes a solid base 11002 and a spring loaded top assembly 11004 connected together by six guide rails or alignment fingers 11006 arranged in two groups of three, although other arrangements and numbers of guide rails are also suitable. A side view of a typical storage device, loaded with a conflated stack of slivers seen end-on, is shown in FIG. 21. In order to use the sliver storage device 11000, the guide rails 11006 are removed from respective securing holes (not shown) in the base 11002, and the exposed ends of the guide rails 11006 are then fed through the top end of the alignment slots 1606 in the clamp 1600 until they project from the bottom end of the alignment slots 1606. The guide rails 11006 are then returned to their securing holes in the base 11002 so that the clamp 1600 is retained within the sliver storage device 11000. The relative movement of the clamp 1600 and the storage device 11000 is thus restricted to the direction parallel to the alignment slots 1606 and the guide rails 11006, shown as vertical in FIGS. 20 and 21. The spring loaded top assembly 11004 includes a securing plate 11008 and an end plate 11010, connected by and maintained in a mutually spaced configuration by intervening springs 11012. As shown in FIG. 20, the length of the guide rails 11006 is such that the securing plate 11008 presses with a pre-set or adjustable pressure against the topmost sliver 1904 when the sliver stack is still in the wafer frame 1104 and when the slivers are removed from the wafer and conflated to a contiguous stack 1100. This ensures that the correct relative orientation of each sliver is maintained at all times during the separation process.

The two halves 1602 of the clamp 1600 securing the sliver cells 1100 are then progressively separated from the sides of the array of sliver cells 1100. Through the action of gravity or gravity and the downwards force of the spring 11012 acting on the securing plate 11008, the slivers 1100 are thus conflated together as the clamp inner faces 1604 gradually release the slivers 1100 and the adjacent faces of the slivers rest on one another or are pressed together between the base 11002 and the securing plate 11008.

Thus the sliver cells 1100, which have been released from the wafer frame 1106 and subsequently maintained in the clamp 1600 in a separated array similar to or matching their original pitch and orientation in the starting wafer 1104, are conflated into a stack of sliver cells with adjacent cell faces resting in contact under gravity or under action of the spring loaded top assembly 11004 of the storage device. The conflation preserves the sliver cell orientation and polarity by ensuring that the spacing between sliver cells is never sufficiently large to allow a cell to flip or jam.

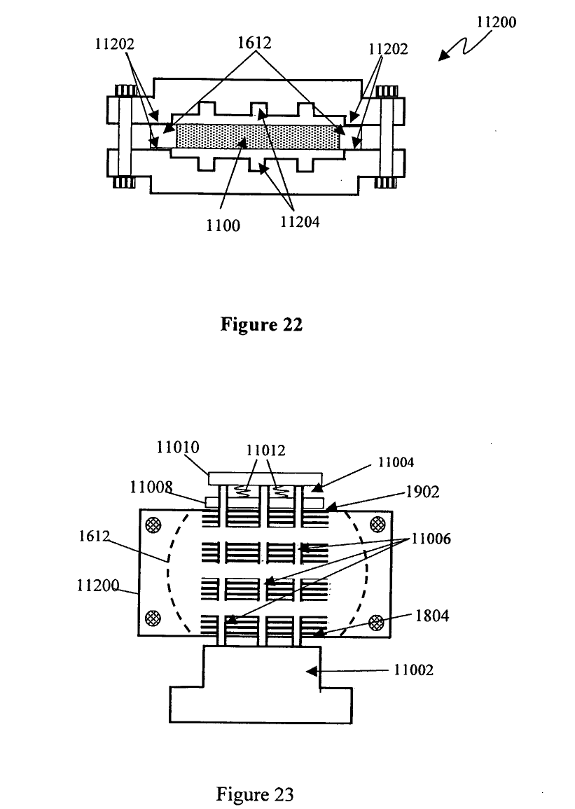

In an alternative embodiment, as shown in FIGS. 22 and 23, the set of slivers 1100 is secured by a clamp 11200 having inner faces 11202 that engage the lateral wafer frame portions 1612 but do not contact the slivers 1100. The clamp extends over (but does not contact) the edges of the sliver cells 1100. The clamp 11200 may also contact the top frame portion 1702 if this has not yet been removed. The portion of the clamp 11200 extending over the sliver cells 1100 includes alignment slots 11204 for locating the guide rails 11006 of the storage device 11000. If the top frame portion 1702 and the bottom frame portion 1704 of the wafer frame 1106 have not yet been removed, at least one of these frame portions 1702, 1704 is then removed to provide access to the top sliver cell 1904 and/or the bottom sliver cell 1804, respectively.

The locating guide rails 11006 of the storage device 11000 are then inserted into and through the respective alignment slots 11204 of the clamp 11200, and then inserted into their respective retaining holes in the storage device base 11002 in the manner described above. The clamp 11200 and the base 11002 are then pushed together along a direction parallel to the longitudinal axis of the locating guide rails 11006.

When the leading face of the base 11002 meets the bottom sliver cell 1804, this will impede the pushing action. However, by continuing to force the base 11002 towards the securing plate 11008, the bottom sliver cell 1804 is fractured at or near its ends, thus releasing the cell 1804 from the wafer frame portions 1612. The released cell 1804 then rests on the base 11002 and subsequently transmits the applied force to the face of the adjacent sliver, which is then released in the same manner as the first, allowing the base 11002 to move towards the next sliver cell.

The device 11000 can operate in any orientation, even upside down, without modification because the released slivers are constrained from moving in a direction parallel to the planes of their faces by the locating guide rails 11006 of the storage device 11000, and are constrained from moving in a direction perpendicular to the plane of the face by the next un-released sliver at one face and the released, conflated stack of slivers at the other face. The force required, of the order of only a few Newtons, is orders of magnitude greater than the weight force of a sliver, which is of the order of a few milli-Newtons. This action is continued so that as the base 11002 of the storage device 11000 is fed into the clamp 11200, the slivers 1100 are successively released in the direction of travel.

The securing plate 11008 of the spring loaded top assembly 11004 prevents the last sliver, or last few slivers, from jumping away when the ends of the last sliver are fractured, and also limits the free space available between the securing plate 11008 and the conflated stack of slivers to less than a sliver width, thus ensuring slivers can never flip or change orientation. The sides of the sliver cell storage device 11000 retain the released sliver cells 1100 at their edges with suitable clearance 11102. The clearance should be large enough to ensure that the width of the widest sliver does not exceed the cell storage device width less the maximum machining tolerance. A suitable clearance value typically lies between 20 and 50 microns.

The securing plate 11008 biased by the spring 11012 prevents the last sliver cell or cells from springing away on release, containing the released sliver cells between the base 11002 and the securing plate 11008. Thus the sliver cells 1100 are successively released from the lateral wafer frame portions 1612 to form a stack of sliver cells with adjacent cell faces resting in contact under gravity or under the biasing action of the spring 11012. The conflation preserves the sliver cell orientation and polarity by ensuring that the spacing between the sliver cells is never sufficiently large to allow a sliver cell to flip as the release pressure is transmitted from face to face of successive sliver cells. The pressure of the springs 11012 also inhibits the slivers from sliding relative to each other.

End-plates (not shown) can then be inserted into the storage device 11000 through slots (not shown) in the base 11002 and/or the end-plate 11010, to retain the released slivers at their ends. This securing operation can be performed immediately after loading the storage device 11000, just before dispensing the slivers, or after aligning the sliver ends to ensure they are coplanar.

The length of the springs 11012 is riot critical for the removal of slivers from the wafer, as their function is to retain the last or end sliver 1904 and ensure there is never enough space for a sliver to flip its orientation. To facilitate the application of a known and constant pressure on the sliver stack 1100 over a relatively long distance, this pressure can alternatively be provided by replacing the springs 11012 and securing plate 11008 with a weight, with the restriction that the device be maintained in a vertical or near-vertical orientation.

The ratio of the sliver thickness to the gap between adjacent slivers is typically around 60:40 to 70:30, so the gap between the slivers is not significantly smaller than the sliver thickness. However, during the loading operation, the springs 11012 move the securing plate 11008 over a distance of approximately 2 cm, being the cumulative distance of all the spaces between the slivers in the array 1100. For comparison, a movement of around 8 to 8.5 cm is required to prevent flipping of slivers during the unloading operation, being the total thickness of the conflated stack of slivers. Due to the simplicity of the retention mechanisms described above, it is practical to use a different method for loading (spring tension) and unloading (freely sliding weight) to provide a substantially constant force over the distance of travel.

Because the sliver stack is clean and dry there are no stiction issues with the separation, handling, and dispensing processes described above. The possibility of stiction is further reduced by the fact that the faces of the slivers are often textured with random features of the order of a few microns high, and the slivers themselves are not exactly rectangular in cross-section, even though they are generally referred to as such herein. Depending on the particular process used to form the slivers, they are actually either hexagonal in cross-section, with each face being about 10 to 15 microns thicker in the middle than near its edges, or rhomboid with one edge 10 to 20 microns wider longer than the other, opposite edge.

The area, length and shape of the base 11002 along the length of the slivers 1100 can be selected to control the bending of each sliver cell at or near its junctions with the lateral wafer frame portions 1612 and thereby improve the fracture and separation of the sliver cells 1100 from the wafer frame portions 1612.

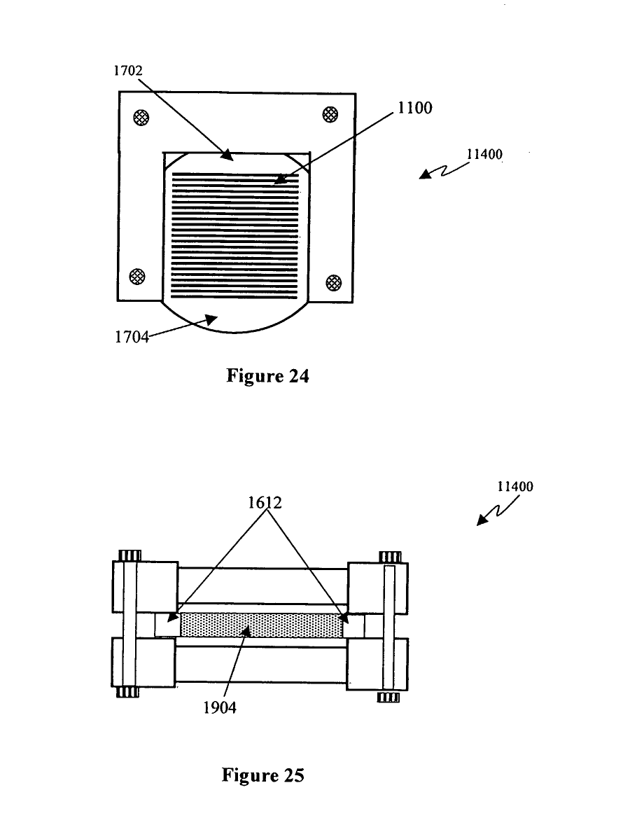

In a fourth embodiment, as shown in FIGS. 24 and 25, the set of slivers 1100 is secured in an open-sided, U-shaped clamp 11400 contacting only the planar surfaces of the lateral wafer frame portions 1612, and the top wafer frame portion 1702, if this has not been removed. The bottom wafer frame portion 1704, if present, is removed to expose the bottom sliver 1804 using one or more of the procedures described above.

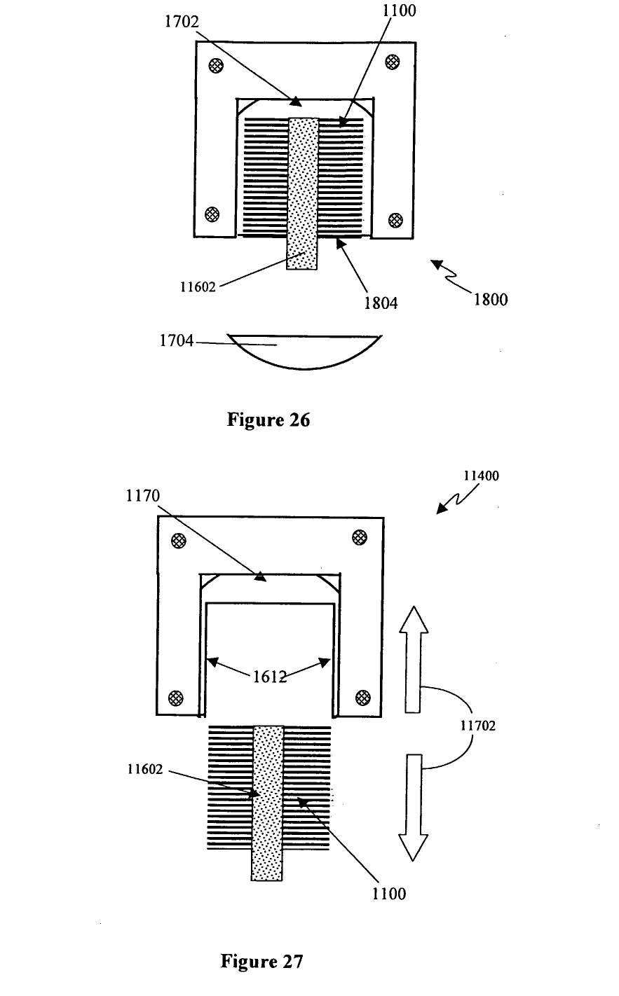

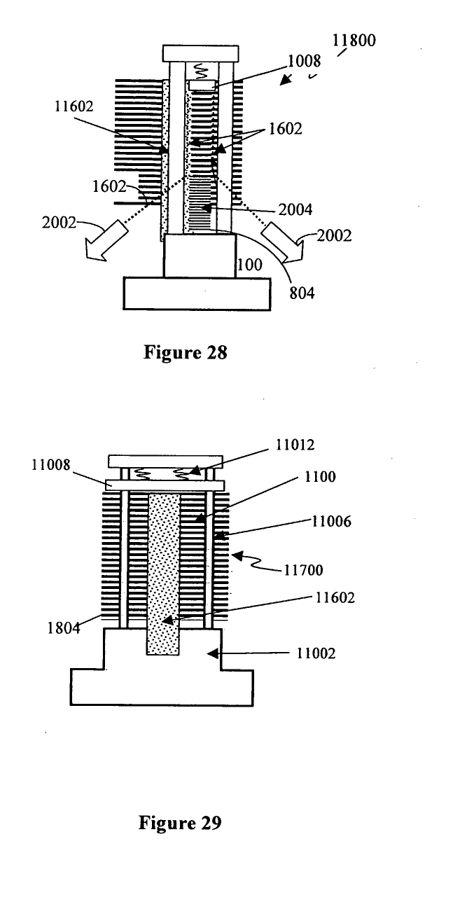

As shown in FIGS. 26-29, a length of adhesive tape 11602 or other adhesive material is attached to the edges of the sliver cells 1100 in the plane of the wafer surface extending along the array to cover all sliver cells which are to be removed. The selected section may include the entire sliver cell array, as illustrated, or only a subset of the entire array. Preferably, a second length of tape is applied to the opposite edges of the sliver cell array coplanar with the opposite wafer surface. Alternatively, an adhesive paste or double-sided adhesive film may be applied to the sliver cell edges and another material or supporting layer bonded to the adhesive paste or adhesive film to retain the sliver cells by the edges as with the adhesive tape.

The sliver cells attached to the adhesive tape 11602, are then separated from the lateral wafer frame portions 1612 by displacing the sliver cells relative to the lateral wafer frame portion 1612, as shown by the arrows 11702 in FIG. 27. This can be achieved by moving the sliver cell array and the clamp 11400 away from each other. In an alternative embodiment, the clamp extends over the ends of the sliver cells 1100 in order to keep the released sliver cells planar with the wafer 1104 while the slivers 1100 are being removed from the lateral wafer frame portions 1612.

The selected portion of the sliver cell array attached to the adhesive tape or tapes 11602 now provides an assembly 11800 of sliver cells 1100 released from the wafer portion frame 1612 with identical orientation and polarity, and substantially similar pitch to that of the sliver cells before release from the lateral wafer frame portions 1612. The released sliver cell assembly 11800 constrained by the adhesive tape 11602 may be provided directly for subsequent processing, or may be transferred to a cassette or storage unit such as the storage unit 11000 described herein.

The width of the adhesive tape 11602 or other adhesive material (i.e., in a direction parallel to the longitudinal axes of the sliver cells 1100) affects the fracture of the sliver cells at or near the ends of the sliver cells where they join the lateral wafer frame portions 1612. The tape width determines the bending angle of the sliver cells, which controls the localised stress in the sliver ends via the fracture force imposed by displacing the sliver cells relative to the wafer frame. The narrower the adhesive tape 11602, the more the sliver cells 1100 will bend when the centre portions of the sliver cells are displaced relative to the ends of the sliver, cells attached to the lateral wafer frame portions 1612. As an illustration, for sliver cells of length 60 mm, an adhesive tape width of 16 mm gives good adhesion as well as good bending for localised fracture at the ends of each sliver cell. For different length and different thickness sliver cells, an optimal width can be found by trial and experiment.

Alternatively, the sliver cell array 1100 contained within the wafer frame portions 1612 may be clamped with a clamp with a sliver-edge contact surface coated with an adhesive film or a layer or sheet of compliant material to simulate the action of the adhesive tape 11602. Such a clamp can be considered to act in a manner similar to a pair of rubberised tongs. As was the case with the tape 11602, the width of the clamp and compliant material in the direction of the length of the sliver cells is chosen to improve the localized fracture of the sliver cells at or near the ends of the sliver cells near the lateral wafer frame portions 1612.

Alternatively, the sliver cell array 1100 contained within the wafer frame may be manually processed without the requirement of an external clamp to remove the unwanted sections of the wafer frame 1702, 1704. Further, the separation of sliver cells from the lateral wafer frame portions 1612 can also be performed manually, without the requirement of a clamp to hold the lateral wafer frame portions 1612.

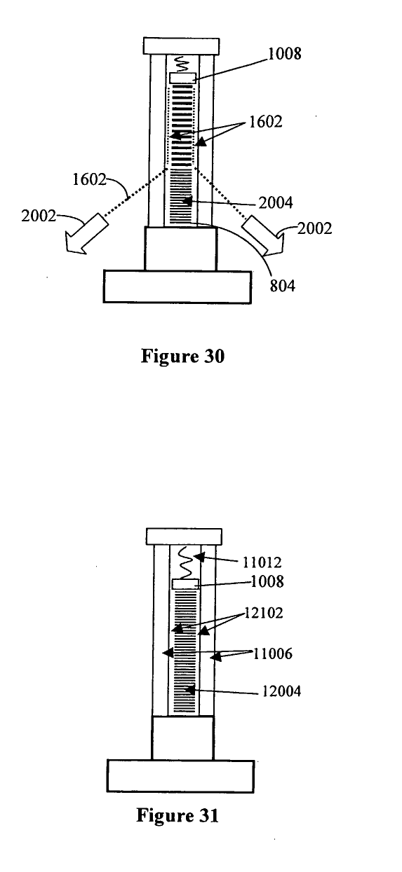

The sliver assembly 11800 can be fed between the pairs of alignment guides 11006 and into the storage device 11000 whilst holding the securing plate 11008 away from the slivers 1100, as shown in FIG. 29, or by removing the spring loaded top assembly 11004 to allow free access to the top of the storage device 11000. The sliver cells 1100 are then conflated by pulling the end of the adhesive tape 11602 at the base of the sliver assembly 11800 at a downwards angle, as represented by the arrows 12002 in the side view of FIG. 30, the angle being chosen so that the downwards component of the pulling force brings adjacent sliver cell surfaces together and the outward or transverse component of the pulling force releases the adhesive tape 11602 from the edges of the sliver cell 1100 in the assembly 11800, beginning with the bottom sliver cell 1804 and progressing upwards as successive sliver cells are released to form a conflated sliver cell stack 12004, as shown in FIG. 31.

During this operation, the securing plate 11008 follows the top of the un-conflated section of the sliver stack downwards under the action of the spring mechanism 11012 to ensure that the last sliver or last few slivers do not flip their orientation if there is any unevenness or asymmetry in the action of removing the tape 11602. The alignment guides 11006 retain the released slivers within the storage device 11000 with suitable clearance 12102, as described above.

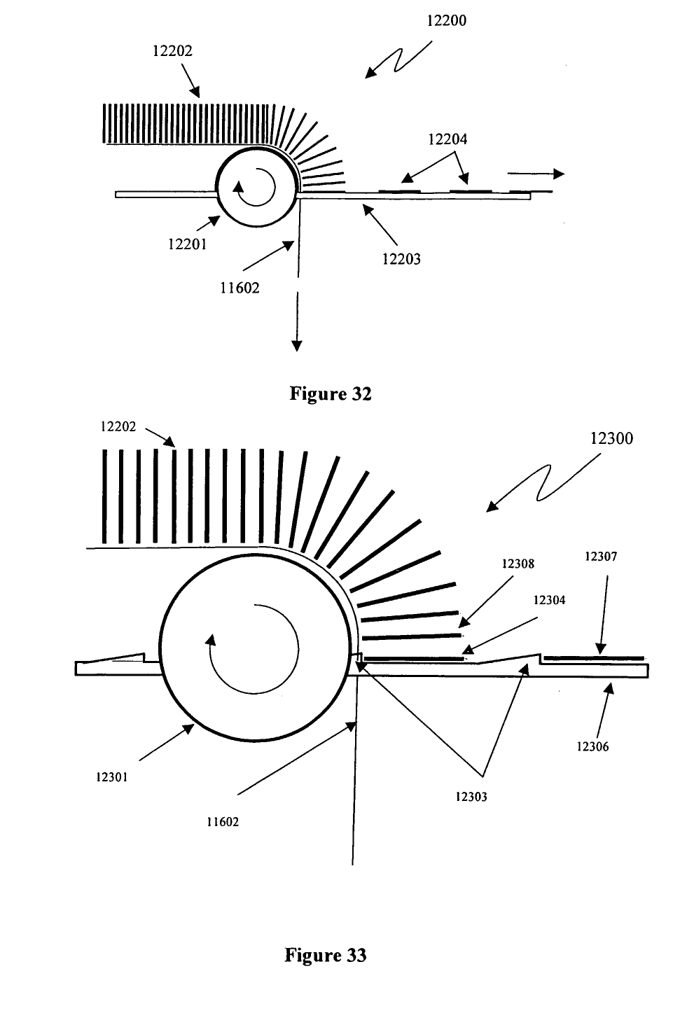

Alternatively, the released sliver cell assembly 11800 constrained by the adhesive tape 11602 can be fed directly to a sliver cell singulation unit 12200, as shown in FIG. 32. In the sliver cell singulation unit 12200, the adhesive tape 11602 constraining the stack of separated slivers 12202 is fed over a small-diameter roller 12201 with the non-adhesive back of the tape 11602 to the roller 12201. As the tape 11602 is passed over and around a selected portion of an arc over the roller or drum 12201, the outer edge of the sliver cells 12202 fan out, increasing the distance between the edges furthest away from the tape 11602, thus facilitating access to individual sliver cells. The individual sliver cells can be picked off the adhesive tape 11602 by mechanical fingers or hooks on a moving belt 12203, or by vacuum suction on the belt 12203, or by electrostatic attraction, or by some combination of these methods.

Alternatively, the sliver cell assembly 11800 can be provided directly to a subsequent assembly stage 12300, such as shown in FIG. 33, where the sliver cells 12202 are separated from the adhesive tape 11602 and assembled into a planar array on a frame or jig 12306, or directly to a solar cell module substrate. In the case of the frame or jig 12306, the edge of a fanned-out sliver cell 12304 that is to be removed from the tape 11602 is brought into contact with a step 12303 in the frame or jig 12306. The step 12303 is of sufficient height to reliably engage the sliver cell 12304 that is to be removed from the tape 11602, but less than the sliver pitch, which is the distance from the face of one sliver cell to the adjacent face of the adjacent sliver, so that contact with the adjacent sliver cell 12308 is avoided. The sliver cell is removed from the adhesive tape 11602 by relative motion of the jig 12306 and tape 11602. Each sliver cell can be captured and secured with the assistance of vacuum or electrostatic attraction, or by other mechanical means. These operations are repeated until the required number of sliver cells has been assembled into a solar cell sub-module or a temporary array of sliver cells.

The sliver removal apparatus and processes described herein allow slivers to be separated from a wafer frame whilst retaining the orientation and therefore relative polarity of separated sliver cells. In some embodiments, the relative separation or pitch of the separated slivers is initially retained and the released slivers are then conflated to remove spaces between the faces of adjoining slivers, allowing them to be stacked in a contiguous array, and provided to a further processing stage, such as a test or assembly stage. In other embodiments, each sliver is conflated with previously released slivers as the sliver is released from the wafer frame.

The bulk or substantially simultaneous removal of slivers from a wafer avoids the need to locate, engage, separate, and handle individual sliver cells. Furthermore, the slivers are engaged by their edges, which are more robust than the sliver faces. The sliver removal processes described herein do not rely on precise positioning such as that required for individual sliver cell separation, and in particular, do not depend upon the detailed knowledge of the small, and thickness-variable gap between the sliver cells in the wafer array.

The sliver removal processes and apparatus described herein provide a clean array of slivers or sliver cells held in a clamp, a cassette, or constrained by adhesive tape, without any separation fragments contaminating the array. One of the problems with “in-line” or sequential separation and assembly processes is that the separation fragments, which are quite numerous, can contaminate the sliver retention mechanisms. If the retention mechanism is a vacuum, the vacuum holes can become blocked, or a vacuum hole can be partially jammed with a sliver fragment standing on its edge, which then fractures the next sliver that is pressed down on it. Sticky surfaces suffer from the same problems. By decoupling the separation and subsequent handling and/or assembly stages, the separation detritus can be removed at the separation stage, preventing it from contaminating the following assembly processes. Regardless of the particular implementation of separation and sliver retention, such as the clamp, tape, or sliver cassette described above, the separation fragments produced when fracturing or otherwise cutting the ends of the slivers out of the wafer frame can be easily removed from the sliver stack.

The resulting sliver array is in a convenient form that facilitates storage or dispensing of individual slivers to subsequent processing or assembly stages, without requiring high precision or fine-tolerance engineering or complex control systems. Each step of the sliver removal processes can be easily executed by hand, in a short time, and with minimal expense, with the orientation of slivers being positively maintained at each step. Furthermore, the simplicity of the processes herein allows straightforward, inexpensive, and robust automation of any of the sliver removal and handling process steps.

Returning to FIGS. 13 to 15, it will be apparent that the rectangular arrangements of sliver arrays in FIGS. 13 and 14 are directly compatible with the separation and handling processes described above, provided that each wafer is cleaved into sections between the last sliver in each array and the first sliver in the next array in the same wafer. For example, the wafer shown in FIG. 14 containing five arrays of slivers would be cleaved into five sections in a process similar to that illustrated in FIGS. 18 and 19. The top wafer frame portion of the top section and the bottom wafer frame portion of the bottom section can be removed to provide five rectangular sliver banks, each bank separately constrained by those lateral wafer frame portions remaining at the ends of the slivers.

A similar process will achieve the same result in FIG. 15, with the added requirement that the inclined stack of slivers will require a straightening or alignment step to produce a rectangular, contiguous array of separated slivers ready for the dispensing or placement operation. As the primary advantage of sliver cells is the dramatic increase in active surface area of cells that can be produced from a given mass of silicon, any arrangement that increases this available surface area of cells from a wafer, such as those illustrated in FIG. 13 to 15, further enhances the benefits of sliver technology.

Although the sliver removal processes and apparatus have been described herein in terms of sliver solar cells, it will be apparent that these are equally applicable to slivers used for other applications.

### Sub-Module Formation

Referring to FIG. 1, sliver solar cells 101 and crossbeams 102 are assembled to form a “sliver raft” sub-module 100. The spacing between the solar cells can range from zero to several times the width of each cell. The crossbeams 102 can be made of any material and are preferably thin, not electrically conductive (or are coated with an insulating material) and can be readily coated with conductive tracks. For example, thin strips of silicon 30 to 100 micron thick, 1 to 3 mm wide, and 2 to 20 cm long constitute a suitable material for the crossbeams. The cells 101 are mechanically adhered to the crossbeams 102 using adhesive or metal solder or conductive epoxy or similar material.

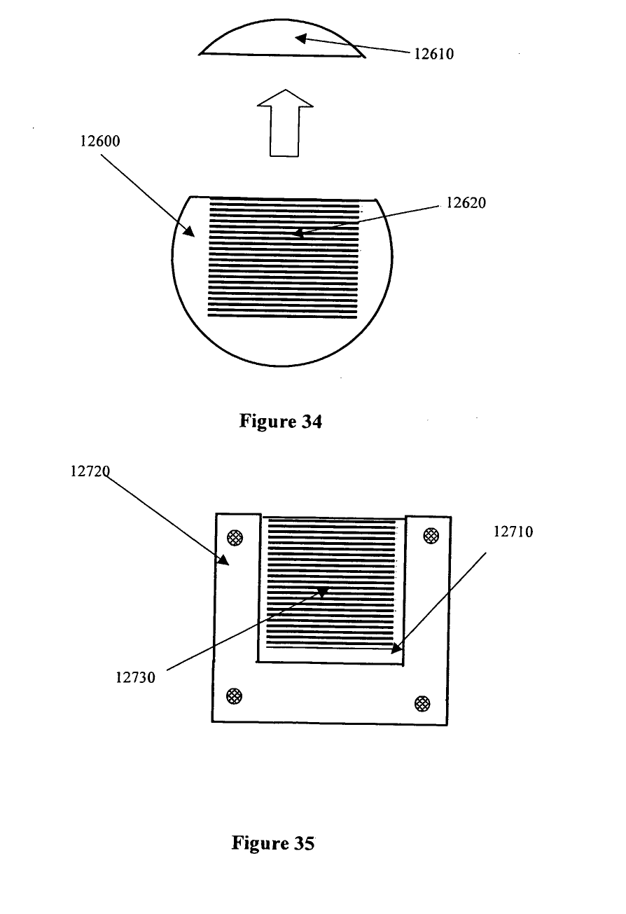

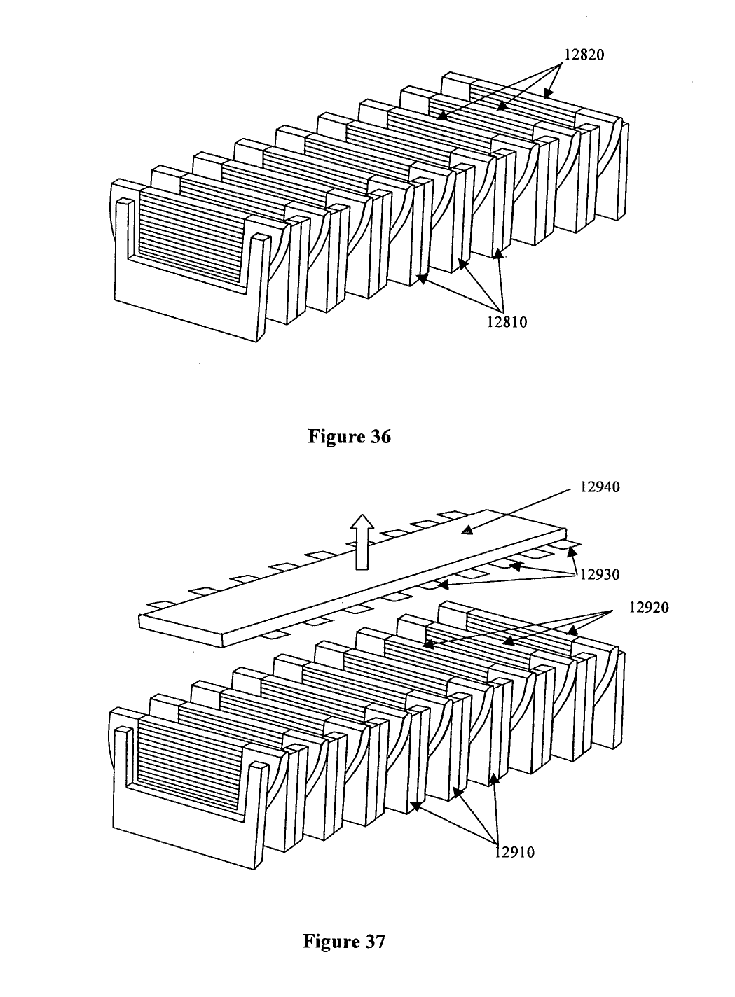

As seen in FIG. 34 a set of sliver cells 12620 is formed in a wafer according to the processes described in the sliver patent application. The wafer has a frame portion 12600 at each end of the set of sliver solar cells 12620. The wafer frame portion may or may not extend around the circumference of the wafer to the regions adjacent to the flat faces of the outermost sliver cell at each end. The wafer is cut, or snapped removing portion 12610 to expose one face of the sliver solar cell array 12620. The wafer is then secured in a clamp, as shown in FIG. 35, contacting the edges of the wafer 12710 outside the sliver cell array area 12730 in the plane of the faces of the wafer. Advantageously the surface of the clamp contacting the edge of the wafer has a compliant surface. More than one wafer may be clamped 12810 to provide a grid or array of surfaces 12820, as shown in FIG. 36. The number of wafers clamped in the array can be equal to the number of sliver solar cells required to form a raft or boat sub-module.

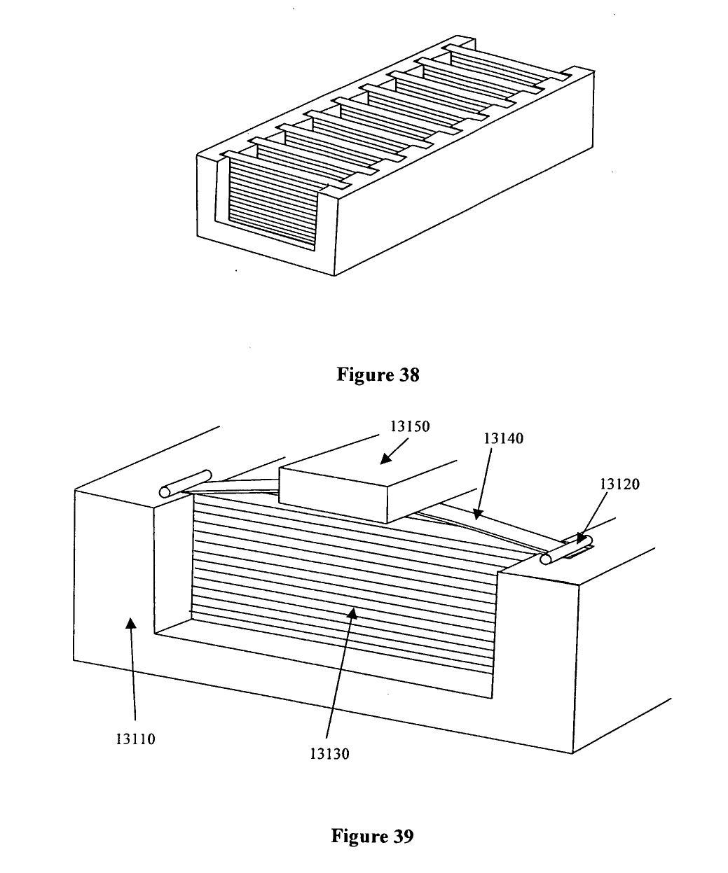

As shown in FIGS. 37-39 the exposed sliver cell from each wafer 12820, 12920 can be removed as an array 12930 by mechanical means such as a vacuum engagement tool 12940. The vacuum engagement tool is used to transfer the sliver cells to the next stage of sub-module assembly, such as placing the array on cross-beams to form a raft. Alternatively as shown in FIG. 40, the exposed sliver cell 13220 from each wafer may be removed in an array arrangement 13230 by a fast-cure adhesive 13260 which directly and permanently bonds the sliver cells to the sub-module array cross-beam or raft beam 13250. The raft cross-beams are prepared with adhesive using dispensing, stencil printing, screen printing, stamping or other well-known method of transferring the desired quantity of adhesive to the required location. The sub-module array is then transferred to the next stage of assembly which may be the installation of electrical connections between adjacent sliver cell electrodes.

The exposed sliver cell from each wafer can also be removed in an array arrangement by a re-useable sticky surface that temporarily bonds the sliver cells to the transport or transfer mechanism. The temporary adhesive performs the function of a vacuum. The sliver cells are removed from the transfer tool after separation from the wafer and subsequently assembly into sub-module assemblies or rafts. In an alternative embodiment, the exposed sliver solar cells from each wafer are removed in an array arrangement using static electrical attraction that temporarily bonds the sliver solar cells to the transport or transfer mechanism. The sliver solar cells are then removed from the transfer tool after separation from the wafer and subsequent assembly into rafts or boats by discharging the transfer head.

The sliver solar cells are positively engaged at all times to ensure correct orientation and polarity. The sliver solar cells are also directly assembled into rafts or boats following separation from the wafer, thus avoiding any intermediate handling or storage steps. Importantly, sliver solar cells are only ever handled in groups, which vastly reduces the number of handling operations per square metre of photovoltaic module.

In FIGS. 41-43 a method is shown for handling sliver solar cells that have already been removed from a wafer frame and are contained in some form of bulk storage such as a storage cassette. Sliver solar cells 13370 contained in a cassette or bulk storage unit 13320 are provided. More than one cassette or buffer storage unit may be assembled to provide a grid or array of sliver solar cell surfaces presented in a planar arrangement constituted by the accessible sliver solar cell in each unit. This planar arrangement embodies the desired relative location and orientation of sliver solar cells in the subsequently formed raft or boat array. A number of cassettes or buffer storage units are arranged in a grid or array so that the accessible sliver solar cell in each unit is in the correct location and orientation, relative to adjacent sliver solar cells, to form a raft or boat sub-module or assembly.

Alternatively, as the sliver solar cell stacks 13020 may be assembled directly into a multiple-stack unit 130710, which is effectively a single cassette incorporating multiple stacks of separated sliver solar cells, each resting on the face of the adjacent sliver solar cell, and each stack located and constrained by the ends of the sliver solar cells resting in grooves in the cassette wall. The stack pitch, or the separation between each stack, is selected to satisfy the desired location in the final raft or boat sub-module. In the case of an array assembled from multiple cassettes, the number of cassettes or bulk storage units clamped in the array can be equal to the number of sliver solar cells required to form a raft or boat. Alternatively, the sub-module array can be constructed using a smaller number of storage units and more than one repeated assembly operation.

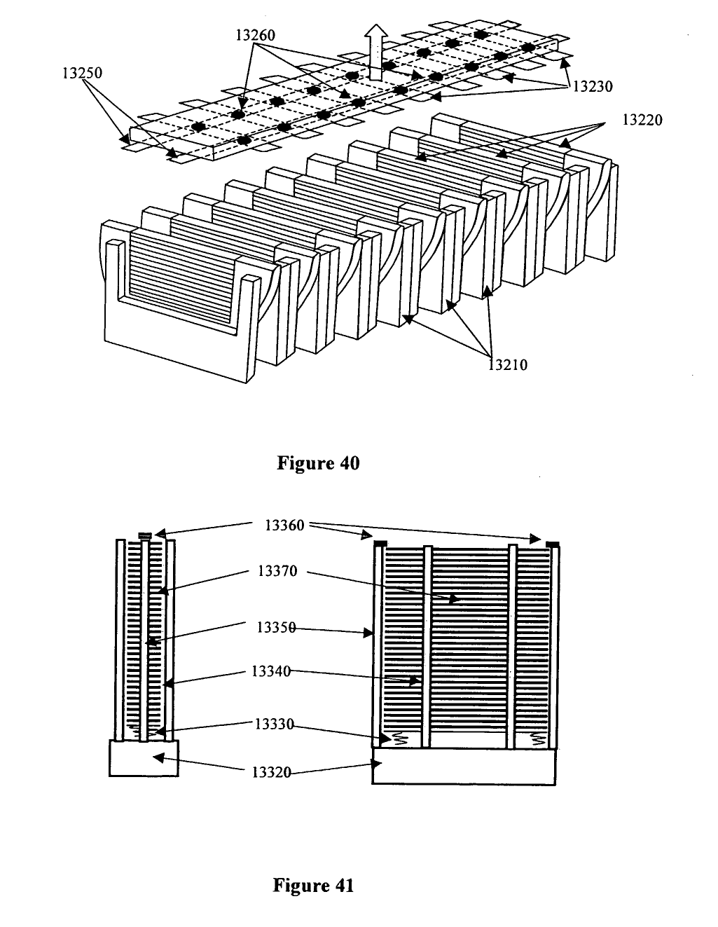

As shown in FIG. 41 the sliver solar cell levels in the stack are maintained by a spring 13330 or mechanical feed control so that the upper sliver solar cell is always in the same position. As shown in FIG. 39 the sliver solar cell is kept within the stack by a mechanical stopper 13120 located near the ends of the sliver solar cell. The sliver solar cell can be removed when its effective length is sufficiently reduced by bending or bowing during extraction from the cassette. The degree of bending, and the bending location is controlled by the width and location of the vacuum transfer tool and the position of the mechanical stopper or rollers at the ends of the sliver solar cell. Alternatively, the cassette can face downwards so that the weight of the sliver solar cell stack and stack follower ensures that the outermost sliver solar cell is ready to be presented to as pickup device.

As shown in FIG. 39 the exposed or first-presented sliver solar cell 13140 from each cassette, group of cassettes, or multi-stack cassette 13110 may be removed in an array arrangement by mechanical means such as a vacuum engagement tool 13150. The vacuum engagement tool 13150 is used to transfer the array to the next stage of sub-module assembly. Alternatively, the exposed sliver solar cell 13140 from each cassette, group of cassettes, or multi-stack cassette 13110 can be removed in an array arrangement by a fast-cure adhesive which directly and permanently bonds the array to the sub-module array cross-beam or raft beam. The sub-module array is then transferred to the next stage of assembly which can be the installation of electrical connections between adjacent sliver solar cell electrodes. In an alternative embodiment, the exposed sliver solar cell from each cassette, group of cassettes, or multi-stack cassette is removed in an array arrangement by a re-useable sticky surface that temporarily bonds the sliver solar cells to the transport or transfer mechanism. The sliver solar cells are then removed from the transfer tool after separation from the cassette, group of cassettes, or multi-stack cassette and subsequently assembled into rafts or boats. In yet a further alternative embodiment, the exposed sliver solar cell from each cassette, group of cassettes, or multi-stack cassette is removed in an array arrangement using static electrical attraction that temporarily bonds the sliver solar cells to the transport or transfer mechanism. The sliver solar cells are then removed from the transfer tool after separation from the cassette, group of cassettes, or multi-stack cassette by discharging the transfer head.

The sliver solar cells removed from the cassette, group of cassettes, or multi-stack cassette are positively engaged at all times to ensure correct orientation and polarity. The sliver solar cells are directly assembled into rafts or boats following separation from the cassette, group of cassettes, or multi-stack cassette, thus avoiding any further intermediate handling or storage steps.

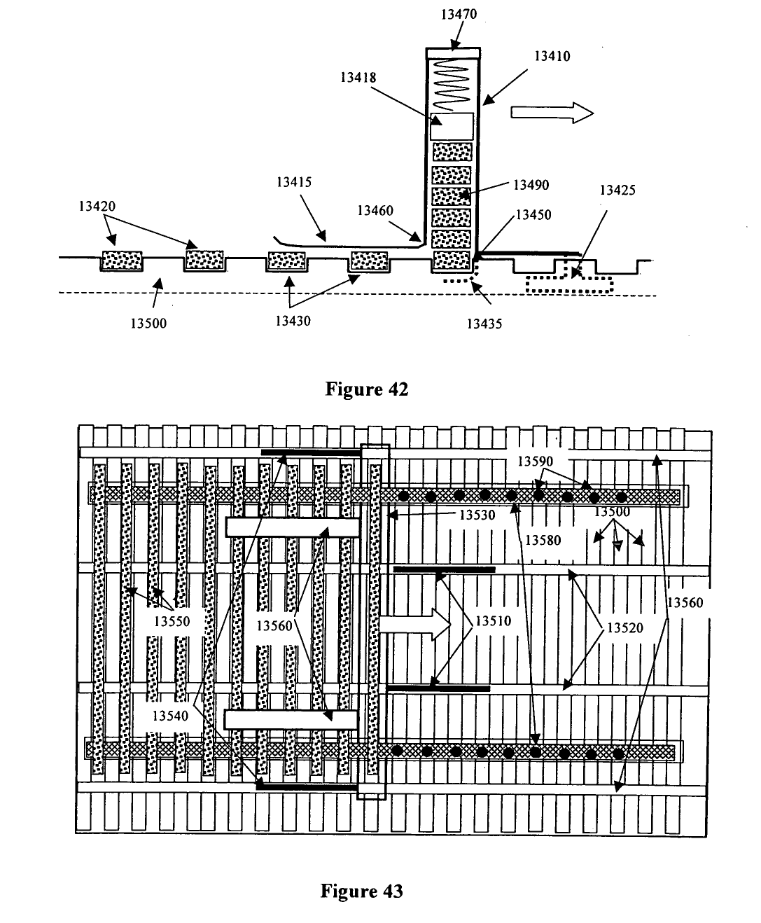

FIG. 42 shows a method for handling sliver solar cells contained in some form of bulk storage device such as a dispenser cassette. The dispenser cassette is used to mechanically dispense sliver solar cells 13420, 13550 into an array of aligned, correctly oriented sliver solar cells with an array pitch, or relative location with reference to adjacent sliver solar cells, that matches the desired pitch of the raft or boat assembly. The dispenser cassette releases a single sliver solar cell into a groove 13430 or slot machined in a metal jig 13500. The groove or slot locations have a lateral pitch that matches the relative sliver solar cell locations in the raft or boat assembly.

The sliver solar cells are mechanically removed from the base of the cassette by the approaching wall of the groove 13450. The groove depth 13430 is designed to be slightly less than the sliver solar cell thickness 13420 so that only one sliver solar cell at a time is engaged by the grooves in the metal jig. The width of the grove is designed to be slightly wider than the width of the sliver solar cell so that the sliver can rest in the groove without jamming or being crushed. The rear gate 13460 of the sliver solar cell dispense cassette is designed to be slightly higher than the top surface, or face, of the sliver solar cell resting in the groove. This ensures that the sliver solar cell adjacent to, or next higher than, the sliver solar cell that is being dispensed is retained in the sliver solar cell dispensing cassette until the next vacant groove is presented.

The top 13470 of the dispensing cassette 13410 is enclosed to contain a follower-plate 13480 that applies pressure to the stack 13490 in the dispensing cassette. The level of pressure on the stack is selected so that the leading edge of the bottom sliver solar cell engages the far side of the groove-wall in the jig. After this stage, the pressure is selected to ensure that the sliver solar cell rests flat on the bottom of the groove. Once the sliver solar cell is flat on the bottom of the groove, and held there by pressure transferred from the adjacent sliver solar cell, the rear gate of the dispensing cassette can clear the rear edge and top face of the retained sliver solar cell. This sequence is repeated for all grooves in the array-forming jig as the dispensing cassette continues a transit of the metal jig until all grooves are filled. A trailing double-ended ski 13415, 13560 retains the sliver solar cell in the grooves to prevent them flipping or jumping as the rear gate and trailing edge of the adjacent sliver solar cell retained in the dispensing cassette slips over the front edge of the sliver solar cell in the groove.

The dispensing cassette may be kept in the correct alignment laterally and parallel to the grooves in the jig by guides 13425, 13510, 13540 running in slots 13520, 13560 machined into the jig. There may be more than one slot, and the slot may be located within the wafer array since the guide runs through the empty area of the jig before the sliver solar cells are dispensed. Alternatively, guides may be located behind the dispensing jig 13540 provided they lie outside the array area. A combination of guides before and after the dispensing cassette may also be used. Sliver solar cells are retained in the dispensing cassette by retention hooks 13435 that also travel through the guide grooves. The retention hooks allow the dispensing cassette to retain slivers during transfer between jigs, between arrays, and between storage and loading operations. The stack can be loaded into the dispensing cassette using bulk transfer methods.

The cells are removed from the dispensing cassette without the requirement for individually locating and engaging single sliver solar cells. Advantageously, the dispensed sliver solar cells may be more tightly held in the grooves in the alignment jig by the application of a vacuum through holes in the base of the grooves to the bottom face of the sliver solar cell. The vacuum is only used to hold or retain the sliver solar cell in the groove after the sliver solar cell has been dispensed. In one implementation of the dispensing cassette operation the vacuum is not used to remove the sliver solar cell from the dispensing cassette. Alternatively, the vacuum arrangement may be used to remove the sliver solar cell from the cassette, or to assist removal of the sliver solar cell from the cassette. Alternatively, the dispensed sliver solar cell array may be secured by a trailing skid or rail such as a double-ended ski that that slides over the top surface of the sliver solar cell, confining it to the groove, and prevents it from jumping out of the slot in the metal jig. A ski-like shape is preferred so that the pressure and contact is gradually removed as the ski transits the dispensed sliver solar cell rather than having pressure or contact abruptly ending such as would be the case with either with the rear edge of the adjacent sliver, or the rear gate of the dispense cassette, or a flat square-ended rail.

The motion continues until the required number of sliver solar cells for a raft or boat has been dispensed. The cross beams 13580 required to complete the raft array are previously prepared with adhesive 13590 in areas where the beam surface coincides with the sliver solar cell surface. The cross-beams required to complete the raft assembly may be presented to the top surface of the array and bonded in place. Alternatively, the cross beams can be prepared with adhesive material and then placed in special grooves running transversely to the sliver solar cell locating grooves. The grooves are formed in the metal jig so that the top surface of the beams lying in the grooves clears the underneath surface of the dispensed sliver solar cell. The clearance is selected to allow for the adhesive bond-line thickness, so that the raft or boat array is formed on top of the beams lying in the grooves. Further, the sliver solar cell dispensing on the metal jig may be continuous or semi-continuous. That is, for continuous-type assembly, the rafts or boats may be formed in a continuous or contiguous manner in a long metal jig. For semi-continuous assembly, the rafts or boats may be formed in a disjoint or semi-detached jig where each grooved section is only as long as the raft or boat assembly. These jig sections can be attached to a chain or belt conveyor to provide linear assembly of rafts or boats.

A photographic image of an array being assembled using a dispensing jig is shown in FIG. 43. The sliver solar cells are 1.00 mm wide and 70 microns thick. The grooves in the jig are 1.05° mm wide and 50 microns deep. The sliver solar cells are kept in place in the grooves immediately following dispensing by a trailing plane section of glass slightly inclined to the plane of the jig such that the pressure is gradually released and the final edge of the guard does not cause the sliver solar cells to jump or flip.

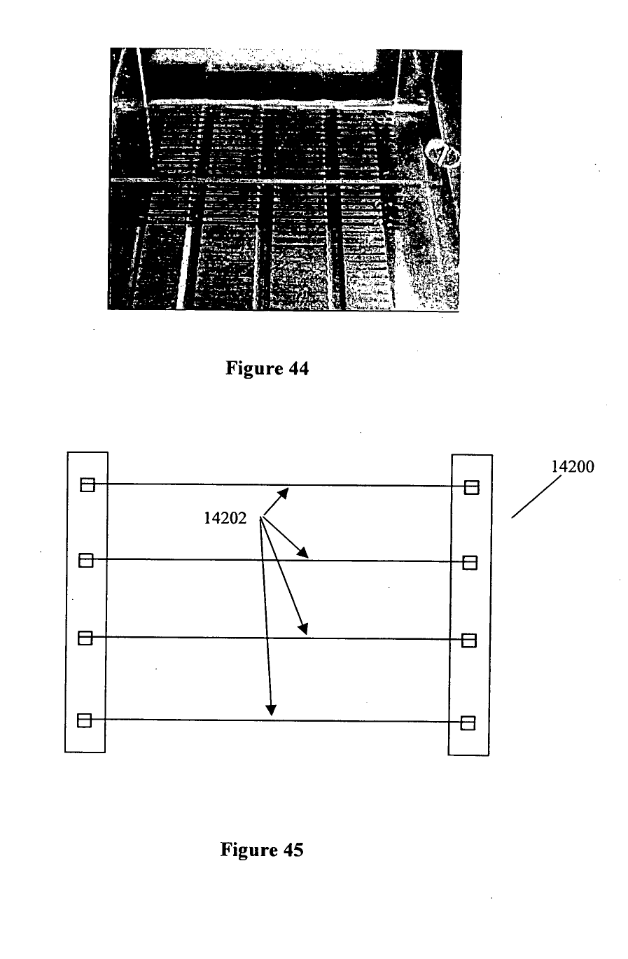

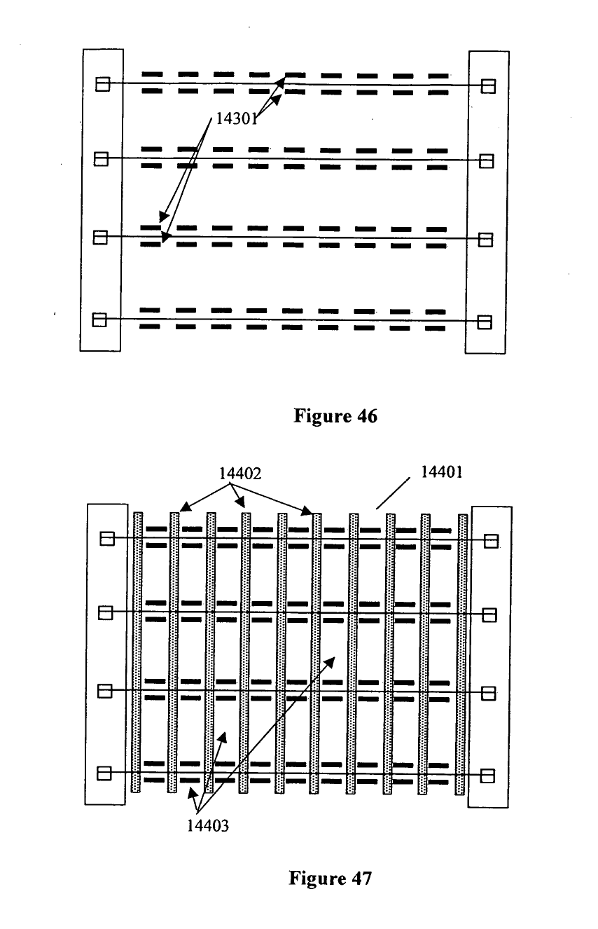

FIGS. 44 to 52 relate to an alternative embodiment, referred to as “mesh rafts”. As best shown in FIG. 8, 9-Assembly, 9-Assembly and 52 and hereafter referred to as “mesh rafts” 14900, the slivers 12401 in the mesh raft assembly can be held in place by the electrical connections 14902 alone, removing the requirement for a metallised track as well as the cross-beam or substrate. This embodiment is ideal for raft arrays, but may only be suitable for boats under certain circumstances.

The electrical inter-connections 14902 between the slivers 12401 are formed from thin wires 14202, which may be thicker than the slivers. The individual interconnect wires 14602 are formed from a number of single lengths of wire 14202, each longer than the length of the mesh raft array, providing for an extra length at the ends of the mesh raft array 14603, 14903 which can be used for stringing the mesh raft arrays 14900 together during module fabrication. The number of these long lengths of wire 14202 may be equal to the number of rows of interconnects corresponding to the number of cross beams in the embodiments described above. Alternatively, the number of rows of electrical interconnections can be increased substantially by staggering or offsetting the line of connections between individual slivers, or simply increasing the number of rows of interconnects within a mesh raft, because the use of thin wires rather than cross-beams or substrates almost eliminates the shading penalty incurred by the embodiments described above.

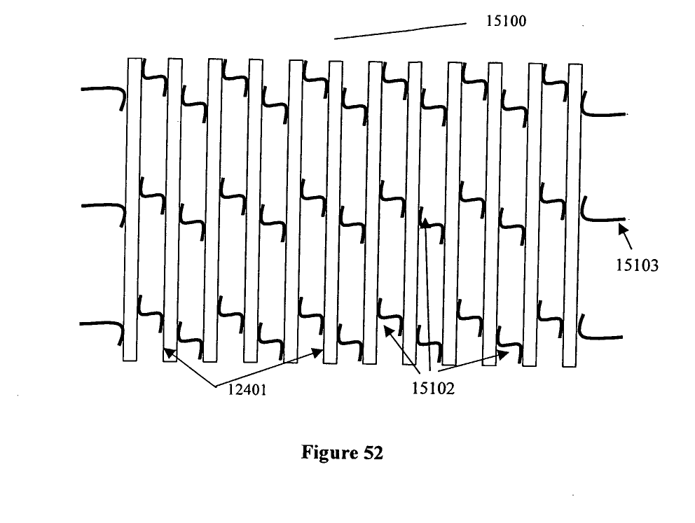

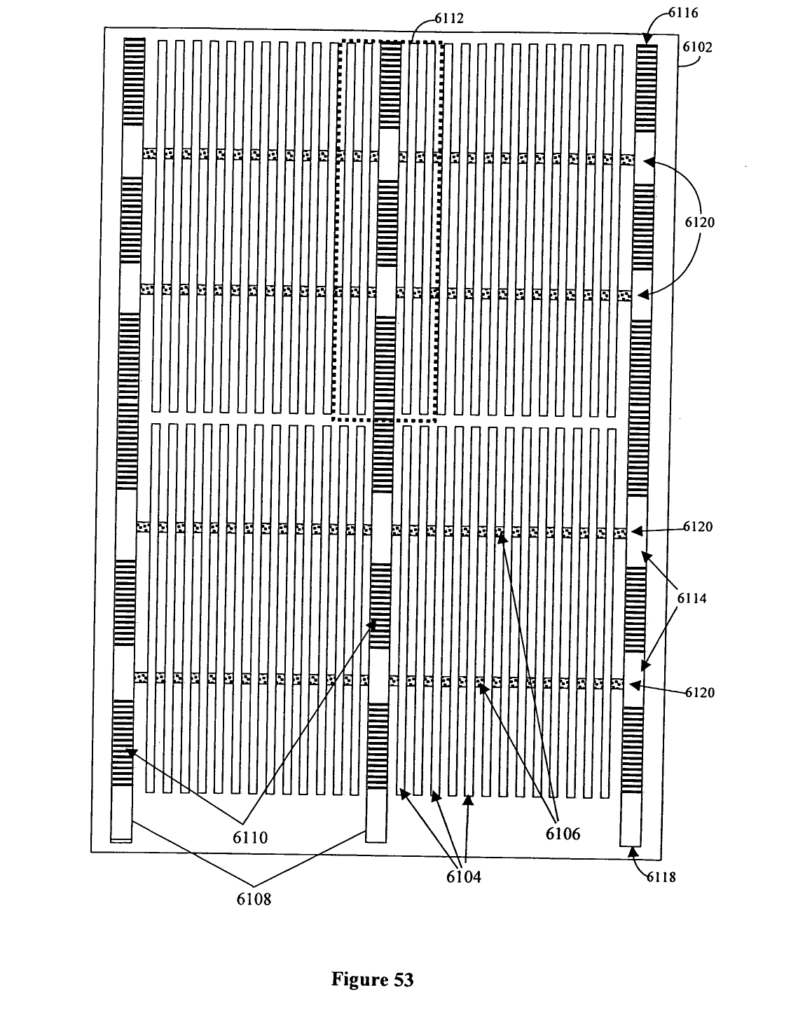

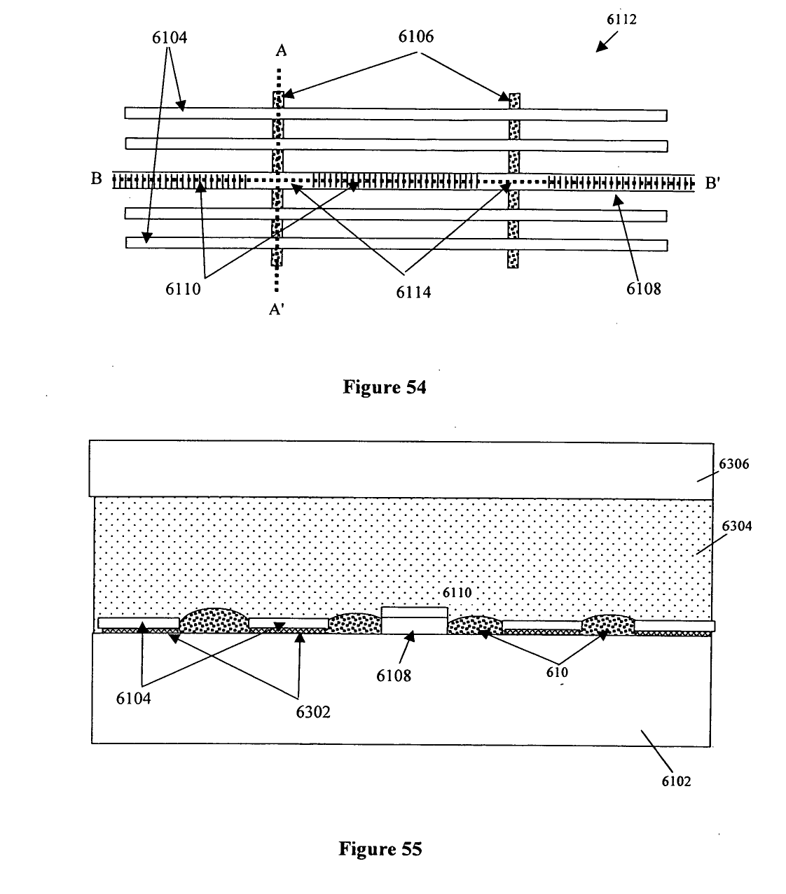

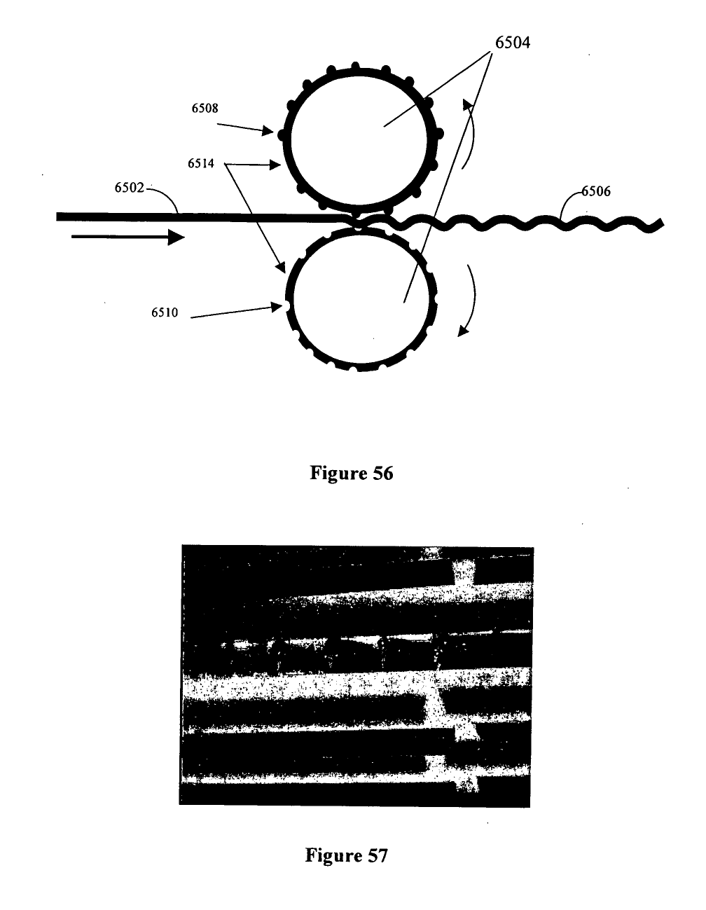

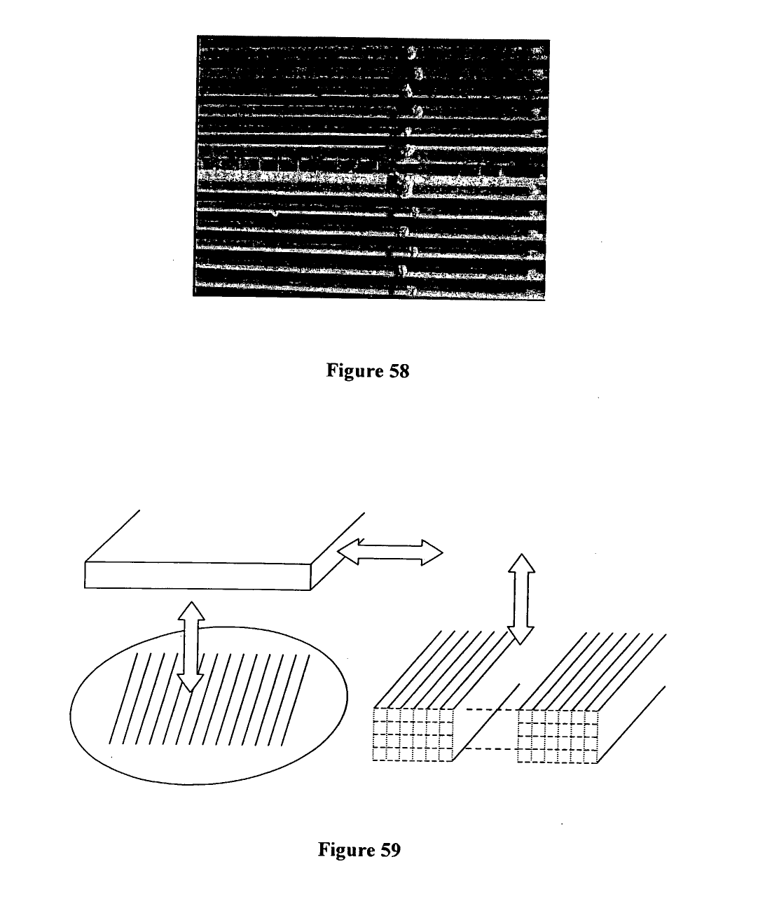

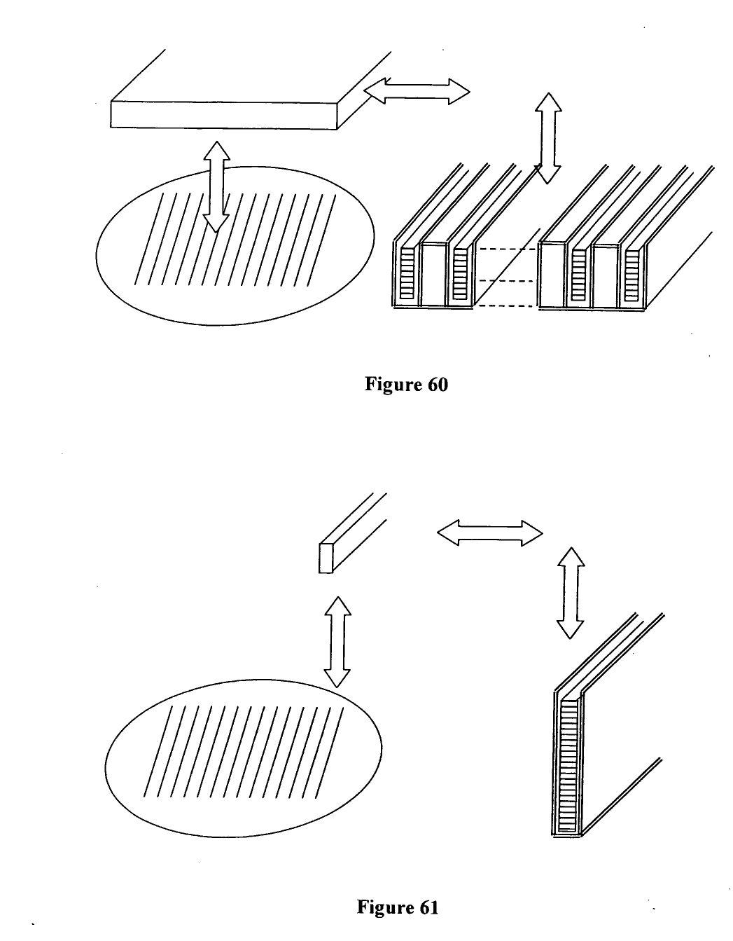

In the case of staggered or offset electrical interconnections 15102 within offset rows shown in FIG. 52, the length of the wire running along the electrode on the edge of the slivers may be longer, or alternatively, the extra length arising from spanning an integral number of sliver pitches greater than one with a staggered or offset pair of rows can be removed during the cutting operation.

The short wire lengths forming the electrical interconnections may be “S”-shaped, or “U”-shaped, or any other convenient shape that provides arms 14802 that run along the sliver electrodes 14803 for a sufficient length to enable the formation of a reliable electrical connection 14904 between the electrodes of adjacent slivers by convenient means such as soldering or bonding with conductive epoxy, and an intermediate section 14902 between the two contact arms 14802 that is convenient for gripping with the mechanical tweezers 14301.

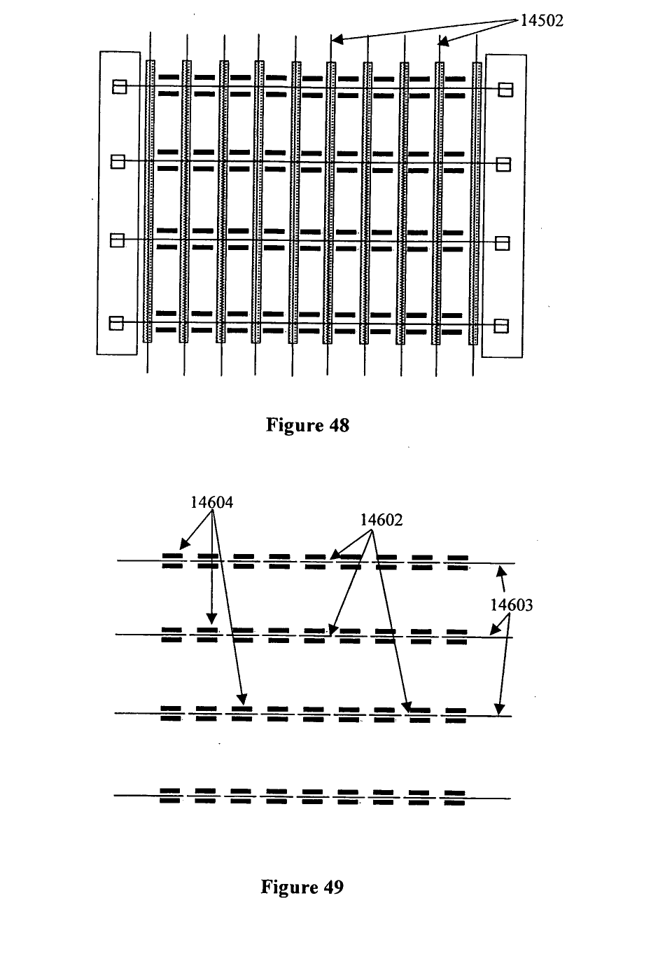

The wire interconnects for the entire mesh raft are formed in a highly parallel process which avoids the requirement of picking or placing individual short wires used to establish sliver cell interconnects. The wires corresponding to each track or row of interconnects 14202 are strung, with a longitudinal spacing along the direction of the length of the sliver 14401 corresponding to the electrical interconnect row spacing in the mesh raft, across a frame 14200 which has a length greater than the length from the remote ends of the mesh raft stringing interconnects 15003 or 15103. A set of mechanical tweezers 14301 with a comb-like array of fingers grips the intact, strung wires, 14202. Preferably, each row or set of tweezers 14201 is formed from two base-plates with aligned, slightly flexible resilient fingers formed from the plates, or rigidly attached to the plates, so that the gripping action is achieved by only two axes of control, rather than a line of individual tweezers requiring individual control. The individual gripping fingers of the tweezers 14301 in each set have a lateral spacing along the length of the wire, which is transverse to the direction of the length of the slivers 12401 in FIGS. 48 to 51, and with centres corresponding to the centres of the short wire sections 14902 required to interconnect the slivers 12401 in the mesh raft 14900, 15000, 15100. The banks of rows or sets of tweezers 14301 have a longitudinal spacing, along the length of the slivers 12401 which run at right angles across the string of wires 14202. The wires, 14202, run in a direction transverse to the slivers, corresponding to the centre-line of the rows of electrical interconnects 14902 in the mesh raft array 14900, 15000, 15100. This arrangement of tweezers 14301 means that after the strung wires 14202 are cut 14602 to the required length the tweezers will grip the individual wires, which will be used to establish individual connections 14904, 14902 between adjacent sliver electrodes 14803.

The strung wires 14202 are all cut into an array of correctly located individual wires 14602 simultaneously in a simple process as shown in FIG. 49. A grooved anvil 14401 is introduced below the wires, with the top of the lands 14402 between the grooves 14403 corresponding to the centre-line of the slivers 12401 in the mesh raft array 14900, 15000, 15100 between which the electrical connections 14902, 15002, 15102 will be established. A set of blades, 14502, adjusted to the centre-line of the slivers 12401 in the mesh raft array 14900, 15000, 15100 between the individual interconnects presses down from above the wires 14202 onto the lands 14402 of the anvil 14401, severing the strung wires 14202 into an array of short wires 14602 held by the tweezers 14604. The blades 14502 and the anvil 14401 are then removed from the vicinity of the array, leaving the array of short wires 14602 retained by the slotted tweezers 14604, as shown in FIG. 49.

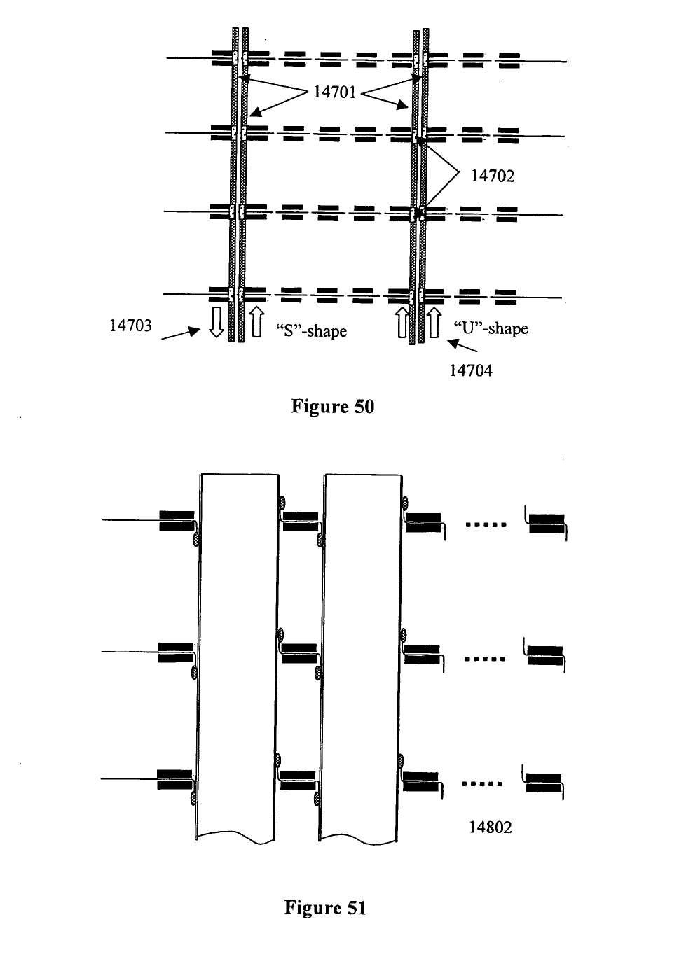

The array of short wires 14602 is then bent into an array of “U”—or “S”-shaped planar connectors in a one- or two-step process. As shown in FIG. 50, a series of narrow slotted plates 14701 are introduced into the array 4602. For clarity, only two pairs are shown in FIG. 50. The slots 13702 in the plates 14701 correspond to the wire positions protruding from the array of tweezers. Consequently, displacing the plates 14701 in a direction transverse to the length of the wires bends the ends of the wire in the direction the plate is displaced when the walls of the slots contact the ends of the wires. Pairs of plates 14701 between each set of tweezers 14604 can be used with one application. Alternatively, a single plate 14701 between a pair of tweezers 14604 may be used in a two-step process. The plate 14701 is inserted, displaced, and then removed, to be reinserted to bend the wire on the other side of the tweezers 14604. The plate 14701 is again displaced laterally; either in the same direction to form a “U”-shape, or in the opposite direction to form an “S”-shaped connector 14902, with the plane of the “S” lying in the plane of the sliver raft. If the plates are thinner than the length of wire protruding from the jaws of the tweezers, then an “S”-shaped planar connector can be formed in two steps using the process just described.

If the plates 14701 are thicker than the length of wire protruding from the tweezers 14604, with a thickness up to the gap between the jaws of the tweezers 14604 less double the thickness of the wire, a “U”-shaped planar connector can be formed with a single displacement of the notched plate 14701. The width of the individual jaws of the tweezers 14604 is selected to facilitate the formation of the desired short-wire interconnection.

The planar array of short-wire interconnects 14602, with a lateral spacing corresponding to the pitch of the mesh raft array, and a longitudinal spacing corresponding to the location of the rows of interconnects within the mesh raft is introduced into a prepared sliver cell array which can be assembled by any of the methods described above. The assembled sliver cell array is held in a frame or jig, with recesses along the lateral line of interconnects 14802 that allows the nose of the tweezers 14301 to protrude to the rear and bring the array of bent planar wire connectors 14602 into the plane of the electrodes 14803 in the sliver array. Electrical and mechanical connections 14904 can be formed by soldering the wires to the electrodes, or by bonding with conductive epoxy or similar material. If soldering is performed at this stage an infra-red heating or hot-air process is used because the wires need to be mechanically constrained until the electrical connections are complete.

Advantageously, the mechanical and electrical connection process can be decoupled. Mechanical integrity can be achieved by bonding the wire 14902 to the electrode 14803 with SMT adhesive, or other conductive or non-conductive material over a short section of the contact length of the wire arm and the electrode. Electrical connection, 14904 and improved mechanical integrity, can be provided later at a more convenient time and using a more convenient and reliable soldering process during the subsequent assembly process. Preferably, the electrical connections are established using a wave solder process.

The mesh raft 14900, 15000, 15100 described above is particularly suitable for flexible module construction. Slivers are quite flexible along their length, and can be bent in a curve normal to an optically active face with a radius of curvature of around 2 cm. However, slivers are not at all flexible in the plane parallel to an optically active face, and will shatter before any bend is visible. Very thin wires are also very flexible, and, very importantly for flexible module applications, will bend equally in all directions. A grid of slivers, such as a raft with sliver cross beams is quite flexible in the longitudinal direction along the length of the sliver cell array when bent in a curve lying in a plane normal to the face of the slivers, and also in the transverse direction along a curve lying in the same plane of orientation for the thin sliver cross beam. However, the sliver cell and sliver cross-beam array, when bonded in a grid, is significantly less flexible when curved in a plane lying in a direction inclined to the longitudinal axes of the slivers and the cross-beam because stresses are set up in the plane of the slivers in a direction that the slivers cannot flex, rather than normal to the plane of the slivers and the raft in a direction over which the slivers can easily flex. The introduction of the thin, short-wire interconnects relieves stresses in the plane of the mesh raft array.

In the foregoing description, the engaging or dispensing motion should be understood as being relative. That is, the vacuum engagement tool or dispensing cassette may be stationary and the wafer array or grooved jig may be moved to remove the array or dispense the sliver solar cells into the metal jig grooves. The moveable jig may take the form of sub-sections held on a chain conveyor or some other suitable transport mechanism. If the assembly of sliver solar cells into sub-modules is performed in a continuous manner, the transport mechanism can proceed through the adhesive curing stage and the electrical connection stage in a linear fashion.

### Release, Handling and Storage of Planks

As described above and in the sliver patent application, sliver solar cells have optically active faces that are perpendicular to the faces of the original wafer from which they are formed. However, in general elongate solar cells can be formed with their optically active faces in the same plane as the original elongate substrates are formed, as is the case with plank solar cells, as described above. The sliver solar cell release processes described above have been developed to expose an optically active face of each sliver solar cell. However, in the case where an optically active surface of the elongate solar cell is formed on the same plane as the original starting wafer, as in plank solar cells, the following process can be used to release the plank or other form of elongate solar cells.

Although the process and apparatus are described in terms of plank substrates in which solar cells have been formed, it will be apparent that the methods and apparatus are not limited to use with plank solar cells, but can be used with any form of elongate substrate, which may or may not incorporate solar cells.

Referring to FIG. 59, a wafer incorporating a plurality of elongate plank substrates is supported on a chuck. The planks can be partially pre-cut at the ends to facilitate easy snapping out of the wafer frame. The entire array of planks can be stacked in a plank “slab” frame from which individual stacks can be removed and stored in a single stack cassette or a multi-stack cassette. Removal of a single stack can be performed with a narrow clamp arrangement from the plank-ends edge of the slab frame array holder mechanism. Preferably, the single stacks are removed from the array holder edge at the long side of the plank stack using a wide clamp with a short throat. The array holder assembly has slots in the base to allow the clamp to access successive stacks, avoiding the requirement of moving the remaining stacks in the array to the side for easy clamp access. Alternatively, the remote array holder wall can be spring-loaded or moved in an indexed manner so that the plank stack to be removed is always in place against the access wall. The removed single stacks can be loaded into a single-stack dispensing cassette (and then handled as described above for slivers) or into a multi-stack cassette-(and then handled as described above for slivers).

In some cases, it can be advantageous to have the elongate substrates stored in mutually spaced stacks with the separation between adjacent stacks (the stack pitch) selected to correspond to the desired arrangement of elongate substrates in a submodule to be formed from the elongate substrates.

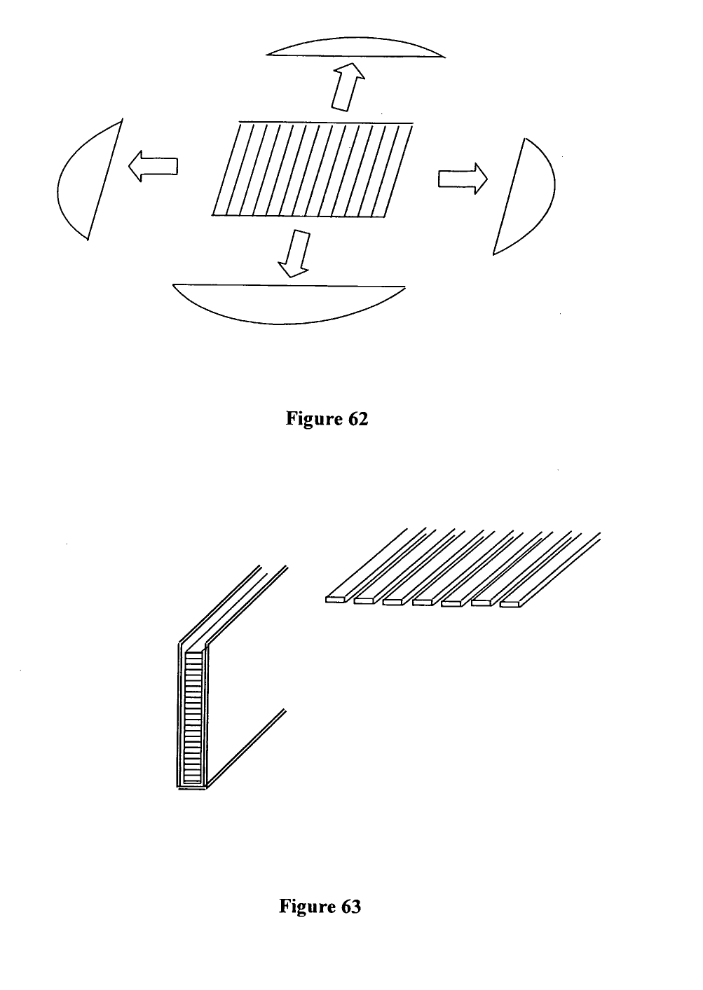

Referring to FIG. 60, every second plank is removed by a mechanical separation head (vacuum, electrostatic, sticky, re-useable etc) and stacked in a multi-stack cassette with 2× stack array pitch. A two-step operation sequence is required to remove all planks and stack in the 2× cassette, ready for dispensing (as described above for slivers). Alternatively, a three-step operation can be used to stack the planks for a 3× pitch etc. This is a preferred method for loading a 2× or 3× pitch multi-stack cassette for subsequent formation of entire sub-module arrays of plank solar cells (as described above for slivers).

Referring to FIG. 61, planks are individually removed by mechanical separation head and stacked in a single-stack cassette. Alternatively, the removed planks can be stacked sequentially in a multi-stack cassette. This process is useful if a plank pitch other than integral 2×, 3× etc formed by the multiple plank removal in FIG. 60 is required. Subsequent processing as for slivers.

Referring to FIG. 62, the plank wafer can be held by the top and bottom faces covering the plank array window in a clamp that leaves the four or more edges of the plank wafer frame exposed. The plank wafer frame is successively removed by snapping the four or more exposed sections. These sections may be partially pre-cut, or could be removed by a scribe-and-break process. The top section of the clamp is then removed, exposing the plank array. The base section of the clamp may have an array of vacuum ports to retain the planks in the original spacing and orientation. Alternatively, the base section may be coated with a re-usable partially sticky coating to prevent misalignment of the released planks. The planks can be removed in an entire array to an array slab holder (as shown in FIG. 59) or removed to multi-stack cassettes (as shown in FIG. 60) from which entire arrays are formed. The clamp arrangement may consist of clamp faces moved by linear actuators for example in a fully automated in-line process where the wafer enters the line, is clamped, the exposed edges snapped off, the separated planks removed singly in a sequential process to a single-stack cassette, or integrally in a spaced array to an appropriately pitched multi-stack array, or in a complete continuous array to a plank slab holder frame.

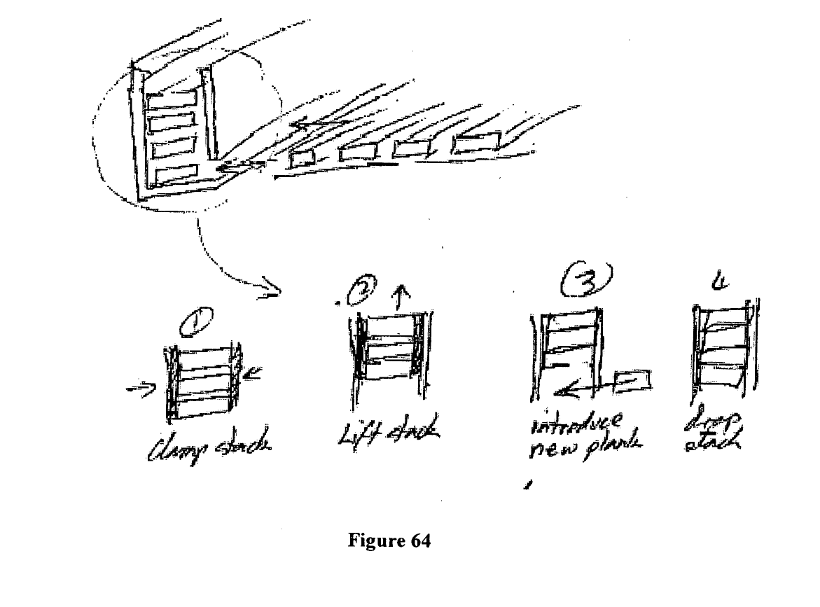

Referring to FIG. 64, a plank wafer is held by a clamp covering the top and bottom faces leaving the four or more edges exposed. The plank wafer frame is successively removed by snapping the four or more exposed sections. These sections may be partially pre-cut, or could be removed by a scribe-and-break process. The top section of the clamp is then removed, exposing the plank array. The base section of the clamp has a mechanical confinement arrangement that covers a portion of the top of the end faces of the planks. The clearance between the top surface of the plank solar cell and the under surface of the mechanical retainer is sufficiently less than the thickness of the plank cells in order to prevent jamming or doubling up of plank cells in the released array.

The opening or portal at the array removal end of the mechanical confinement mechanism is at least as wide as the length of the retained plank cells. The array of released plank cells is moved towards the opening by a plate at the edge of the plank array remote from the portal or removal edge. The surface of the clamp supporting the bottom face of the plank cell array ends in an edge parallel to the long edge of the plank cell array. The edge is constructed such that a single-stack cassette can be loaded directly from planks in the released array.

Several processes can be used to load plank cells into the cassette.

The cassette can be loaded from the top. In this case, it is important to ensure that the top surface of the plank residing or previously stored in the cassette is close enough to the top of the cassette and the plane of the top surface of the clamp, which forms the transfer slide surface, so that the plank cannot flip or jam at an angle in the top of the cassette. The rear edge of the plank entering the cassette is disengaged from the front edge of the plank, leaving or about to leave the transfer slide surface. These two requirements can be met by a mechanically linked spring mechanism. The mechanically linked mechanism actuates a dual pair of “walking beams” that grip the edge of the plank cell stack, level with the top loading surface of the cassette, and depress the stack by a preset distance which is the thickness of a plank cell plus the required clearances and tolerances. The plank cell is slid into the cassette, and the process repeats.

Alternatively, these requirements can be met by sensors and electronic control mechanisms. The motion of the planks is essentially the same.

Preferably, the plank to be inserted into the single stack cassette is singulated from the presented array which has been slid near to the edge of the clamp base/cassette mouth by a soft rubber wheel engaging the top surface of the plank, with the wheel being driven in a direction such that the plank is slid towards the cassette faster than the slide pushing the rest of the array. The plank so separated from the array can be “driven through” a sequence of mechanical interlocks. The mechanical system is arranged such that individual sensors and logical or electronic processing is not required. Subsequent planks in the array cannot proceed into the next sequential step until the plank being transported has cleared that particular mechanical interlock. Alternatively, a logically identical process can be implemented with electronic sensors and linear drive transport and logical control mechanisms.

The embodiment of FIG. 64 is a similar process to top-loading cassettes, but here the cassettes are loaded from the base. As in FIG. 62, the plank wafer is held by a clamp covering the top and bottom faces leaving the four or more edges exposed. The plank wafer frame is successively removed by snapping the four or more exposed sections. These sections may be partially pre-cut, or could be removed by a scribe-and-break process. The top section of the clamp is then removed, exposing the plank array. The base section of the clamp has a mechanical confinement arrangement that covers a portion of the top of the end faces of the planks. The clearance between the top surface of the plank solar cell and the under surface of the mechanical retainer is sufficiently less than the thickness of the plank cells in order to prevent jamming or doubling up of plank cells in the released array.

The separated array is now an array of plank cells with the same spacing and orientation as the planks in the host wafer. The opening or portal at the array removal end of the mechanical confinement mechanism is at least as wide as the length of the retained plank cells. The array of released plank cells is moved towards the opening by a plate at the edge of the plank array remote from the portal or removal edge. The surface of the clamp supporting the bottom face of the plank cell array ends in an edge parallel to the long edge of the plank cell array. The edge is constructed such that a single-stack cassette can be loaded directly from planks in the released array.

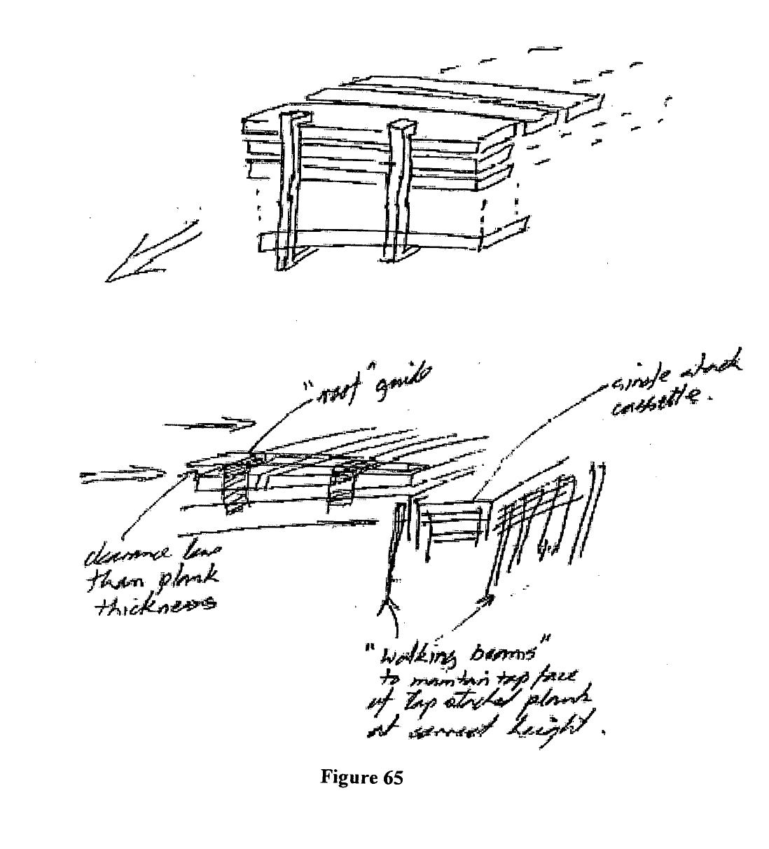

There are several processes for transferring plank cells into the bottom-loading cassette. In the case of FIG. 65, it is important that the bottom surface of the plank residing or previously stored in the cassette clears the upper edge of the cassette loading opening in order to allow the next plank to be placed within the cassette. This can be accomplished by a mechanical system introduced from the rear face of the bottom-loading cassette. A walking beam system, similar to the top loading mechanism, raises the stack in the cassette by the required amount to provide the clearance. In this case, only one half of the walking beam system is required. The new plank is loaded into the base of the cassette. The stack is released by the walking beam clamp, and the clamp re-engages at the bottom of the stroke, raising the new stack with the new plank at the base of the stack, by the same distance to give the clearance as before. The cycle continues until the cassette is full.

The rear edge of the plank entering the cassette must be disengaged from the front edge of the plank leaving or about to leave the transfer slide surface. These two requirements can be met by a mechanically linked spring mechanism. The mechanically linked mechanism actuates a dual pair of “walking beams” that grip the edge of the plank cell stack, level with the top loading surface of the cassette, and depress the stack by a preset distance which is the thickness of a plank cell plus the required clearances and tolerances. The plank cell is slid into the cassette, and the process repeats.

Alternatively, these requirements can be met by sensors and electronic control mechanisms. The motion of the planks is essentially the same.

Preferably, the plank to be inserted into the single stack cassette is singulated from the presented array which has been slid near to the edge of the clamp base/cassette mouth by a soft rubber wheel engaging the bottom surface of the plank, with the wheel being driven in a direction such that the plank is slid towards the cassette faster than the slide pushing the rest of the array.

The bottom loading cassette is the preferred version for single-stack cassettes, suitable for dispensing, because the bottom-loading system is insensitive to the number of planks already in the cassette. The partial plank stack need only be lifted a defined distance in order to insert the next plank, and no track need be kept of the number of planks already in the cassette—or the height of the stack. For an electronic/sensor based implementation, this is not a major factor. For a basic mechanical system with fast, cheap, and simple process and equipment, it is a valuable simplification.

The apparatus and processes described herein allow the production of easily handled raft, mesh raft, or boat sub-module assemblies which greatly reduce the number of individual assembly steps required when compared with present practice for assembling photovoltaic power modules from elongate solar cells. The raft, mesh raft, and boats sub-module assemblies allow easy use of conventional photovoltaic module assembly equipment, and allow conventional photovoltaic module materials to be used in manufacturing photovoltaic power modules from assemblies of elongate solar cells.

The raft, mesh raft, and boat sub-module assemblies described herein provide the manufacturer of elongate solar cells with the ability to handle and assemble large numbers of elongate solar cells in a fast, efficient, reliable, high-yield, high throughput, and low cost process using conventional photovoltaic module materials.

The present invention in its various forms provides, inter alia, the following advantages:
(i) Removal of individual sliver solar cells from each wafer separately, but each separation cycle handles large numbers of sliver solar cells in a large-scale parallel fashion, in every implementation always without the need to resort to locating, engaging, separating, handling, placing or assembling individual sliver solar cells singly.
(ii) Engaging bulk sets or entire arrays of sliver solar cells by their faces, each sliver solar cell pre-located in the required relative position with respect to adjacent sliver solar cells, and forming a full raft assembly in one process cycle.
(iii) Eliminating the requirement for expensive equipment and high-level automation control necessary to achieve precise individual sliver solar cell positioning such as that required for individual sliver solar cell placement and assembly concepts; the relative location and orientation of the sliver solar cells in each raft assembly being determined either by the alignment jig or the stack array in the multi-stack bulk cassette.
(iv) Eliminating the problem of debris generated in the in-line separation and assembly processes of sliver solar cell module construction, providing a clean array of separated sliver solar cells, without any separation fragments contaminating the array or subsequent assembly area.
(v) Positively maintaining the orientation and polarity of the sliver solar cell during each stage of assembly.
(vi) The sliver solar cell raft or boat is a convenient collective form of groups of sliver solar cells that allows easy subsequent assembly of modules using conventional equipment, materials, and handling processes.
(vii) Eliminates the requirement for large-scale precision and large-scale fine-tolerance engineering and complex control systems. All raft and boat assembly operations can be easily executed by hand, in a short time, and minimal expense.
(viii) The use of thin-wire interconnects for mesh rafts significantly reduces the shading of the slivers, particularly shading of sections of the rear surface of the slivers cells where the slivers are bonded to the cross beams, and eliminates the requirement of preparation and metallisation of raft cross beams.
(ix) Flexible, fully symmetric bi-facial modules can easily be constructed using the thin-wire mesh raft assembly process which provides thin assemblies of slivers which have flexibility in many planes
(x) Automation of the assembly operation is very straightforward. Handling 50 sliver solar cells at a time in each assembly operation cycle greatly simplifies handling and provides a dramatic increase in assembly throughput.

Sliver removal, handling and storage processes and apparatus described herein advantageously maintain the orientation and polarity of sliver solar cells during separation, handling, and sub-module assembly, provide significant simplification of the sliver solar cell handling and photovoltaic module assembly process, produce easily handled raft or boat sub-modules which greatly reduce the number of individual assembly steps required, allow the easy use of conventional photovoltaic module assembly equipment, allows conventional photovoltaic module materials to be used in manufacturing sliver solar cell modules.

The foregoing describes only some embodiments of the invention and it will be apparent to those skilled in the art that, in the light of this disclosure, numerous changes, substitutions and alterations may be made without departing from the spirit and scope of the invention.

1. A solar cell sub-module for a photovoltaic device, including a plurality of elongate solar cells mounted in a structure that maintains the elongate solar cells in a longitudinally parallel and generally coplanar configuration, the structure providing one or more conductive pathways electrically interconnecting the elongate solar cells.

2. A solar cell sub-module as claimed in claim 1, wherein the elongate solar cells are mounted to a thermally compatible support to prevent damage to the elongate solar cells or the one or more conductive pathways during a change in temperature.

3. solar cell sub-module as claimed in claim 1, wherein the elongate solar cells and the one or more conductive pathways form the structure.

4. A solar cell sub-module as claimed in claim 1, wherein the elongate solar cells are electrically interconnected in series to increase the output voltage of the solar cell sub-module.

5. A solar cell sub-module as claimed in claim 1, wherein the elongate solar cells are electrically interconnected in parallel to reduce the effect of shadowing on output of the sub-module.

6. A solar cell sub-module as claimed in claim 1, wherein the elongate solar cells are electrically interconnected as groups electrically interconnected in parallel, with the elongate solar cells in each group being electrically interconnected in series.

7. A solar cell sub-module as claimed in claim 1, wherein the elongate solar cells abut one another.

8. A solar cell sub-module as claimed in claim 1, wherein the elongate solar cells are mutually spaced.

9. A solar cell sub-module as claimed in claim 8, wherein each of the elongate solar cells includes two active faces, and the spacing between elongate solar cells is selected on the basis of illumination of the active faces of the elongate solar cells and the number of elongate solar cells in the sub-module.

10. A solar cell sub-module as claimed in claim 1, wherein the structure includes at least one support to which the elongate solar cells are mounted.

11. A solar cell sub-module as claimed in claim 10, wherein the at least one support is compliant to accommodate thermal expansion of the elongate solar cells.

12. A solar cell sub-module as claimed in claim 1, wherein the structure is encapsulated within a transparent encapsulating material.

13. A solar cell sub-module as claimed in claim 1, wherein the structure includes one or more crossbeams to which the elongate solar cells are mounted.

14. A solar cell sub-module as claimed in claim 1, wherein the one or more crossbeams are silicon.

15. A solar cell sub-module as claimed in claim 1, wherein the one or more crossbeams are a polymer, a ceramic, a metal or a glass.

16. A solar cell sub-module as claimed in claim 1, wherein the size of the structure is selected to be substantially the same as the size of a standard solar cell.

17. A solar cell sub-module as claimed in claim 1, wherein the elongate solar cells are mounted on an electrically insulating continuous or semicontinuous support.

18. A solar cell sub-module as claimed in claim 17, wherein the one or more conductive pathways are formed on the electrically insulating support.

19. A solar cell sub-module as claimed in claim 18, wherein the electrically insulating support is substantially silicon.

20. A solar cell sub-module as claimed in claim 18, wherein the electrically insulating support is substantially borosilicate glass, plastic, or ceramic.

21. A solar cell sub-module as claimed in claim 17, wherein the support is mounted to a heat sink.

22. A solar cell sub-module as claimed in claim 1, wherein the elongate solar cells and one or more conductive pathways substantially form the structure.

23. A photovoltaic device including a solar cell sub-module as claimed in claim 22, the device further including a reflector mounted behind the solar cell sub-module to reflect light passing through gaps between the elongate solar cells back towards the elongate solar cells to improve the efficiency of the photovoltaic device.

24. A solar cell sub-module as claimed in claim 1, wherein each of the elongate solar cells includes electrically conductive contacts on at least two adjacent surfaces of the solar cell, and the one or more conductive pathways are substantially planar electrically conductive regions that are mounted to the electrically conductive contacts of the elongate solar cells, thereby electrically interconnecting the elongate solar cells.

25. A solar cell sub-module as claimed in claim 1, including a sheet of pliant material mounted to the structure to provide a resilient solar cell sub-module.

26. A solar cell sub-module as claimed in claim 1, including a substantially rigid curved support to which the structure is conformally mounted.

27. A photovoltaic device including a plurality of solar cell sub-modules as claimed in claim 1.

28. A method of forming a solar cell sub-module for a photovoltaic device including the steps of:
mounting a plurality of elongate solar cells in a structure that maintains the elongate solar cells in a substantially longitudinally parallel and generally co-planar configuration; and
establishing one or more conductive pathways extending through the structure to electrically interconnect the elongate solar cells.

29. A method as claimed in claim 28, including mounting the structure to a substantially rigid curved support to provide a curved solar cell sub-module.

30. A method as claimed in claim 29, wherein the substantially rigid curved support is transparent.

31. A method as claimed in claim 30, wherein the substantially rigid curved support is glass.

32. A method as claimed in claim 29, wherein the substantially rigid curved support is a curved extruded aluminium receiver for a linear concentrator.

33. A method as claimed in claim 28, including conformally mounting the structure to a substantially rigid planar support and deforming the resulting assembly to provide a non-planar solar cell sub-module.

34. A method as claimed in claim 28, including processing at least a portion of one or more faces of each of the elongate solar cells in the solar cell sub-module.

35. A method as claimed in claim 34, wherein said processing includes depositing a coating on at least a portion of the one or more faces.

36. A method as claimed in claim 35, wherein said coating includes at least one of an anti-reflection coating, a passivation coating, and metallisation.

37. A substrate release process, including: receiving a wafer including a plurality of elongate substrates interconnected by lateral wafer frame portions, the wafer further including proximal and distal wafer frame portions;
removing at least one of said proximal and distal wafer frame portions to expose a face of a corresponding one of said elongate substrates;
engaging at least one of the lateral wafer frame portions to secure the plurality of elongate substrates, without engaging the edges of the plurality of elongate substrates;
applying elongate substrate engaging means to the exposed face of the exposed elongate substrate to engage the exposed elongate substrate; and
moving the elongate substrate engaging means away from the plurality of elongate substrates to release the exposed elongate substrate from the remaining elongate substrates.

38. A substrate release process as claimed in claim 37, including storing the released elongate substrate at the top of a stack of elongate substrates in an elongate substrate dispensing unit.

39. A substrate release process as claimed in claim 37, wherein the plurality of elongate substrates are elongate solar cells.

40. A substrate release process, including:
receiving a plurality of wafers, each of the wafers including a plurality of elongate substrates interconnected by lateral wafer frame portions, the wafers further including proximal and distal wafer frame portions;
removing at least one of said proximal and distal wafer frame portions from each of the wafers to expose a face of a corresponding one of said elongate substrates of each wafer;
engaging at least one of the lateral wafer frame portions of each wafer to secure the plurality of elongate substrates, without engaging the edges of the plurality of elongate substrates;
wherein the engaged wafers are arranged so that the exposed elongate substrates are presented as an array of mutually spaced elongate substrates.

41. A substrate release process as claimed in claim 40, further including: applying elongate substrate engaging means to the exposed elongate substrates to engage the exposed elongate substrates; and moving the elongate substrate engaging means away from the plurality of elongate substrates to release the engaged elongate substrates from the remaining elongate substrates whilst maintaining the separation between adjacent exposed elongate substrates and the relative orientation of the engaged elongate substrates.

42. A substrate release process as claimed in claim 41, wherein the number of wafers and the separation between the engaged wafers are selected on the basis of an arrangement of elongate substrates in a sub-module to be assembled from the engaged elongate substrates.

43. A substrate release process as claimed in claim 41, wherein the elongate substrate engaging means includes a vacuum tool.

44. A substrate release process as claimed in claim 41, wherein the elongate substrate engaging means includes a static electricity attraction tool.

45. A substrate release process as claimed in claim 41, wherein the elongate substrate engaging means includes a substantially rigid member to which an adhesive has been applied.

46. A substrate release process as claimed in claim 45, wherein the adhesive is a reusable adhesive.

47. A substrate release process as claimed in claim 45, wherein the adhesive has been applied at locations corresponding to the spacing between the exposed elongate substrates.

48. A substrate release process as claimed in claim 45, wherein the substantially rigid member includes a component of a solar cell sub-module to be assembled from the engaged elongate substrates.

49. A substrate release process as claimed in claim 48, wherein the component includes a crossbeam of the sub-module.

50. A substrate removal process as claimed in claim 41, including attaching the engaged elongate substrates to a second plurality of elongate substrates to form an elongate substrate sub-module.

51. A substrate removal process as claimed in claim 41, including moving the engaged elongate substrates to a storage unit and releasing the engaged elongate substrates for storage in the storage unit.

52. A substrate removal process as claimed in claim 51, wherein the storage unit is adapted to store elongate substrates in mutually spaced stacks of elongate substrates.

53. A substrate removal process as claimed in claim 51, wherein the storage unit is adapted to expose at least a portion of a face of elongate substrates at the top of each stack.

54. A substrate removal process as claimed in claim 52, wherein the spacing between each stack matches the spacing between the engaged elongate substrates.

55. A substrate removal process as claimed in claim 52, wherein storage unit includes a plurality of mutually spaced storage bins, the spacing between the storage bins matching the spacing between the engaged elongate substrates.

56. An elongate substrate dispensing process, including:
providing a plurality of mutually spaced elongate substrate storage bins, each of said elongate substrate storage bins having a stack of elongate substrates stored therein, the spacing between the elongate substrate storage bins being selected to provide a desired spacing of elongate substrates in a solar cell sub-module to be assembled from the stored elongate substrates.

57. A process for forming a solar cell sub-module for a photovoltaic device including:
dispensing elongate solar cells from an elongate substrate dispensing unit into respective slots of an alignment jig; and
attaching the elongate solar cells to a substrate, crossbeam or electrical interconnects to form the solar cell sub-module.

58. An elongate substrate handling system, including:
an elongate substrate dispensing unit for storing and dispensing one or more stacks of elongate substrates; and
an alignment jig having mutually spaced slots for receiving respective elongate substrates dispensed from the storage unit.

59. An elongate substrate handling system as claimed in claim 58, wherein the elongate substrate dispensing unit includes a plurality of mutually spaced storage bins, each of the storage bins adapted to store a corresponding stack of elongate substrates.

60. An elongate substrate handling system as claimed in claim 58, wherein the spacing between the slots is selected to correspond to the spacing of elongate substrates in a sub-module to be assembled from the elongate substrates.

61. An elongate substrate handling system as claimed in claim 58, wherein each slot of the alignment jog includes a wall adapted to dispense a corresponding elongate substrate from the dispensing unit.

62. A process for forming a solar cell sub-module for a photovoltaic device including:
engaging a length of electrical interconnect with an engagement tool having a plurality of mutually spaced engagement sections so that only mutually spaced regions of the electrical interconnect are engaged by the tool; and
applying a cutting tool to locations of the electrical interconnect between the engaged regions to cut the engaged electrical interconnect into corresponding lengths of the electrical interconnect.

63. A process as claimed in claim 62, further including deforming free ends of each length of electrical interconnect so that the deformed free ends are substantially orthogonal to the engaged regions of each length of electrical interconnect.

64. A process as claimed in claim 63, wherein the free ends of each length of electrical interconnect are deformed in substantially the same direction.

65. A process as claimed in claim 63, wherein the free ends of each length of electrical interconnect are deformed in substantially opposite directions.

66. A process as claimed in claim 63, including:
applying the engaged lengths of electrical interconnect to an array of mutually spaced elongate substrates; and
attaching the deformed ends of each electrical interconnect to corresponding contacts of the elongate substrates, wherein the spacing between the deformed ends of adjacent electrical interconnects correspond to the spacing between adjacent elongate substrates of the array, thereby forming an array of electrically interconnected elongate substrates.

67. A process for forming an electrical connection in a photovoltaic module, including attaching an electrical conductor to mutually spaced locations of a support, said electrical conductor defining an indirect path between said locations to accommodate different rates of thermal expansion of said electrical conductor and said support, and thereby to maintain an electrical connection between said locations.

68. A process as claimed in claim 67, wherein said indirect path includes one or more corrugations of said electrical conductor.

69. A process as claimed in claim 67, wherein said indirect path includes first regions of said electrical conductor shaped to facilitate attachment to said support between second regions of said electrical conductor including one or more corrugations.

70. A process as claimed in claim 69, wherein said first regions are substantially planar.

71. A process as claimed in claim 67, wherein said electrical connector includes a bus bar for said photovoltaic module.

72. A process as claimed in claim 71, wherein said bus bar is adapted to form electrical connections between solar cells of said photovoltaic module.

73. A process as claimed in claim 72, wherein said solar cells of said photovoltaic module include elongate solar cells.

74. A process for forming an electrical connector for a photovoltaic module, including deforming a length of an electrically conductive substance to define an indirect path between at least two mutually spaced attachment locations along said length to accommodate different rates of thermal expansion of said electrically conductive substance and a support, and thereby to maintain an electrical connection between said attachment locations when at least part of said length of said electrically conductive substance is attached to said support at said mutually spaced attachment locations.

75. A process as claimed in claim 74, wherein said length of said electrically conductive substance is in the form of a wire or a sheet.

76. A process as claimed in claim 74, wherein said length of said electrically conductive substance is in the form of a sheet, and the process includes cutting said sheet along a direction substantially parallel to the length direction to form a plurality of electrical connectors.

77. A process as claimed in claim 74, further including cutting the deformed length of electrically conductive substance into predetermined lengths to form a plurality of electrical connectors.

78. A process as claimed in claim 74, wherein the process includes further deforming the deformed length of electrically conductive substance so that the electrically conductive substance and said support are pressed together during production of said photovoltaic module.

79. A process as claimed in claim 78, wherein said step of further deforming includes rolling the deformed length into a substantially circular shape.

80. A process as claimed in claim 74, wherein said electrically conductive substance includes a metal.

81. A process as claimed in claim 74, wherein said electrically conductive substance is copper.

82. A process for forming electrical connections between elongate solar cells in a photovoltaic module, including attaching a bus bar to mutually spaced attachment locations of a substrate, said bus bar defining an indirect path between said locations to accommodate different rates of thermal expansion of said bus bar and said substrate, and thereby to maintain an electrical connection between said attachment locations.

83. A process as claimed in claim 82, wherein said bus bar includes one or more corrugations.

84. A process as claimed in claim 82, wherein said bus bar includes one or more corrugated regions separated by respective second regions adapted to facilitate attachment of said bus bar to said substrate.

85. A process as claimed in claim 84, wherein said second regions are substantially planar.

86. A process as claimed in claim 82, wherein the substantially planar second regions are convex towards said substrate.

87. (canceled)

88. An electrical connector for a photovoltaic module, said electrical connector being adapted for attachment to mutually spaced attachment locations of a support, said electrical conductor defining an indirect path between said locations to accommodate different rates of thermal expansion of said electrical conductor and said support, and thereby to maintain an electrical connection between said attachment locations.

89. A system for forming electrical connectors for a photovoltaic module, the system including a pair of rotating rollers having mutually opposed projections and recesses adapted to deform a length of an electrically conductive substance fed between said rollers to define an indirect path between at least two mutually spaced attachment locations along said length to accommodate different rates of thermal expansion of said electrically conductive substance and a support, and thereby to maintain an electrical connection between said attachment locations when at least part of said length of said electrically conductive substance is attached to said support at said mutually spaced attachment locations.

90. A linear concentrator system including a plurality of solar cell sub-modules as claimed in claim 1.

91. A linear concentrator system as claimed in claim 90, wherein the elongate solar cells are electrically connected in series so that the electrical current generated by the elongate solar cells flows substantially in a direction parallel to the longitudinal axis of the linear concentrator system to reduce the series resistance of the elongate solar cells.

92. A linear concentrator system as claimed in claim 90, wherein the solar cell submodules are arranged as closely adjacent rows mounted to a receiver of the linear concentrator system, the rows being parallel to an optical axis of the receiver.

93. A linear concentrator system as claimed in claim 90, including a thermally conducting substrate having a first portion located near an optical axis of the system and a second portion, wherein the elongate solar cells are mounted substantially adjacent to each other on the first portion of the thermally conducting substrate, the second portion of the thermally conducting substrate being actively cooled in so that heat generated by the elongate solar cells is conducted away from the elongate solar cells in a direction substantially perpendicular to the optical axis of the system.

94. A sliver removal process, including:
receiving a plurality of mutually spaced sliver solar cells interconnected by one or more wafer frame portions, each of said sliver solar cells having outwardly facing edges having respective polarities and solar cell faces perpendicular to said edges; and
releasing the sliver solar cells from the one or more wafer frame portions in a substantially simultaneous manner whilst maintaining the relative orientation of said solar cell edges to provide a plurality of released sliver solar cells whose edges of a selected polarity have the same orientation.

95. A sliver removal process, including:
receiving a plurality of slivers interconnected and maintained in a mutually spaced arrangement by one or more connecting portions, each of said slivers having outwardly facing edges and faces perpendicular to said edges, the edges of each sliver including a first edge and a second edge, wherein the first edges of said slivers have a first orientation; and
releasing the slivers from the one or more connecting portions in a substantially simultaneous manner whilst maintaining the relative orientation of said edges to provide a plurality of released slivers wherein the first edges of the released slivers have the same orientation.

96. A sliver removal process as claimed in claim 95, wherein the slivers include sliver solar cells, the edges of each sliver solar cell having opposite polarities.

97. A sliver removal process as claimed in claim 95, wherein said step of releasing includes:
engaging the edges of said slivers;
removing the one or more connecting portions from the engaged slivers to provide a plurality of released and mutually spaced slivers; and
disengaging the mutually spaced slivers to conflate said slivers into a substantially contiguous stack of slivers.

98. A sliver removal process as claimed in claim 95, wherein said step of releasing includes:
engaging the one or more connecting portions; and
successively removing each of said slivers from said one or more connecting portions in a substantially simultaneous manner to form a conflated stack of slivers.

99. A sliver removal process as claimed in claim 95, wherein said step of releasing includes:
engaging the one or more connecting portions;
engaging the edges of said slivers; and
removing said slivers from said one or more connecting portions to provide a plurality of released and mutually spaced slivers.

100. A sliver removal process as claimed in claim 99, wherein said step of engaging includes engaging the edges of said slivers with adhesive tape.

101. A sliver removal process as claimed in claim 99, further including:
placing the released and mutually spaced slivers into a storage device; and
disengaging the edges of said slivers to form a conflated stack of slivers.

102. (canceled)

103. A sliver removal apparatus, including:
a clamp having two opposing portions for engaging respective edges or one or more connecting portions of a plurality of mutually spaced slivers interconnected by said one or more connecting portions, each of said slivers having faces perpendicular to said edges, said faces having a relative orientation; wherein said two opposing portions include alignment slots for receiving respective guides of a sliver storage device in a direction substantially transverse to longitudinal axes of said slivers.

104. A sliver removal apparatus as claimed in claim 103, wherein said two opposing portions include compliant surfaces for engaging said edges of said slivers without damaging said edges.

105. A sliver removal apparatus as claimed in claim 104, wherein said compliant surfaces are at least partially adhesive.

106. A sliver removal apparatus, including a sliver storage device having a plurality of elongated guides for mating with respective alignment slots in a clamp engaging one or more connecting portions or edges of a plurality of mutually spaced slivers interconnected by said one or more connecting portions, said edges having a relative orientation; wherein said elongated guides are arranged adjacent and substantially perpendicular to opposing edges of said slivers when said guides are mated with said slots.

107. A sliver removal apparatus as claimed in claim 106, wherein the sliver storage device includes a biased retaining plate for retaining released slivers under compression.

108. A sliver removal apparatus as claimed in claim 106, wherein the sliver storage device includes a base adapted to fracture said slivers at or near ends of said slivers when said base is pressed into said slivers.

109. A sliver removal clamp having two opposing portions for engaging one or more connecting portions of a plurality of mutually spaced slivers interconnected by one or more connecting portions, each of said slivers having outwardly directed edges and faces perpendicular to said edges; wherein said two opposing portions include openings to allow edges of said slivers to be engaged to allow substantially simultaneous removal of said slivers from said one or more connecting portions whilst retaining relative orientation of said edges.

110. A process for releasing elongate substrates from a wafer incorporating a plurality of elongate substrates interconnected by wafer frame portions, including:
engaging only opposing faces of each elongate substrate, the engaged faces being in the same plane as the wafer surfaces;
removing the wafer frame portions to disconnect the elongate substrates from one another; and
disengaging one of the faces of each elongate substrate, the other face of each elongate substrate remaining engaged.

111. A process for releasing elongate substrates from a wafer incorporating an array of elongate substrates interconnected by wafer frame portions, including:
engaging only selected non-adjacent ones of the elongate substrates and disconnecting the engaged substrates from the other elongate substrates in the array; and
depositing the engaged elongate substrates in respective mutually spaced storage bins of a storage unit, the spacing between the storage bins corresponding to the spacing between the engaged elongate substrates.

112. A process as claimed in claim 111, further including:
engaging selected non-adjacent remaining ones of the elongate substrates and disconnecting the engaged substrates from the other elongate substrates in the array; and
depositing the engaged elongate substrates in respective ones of the mutually spaced storage bins to form respective mutually spaced stacks of elongated substrates.

113. A process for releasing elongate substrates from a wafer incorporating an array of elongate substrates interconnected by wafer frame portions, including:
(i) engaging a selected one of the elongate substrates and disconnecting the engaged substrate from the other elongate substrates in the array;
(ii) depositing the engaged elongate substrate in a storage unit; and
(iii) repeating steps (i) and (ii) to form a stack of elongated substrates in the storage unit.

114. A storage apparatus for storing elongate substrates in a stacked configuration, the storage apparatus including a translation mechanism for translating a stack of stored elongate substrates to allow receipt of a subsequently received elongate substrate for storage in the storage apparatus.

115. A storage apparatus as claimed in claim 114, wherein the translation mechanism includes at least two pairs of engagement members that engage the edges of the stack and translate the stack by a predetermined distance.

116. A storage apparatus as claimed in claim 115, wherein the storage apparatus is adapted to receive elongate substrates at the bottom of a stack of stored elongate substrates; and the engagement members are adapted to disengage the edges of the stack following translation to conflate the newly received elongate substrate with the other stored substrates in the stack.

117. A system having components for executing the steps of claim 67.

118. A system having components for executing the steps of claim 74.

119. A system having components for executing the steps of claim 82.

120. A sliver removal apparatus having components for executing the steps of claim 94.

121. A sliver removal apparatus having components for executing the steps of claim 95.
